(19) United States
(12) Patent Application Publication
(10) Pub. No.: US 2025/0279630 A1
(43) Pub. Date: Sep. 4, 2025

(54) LIDAR DEVICE COMPRISING LASER DETECTION ARRAY AND LASER OUTPUT ARRAY

(71) Applicant: SOS LAB Co., Ltd., Gwangju (KR)

(72) Inventors: Hoonil JEONG, Gwangju-si Gyeonggi-do (KR); Dongju JANG, Bucheon-si Gyeonggi-do (KR); Chan M. LIM, Yongin-si Gyeonggi-do (KR); Dongkyu KIM, Gwangju (KR); Junho CHOI, Gwangju (KR); Sungryeol PARK, Hwaseong-si Gyeonggi-do (KR)

(73) Assignee: SOS LAB Co., Ltd., Gwangju (KR)

(21) Appl. No.: 19/197,445

(22) Filed: May 2, 2025

Related U.S. Application Data
(63) Continuation of application No. PCT/KR2023/016526, filed on Oct. 24, 2023.

(30) Foreign Application Priority Data
Nov. 3, 2022 (KR) 10-2022-0144840

(51) Int. Cl. H01S 5/42; G01S 7/481; H01S 5/042

(52) U.S. Cl. CPC H01S 5/423; H01S 5/04256; G01S 7/4815

(57) ABSTRACT

Disclosed is a method for a light detection and ranging (LiDAR) device to measure the distance from the LiDAR device to an object. Specifically, the method may include a LiDAR device: outputting a first laser beam through a vertical-cavity surface-emitting laser (VCSEL) in each of a plurality of scan cycles; identifying at least one time point at which at least one phone is detected through a single-photon avalanche diode (SPAD) optically corresponding to the VCSEL, in each of the plurality of scan cycles, in a time bin unit having a specific time interval; determining a histogram on the basis of the at least one time point; and measuring the distance between the object and the LiDAR device on the basis of at least a portion of the histogram.

### CROSS-REFERENCE TO RELATED APPLICATIONS

This application is a continuation of International Application No. PCT/KR2023/016526 filed on Oct. 24, 2023, which claims priority to Korean Patent Application No. 10-2022-0144840 filed on Nov. 3, 2022, the entire contents of which are herein incorporated by reference.

### TECHNICAL FIELD

The present disclosure relates to a laser emission array that emits a laser, and a LiDAR device using the laser emission array and, in more detail, to a laser emission array that efficiently controls power consumption while emitting a laser with high power, and a LiDAR device using the laser emission array.

### BACKGROUND ART

Recently, Light Detection and Ranging (LiDAR) has been attracting attention with growing interest in autonomous and unmanned vehicles. LiDAR is a device that acquires distance information about the surroundings using a laser, and is being applied not only to vehicles but also to various fields such as drones and aircraft due to its advantages of high precision, high resolution, and the capability to perceive objects in three dimensions.

Meanwhile, a solid-state LiDAR Device is a device that can acquire distance information of the three-dimensional surrounding space without any mechanically moving components, and a laser emission array can be used to implement the solid-state LiDAR Device.

### SUMMARY

### Technical Problem

An objective of the present disclosure is to provide a laser emission module that efficiently controls power consumption while emitting a laser with high power.

An objective of the present disclosure is to provide a method of operating a laser emission module that efficiently controls power consumption while emitting a laser with high power.

Objectives of the present disclosure are not limited to those described above and objectives not stated above will be clearly understood to those skilled in the art from the specification and the accompanying drawings.

### Technical Solution

According to an embodiment of present disclosure, A method for measuring a distance from a LiDAR (Light Detection and Ranging) device to and object, comprising: emitting a first laser beam through a VCSEL (Vertical Cavity Surface Emitting Laser) in each of a plurality of scan cycles; identifying, in units of time bins having a specific time interval, at least one of time points at which at least one of photons is detected through a SPAD (Single Photon Avalanche Diode) optically corresponding to the VCSEL in each of the plurality of scan cycles; determining a histogram based on the at least one of time points, wherein the histogram consists of a count-number of photon detections in each of a plurality of time bins during the plurality of scan cycles; measuring a distance between the object and the LiDAR device based on at least a portion of the histogram; wherein the method further comprises: after emitting the first laser beam in at least some pre-determined scan cycles among the plurality of scan cycles, emitting a second laser beam having an intensity lower than an intensity of the first laser beam; measuring the distance based on the emitting timing of the first laser beam, the emitting timing of the second laser beam, and at least a portion of the histogram.

Herein, the measuring the distance comprises: obtaining a first subset and a second subset of the histogram; measuring the distance using the second subset based on the first subset including a count number of photon detections of time bins corresponding to a predetermined time interval from the emitting timing of the first laser beam and the second subset including a count number of photon detections of time bins corresponding to a predetermined time interval from the emitting timing of the second laser beam; wherein the predetermined time interval is a time interval from when a laser beam emitted from the LiDAR device is reflected by the object and detected through the SPAD, when the object is located within a predetermined distance from the LiDAR device.

Also, each of the first subset and the second subset includes a number of photon detections equal to or greater than a threshold value.

Also, each of the at least some of the scan cycles exists at intervals of N scan cycles among the plurality of scan cycles, where N is a natural number equal to or greater than 1.

Also, the emitting of the first laser beam comprises emitting the first laser beam using a portion of a first electric charge quantity charged in a capacitor connected to the VCSEL; and wherein the emitting of the second laser beam comprises emitting the second laser beam using at least a portion of a second electric charge quantity remaining after emitting the first laser beam from the first electric charge quantity.

Also, the emitting of the first laser beam comprises emitting the first laser beam using a portion of a first electric charge quantity charged in a capacitor connected to the VCSEL; and wherein the emitting of the second laser beam comprises emitting the second laser beam using at least a portion of a third electric charge quantity, which remains after discharging a part of a second electric charge quantity remaining after emitting the first laser beam from the first electric charge quantity.

Also, the measuring of the distance comprises: obtaining a first subset and a second subset of the histogram; determining whether the first subset is distorted, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; and measuring the distance using the second subset, based on determining whether the first subset is distorted.

According to an embodiment of present disclosure, A LiDAR (Light Detection and Ranging) device for measuring a distance to an object, comprising: a laser emitting unit comprising a VCSEL (Vertical Cavity Surface Emitting Laser); a photon detecting unit comprising a SPAD (Single Photon Avalanche Diode) optically corresponding to the VCSEL; and a controller configured to control the laser emitting unit and the photon detecting unit, and to measure the distance between the object and the LiDAR device; wherein the controller is configured to: control the VCSEL to emit a first laser beam in each of a plurality of scan cycles; identify, in units of time bins having a specific time interval, at least one point in time at which at least one photon is detected through the SPAD in each of the plurality of scan cycles; determine a histogram based on the at least one point in time, wherein the histogram consists of a count number of photon detections in each of a plurality of time bins during the plurality of scan cycles; measure the distance between the object and the LiDAR device based on at least a portion of the histogram; wherein the controller is configured to: control the laser emitting unit to emit a second laser beam having an intensity lower than an intensity of the first laser beam, after emitting the first laser beam in at least some predetermined scan cycles among the plurality of scan cycles; wherein the controller is configured to: measure the distance based on an emitting timing of the first laser beam, an emitting timing of the second laser beam, and at least a portion of the histogram.

Also, the controller is configured to: obtain a first subset and a second subset of the histogram; measure the distance using the second subset, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; wherein the predetermined time interval is a time interval from when a laser beam emitted from the LiDAR device is reflected by the object and detected through the SPAD, when the object is located within a predetermined distance from the LiDAR device.

Also, each of the first subset and the second subset includes a number of photon detections equal to greater than a threshold value.

Also, each of the at least some of the scan cycles exists at intervals of N scan cycles among the plurality of scan cycles, wherein N is a natural number equal to or greater than 1.

Also, the controller is configured to emit the first laser beam using a portion of a first electric charge quantity charged in a capacitor connected to the VCSEL; and wherein the controller is configured to emit the second laser beam using at least a portion of a second electric charge quantity remaining after emitting the first laser beam from the first electric charge quantity.

Also, the controller is configured to emit the first laser beam using a portion of a first electric charge quantity charged in a capacitor connected to the VCSEL; and wherein the controller is configured to emit the second laser beam using at least a portion of a third electric charge quantity, which remains after discharging a part of a second electric charge quantity remaining after emitting the first laser beam from the first electric charge quantity.

Also, the controller is configured to measure the distance by: obtaining a first subset and a second subset of the histogram; determining whether the first subset is distorted, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; and measuring the distance using the second subset, based on determining whether the first subset is distorted.

Objectives of the present disclosure are not limited to those described above and objectives not stated above will be clearly understood to those skilled in the art from the specification and the accompanying drawings.

### Advantageous Effects

According to an embodiment of the present disclosure, a laser emission module that emits lasers with high power while efficiently controlling power consumption can be provided.

According to an embodiment of the present disclosure, a method of operating a laser emission module that emits lasers with high power while efficiently controlling power consumption can be provided.

According to an embodiment of the present disclosure, it is possible to accurately measure the distance to an object located at a short distance without significantly increasing power consumption while maintaining a frame rate.

Effects of the present disclosure are not limited to those described above and effects not stated above will be clearly understood to those skilled in the art from the specification and the accompanying drawings.

### DESCRIPTION OF DRAWINGS

FIG. 1 is a diagram illustrating a LiDAR device according to an embodiment.

FIGS. 2A through 2D are diagrams showing various embodiments of a LiDAR device.

FIG. 3 is a diagram illustrating the operation of a LiDAR device according to an embodiment and LiDAR data.

FIG. 4 is a diagram illustrating LiDAR data according to an embodiment.

FIG. 5 is a diagram illustrating LiDAR data according to an embodiment.

FIG. 6 is a diagram illustrating pieces of information included in attribute data according to an embodiment.

FIG. 7 is a diagram illustrating a LiDAR device according to an embodiment.

FIG. 8 is a diagram illustrating a laser emission array and a laser detecting array included in a LiDAR device according to an embodiment.

FIG. 9 and FIG. 10 are diagrams illustrating a LiDAR device according to an embodiment.

FIG. 11 and FIG. 12 are diagrams illustrating a laser emitting module and a laser detecting module according to an embodiment.

FIG. 13 and FIG. 14 are diagrams illustrating an emitting lens module and a detecting lens module according to an embodiment.

FIG. 15 is a diagram illustrating a laser emitting unit according to an embodiment.

FIG. 16 is a diagram illustrating a laser emission array according to an embodiment.

FIG. 17 and FIG. 18 are diagrams illustrating a laser emission array according to an embodiment.

FIG. 19 and FIG. 20 are diagrams illustrating a laser emission array according to another embodiment.

FIG. 21 is a diagram illustrating an operation sequence of a laser emission array according to an embodiment and a charging voltage of a capacitor included in a laser emission array which changes in accordance with the operation sequence.

FIG. 22 is a diagram illustrating a laser emission array according to another embodiment.

FIGS. 23A through 23D are diagrams illustrating an operation sequence of a laser emission array according to an embodiment and driving of various switches depending on the operation sequence.

FIG. 24 is a diagram illustrating an embodiment of a method in which a LiDAR device acquires point data.

FIG. 25 is a diagram illustrating a method of acquiring detection values and LiDAR data according to an embodiment.

FIG. 26 is a diagram illustrating a method of acquiring a detection value set for at least one pixel on the basis of a detection signal acquired from a laser detecting array included in a LiDAR device according to an embodiment.

FIG. 27 illustrates problems that may be generated when a LiDAR device measures the distance to an object by emitting a high-intensity laser beam.

FIG. 28 illustrates a method in which a laser emission device emits a laser beam in one scan cycle in accordance with an embodiment of the present disclosure.

FIG. 29 illustrates an example in which photons are counted in a time bin in accordance with the voltage stored in a capacitor corresponding to FIG. 21.

FIGS. 30A and 30B illustrate an example of the change in the voltage stored in a capacitor and the counting of photons in a time bin according to an embodiment of the present disclosure.

FIGS. 31A and 31B illustrate a method in which a laser emission device emits a laser beam in a plurality of scan cycles in accordance with an embodiment of the present disclosure.

FIG. 32 to FIG. 33 illustrate a method in which a LiDAR device measures the distance between the LiDAR device and an object using a histogram created on the basis of photons detected by at least one detecting device in accordance with an embodiment of the present disclosure.

FIGS. 34A, 34B, 35A, 35B, 36A, and 36B illustrate and compare LiDAR data measurement results in the case of measuring the distance to an object and the case of not measuring the distance in accordance with an embodiment of the present disclosure.

### DETAILED DESCRIPTION

Embodiments described herein are provided to clearly explain the spirit of the present disclosure to those skilled in the art, so the present disclosure is not limited to the embodiments described herein and the scope of the present disclosure should be construed as including changed or modified examples not departing from the spirit of the present disclosure.

Terminologies used herein were selected from general terminologies that are used at present as generally as possible in consideration of their functions herein, but may be changed, depending on the intention of those skilled in the art, precedents, advent of new technologies, or the like. However, when such specific terminologies are defined and used having certain meanings, the meanings of the terminologies will be specifically described. Accordingly, the terminologies used herein should be construed on the basis of the substantial meanings of the terminologies and the entire specification, not simply the names of the terminologies.

The accompanying drawings of the present disclosure are provided for easy description of the present disclosure and the shapes shown in the drawings may be exaggerated to help understand the present disclosure, if necessary, so the present disclosure is not limited to the drawings of the present disclosure.

Elements or layers described in the specification that are referred to as being “on” or “above” another element or layer may include cases where there is an intermediate layer or element between them, not just immediately above the other element or layer.

Throughout the specification, the same reference numerals may generally refer to the same elements.

Numbers (e.g., first, second, etc.) used in the description of the specification may be understood as identification symbols to discriminate one element from another element.

The suffixes “module” and “unit” used for elements in the description of the specification are used or mixed for the convenience of writing the specification, and they may not have distinct meanings or roles by themselves.

When it is determined that detailed description of well-known configurations or functions related to the present disclosure may make the spirit of the present disclosure unclear, they are not described in detail, if necessary.

According to an embodiment, as a laser emission module, there may be provided a laser emission module that includes: a first node and a second node; a first laser emission unit disposed between the first node and the second node, where the first node and the second node have different voltages when the first laser emission unit emits a first laser; a first capacitor connected (coupled) to the first node, where the first capacitor functions to supply energy to the first laser emission unit through the first node; a first power supply connected to the first node, where the first power supply functions to charge the first capacitor through the first node; a first charging switch connected to the first node, where the first charging switch is positioned between the first capacitor and the first power supply; a first common driving switch connected to the second node, where the first common driving switch is positioned between the first laser emission unit and a first ground; and a first discharging switch connected to the first node, where the first discharging switch is positioned between the first capacitor and a second ground, wherein a first electric charge quantity charged to the first capacitor by the first power supply when the first charging switch operates may be greater than a second electric charge quantity discharged from the first capacitor when the first common driving switch operates.

In this configuration, the first laser emission unit may include an upper metal and a lower metal.

In this configuration, the laser emission module includes a first conductor that contacts the upper metal of the first laser emission unit and a second conductor that contacts the lower metal of the first laser emission unit, and the first node may be connected to the first conductor and the second node may be connected to the second conductor.

In this configuration, the second electric charge quantity discharged from the first capacitor by operation of the first common driving switch may be greater than a third electric charge quantity discharged from the first capacitor by operation of the first discharging switch.

In this configuration, the laser emission module may include: a first sub-array including the first laser emission unit and the second laser emission unit; and a second sub-array including a third laser emission unit and a fourth laser emission unit.

In this configuration, the laser emission module may include a third node, and the first laser emission unit and the second laser emission unit may be positioned between the first node and the second node, and the third laser emission unit and the fourth laser emission unit may be positioned between the third node and the second node.

The laser emission module includes: a second capacitor connected to the third node, where the second capacitor functions to supply energy to the third and fourth laser emission units through the third node; a second power supply connected to the third node, where the second power supply functions to charge the second capacitor through the third node; a second charging switch connected to the third node, where the second charging switch is positioned between the second capacitor and the second power supply; and a second discharging switch connected to the third node, where the second discharging switch is positioned between the second capacitor and a third ground, and the first common driving switch may be positioned between the second laser emission unit and the first ground, between the third laser emission unit and the first ground, and between the fourth laser emission unit and the first ground.

In this configuration, the second power supply may be the same as the first power supply.

In this configuration, the first charging switch and the second charging switch are driven independently, whereas the first discharging switch and the second discharging switch can be driven in conjunction.

In this configuration, the laser emission module may include: a first charging switch driver to control the operation of the first charging switch; a second charging switch driver to control the operation of the second charging switch; and discharging switch common driver to control the operation of the first discharging switch and the second discharging switch.

In this configuration, the upper metal of the first laser emission unit and the upper metal of the second laser emission unit may be connected to the first node, and the upper metal of the third laser emission unit and the upper metal of the fourth laser emission unit may be connected to the third node, and the lower metals of the first to fourth laser emission units may be connected to the second node.

In this configuration, when the first laser emission unit and the second laser emission unit emit a first laser and a second laser, respectively, a voltage difference between the first node and the second node is generated by the first capacitor, and when the third laser emission unit and the fourth laser emission unit emit a third laser and a fourth laser, respectively, a voltage difference between the third node and the fourth node is generated by the second capacitor.

In this configuration, the first laser emission unit may include a Vertical Cavity Surface Emitting Laser (VCSEL) emitter.

According to another embodiment, as a method of operating a laser emission module, there may be provided a method of operating a laser emission module that includes: a first node and a second node; a first laser emission unit disposed between the first node and the second node, where the first node and the second node have different voltages when the first laser emission unit emits a first laser; a first capacitor connected to the first node, where the first capacitor functions to supply energy to the first laser emission unit through the first node; a first power supply connected to the first node, where the first power supply functions to charge the first capacitor through the first node; a first charging switch connected to the first node, where the first charging switch is positioned between the first capacitor and the first power supply; a first common driving switch connected to the second node, where the first common driving switch is positioned between the first laser emission unit and a first ground; and a first discharging switch connected to the first node, where the first discharging switch is positioned between the first capacitor and a second ground. The method includes: charging the first capacitor such that the first capacitor has a first electric charge quantity by driving the first charging switch; discharging the first capacitor such that a first laser is emitted from the first laser emission unit by driving the first common driving switch, where the electric charge quantity of the first capacitor changes from the first electric charge quantity to a second electric charge quantity; and discharging the first capacitor by driving the first discharging switch, where the electric charge quantity of the first capacitor changes from the second electric charge quantity to a third electric charge quantity.

In this configuration, the first charging switch is driven for a first time duration, the first common driving switch is driven for a second time duration, and the first discharging switch is driven for a third time duration, in which the second time duration may be shorter than the first time duration and may be shorter than the third time duration.

In this configuration, a voltage drop rate of the first capacitor while the first common driving switch is driven may be faster than a voltage drop rate of the first capacitor while the first discharging switch is driven.

In this configuration, the charging of the first capacitor such that the first capacitor has a first electric charge quantity by driving the first charging switch may include: a first charging step of charging the first capacitor such that the first capacitor has the first electric charge quantity by driving the first charging switch at the first time point; and a second charging step of charging the first capacitor such that the first capacitor has the first electric charge quantity by driving the second charging switch at a second time point after the first time point, in which the amount of variation in the electric charge quantity of the first capacitor in the first charging step may be different from the amount of variation in the electric charge quantity of the first capacitor in the second charging step.

In this configuration, the amount of variation in the electric charge quantity of the first capacitor in the first charging step may be greater than the amount of variation in the electric charge quantity of the first capacitor in the second charging step.

Further, according to another embodiment of the present disclosure, as a laser emission module, there may be provided a laser emission module that includes: a first node and a second node; a first laser emission unit disposed between the first node and the second node, where the first node and the second node have different voltages when the first laser emission unit emits a first laser; a first capacitor connected (coupled) to the first node, where the first capacitor functions to supply energy to the first laser emission unit through the first node; a first power supply connected to the first node, where the first power supply functions to charge the first capacitor through the first node; a first diode connected to the first node, where the first diode is positioned between the first power supply and the first capacitor and functions to control the direction of the current between the first power supply and the first capacitor; a first charging switch connected to the first node, where the first charging switch is positioned between the first capacitor and the first power supply; a second capacitor functioning to supply energy to the first charging switch; a second power supply functioning to charge the second capacitor; a second charging switch positioned between the second capacitor and a first ground; a first common driving switch connected to the second node, where the first common driving switch is positioned between the first laser emission unit and a second ground; a first discharging switch connected to the first node, where the first discharging switch is positioned between the first capacitor and a third ground; and a second diode connected to the first node, where the second diode is positioned between the first capacitor and the first discharging switch and functions to control the direction of the current between the first capacitor and the first discharging switch.

In this configuration, the first laser emission unit may include an upper metal and a lower metal.

In this configuration, the laser emission module includes a first conductor that contacts the upper metal of the first laser emission unit and a second conductor that contacts the lower metal of the second laser emission unit, and the first node may be connected to the first conductor and the second node may be connected to the second conductor.

In this configuration, a second electric charge quantity discharged from the first capacitor by operation of the first common driving switch may be greater than a third electric charge quantity discharged from the first capacitor by operation of the first discharging switch.

In this configuration, the second charging switch may be connected to the first node through the first diode and the first discharging switch may be connected to the first node without passing through the first node.

In this configuration, when the second charging switch is operated, the current flow between the first capacitor and the first ground may be blocked by the first diode.

According to an embodiment of present disclosure, A method for measuring a distance from a LiDAR (Light Detection and Ranging) device to and object, comprising: emitting a first laser beam through a VCSEL (Vertical Cavity Surface Emitting Laser) in each of a plurality of scan cycles; identifying, in units of time bins having a specific time interval, at least one of time points at which at least one of photons is detected through a SPAD (Single Photon Avalanche Diode) optically corresponding to the VCSEL in each of the plurality of scan cycles; determining a histogram based on the at least one of time points, wherein the histogram consists of a count-number of photon detections in each of a plurality of time bins during the plurality of scan cycles; measuring a distance between the object and the LiDAR device based on at least a portion of the histogram; wherein the method further comprises: after emitting the first laser beam in at least some pre-determined scan cycles among the plurality of scan cycles, emitting a second laser beam having an intensity lower than an intensity of the first laser beam; measuring the distance based on the emitting timing of the first laser beam, the emitting timing of the second laser beam, and at least a portion of the histogram.

Herein, the measuring the distance comprises: obtaining a first subset and a second subset of the histogram; measuring the distance using the second subset based on the first subset including a count number of photon detections of time bins corresponding to a predetermined time interval from the emitting timing of the first laser beam and the second subset including a count number of photon detections of time bins corresponding to a predetermined time interval from the emitting timing of the second laser beam; wherein the predetermined time interval is a time interval from when a laser beam emitted from the LiDAR device is reflected by the object and detected through the SPAD, when the object is located within a predetermined distance from the LiDAR device.

Also, each of the first subset and the second subset includes a number of photon detections equal to or greater than a threshold value.

Also, each of the at least some of the scan cycles exists at intervals of N scan cycles among the plurality of scan cycles, where N is a natural number equal to or greater than 1.

Also, the emitting of the first laser beam comprises emitting the first laser beam using a portion of a first electric charge quantity charged in a capacitor connected to the VCSEL; and wherein the emitting of the second laser beam comprises emitting the second laser beam using at least a portion of a second electric charge quantity remaining after emitting the first laser beam from the first electric charge quantity.

Also, the emitting of the first laser beam comprises emitting the first laser beam using a portion of a first electric charge quantity charged in a capacitor connected to the VCSEL; and wherein the emitting of the second laser beam comprises emitting the second laser beam using at least a portion of a third electric charge quantity, which remains after discharging a part of a second electric charge quantity remaining after emitting the first laser beam from the first electric charge quantity.

Also, the measuring of the distance comprises: obtaining a first subset and a second subset of the histogram; determining whether the first subset is distorted, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; and measuring the distance using the second subset, based on determining whether the first subset is distorted.

According to an embodiment of present disclosure, A LiDAR (Light Detection and Ranging) device for measuring a distance to an object, comprising: a laser emitting unit comprising a VCSEL (Vertical Cavity Surface Emitting Laser); a photon detecting unit comprising a SPAD (Single Photon Avalanche Diode) optically corresponding to the VCSEL; and a controller configured to control the laser emitting unit and the photon detecting unit, and to measure the distance between the object and the LiDAR device; wherein the controller is configured to: control the VCSEL to emit a first laser beam in each of a plurality of scan cycles; identify, in units of time bins having a specific time interval, at least one point in time at which at least one photon is detected through the SPAD in each of the plurality of scan cycles; determine a histogram based on the at least one point in time, wherein the histogram consists of a count number of photon detections in each of a plurality of time bins during the plurality of scan cycles; measure the distance between the object and the LiDAR device based on at least a portion of the histogram; wherein the controller is configured to: control the laser emitting unit to emit a second laser beam having an intensity lower than an intensity of the first laser beam, after emitting the first laser beam in at least some predetermined scan cycles among the plurality of scan cycles; wherein the controller is configured to: measure the distance based on an emitting timing of the first laser beam, an emitting timing of the second laser beam, and at least a portion of the histogram.

Also, the controller is configured to: obtain a first subset and a second subset of the histogram; measure the distance using the second subset, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; wherein the predetermined time interval is a time interval from when a laser beam emitted from the LiDAR device is reflected by the object and detected through the SPAD, when the object is located within a predetermined distance from the LiDAR device.

Also, each of the first subset and the second subset includes a number of photon detections equal to greater than a threshold value.

Also, each of the at least some of the scan cycles exists at intervals of N scan cycles among the plurality of scan cycles, wherein N is a natural number equal to or greater than 1.

Also, the controller is configured to emit the first laser beam using a portion of a first electric charge quantity charged in a capacitor connected to the VCSEL; and wherein the controller is configured to emit the second laser beam using at least a portion of a second electric charge quantity remaining after emitting the first laser beam from the first electric charge quantity.

Also, the controller is configured to emit the first laser beam using a portion of a first electric charge quantity charged in a capacitor connected to the VCSEL; and wherein the controller is configured to emit the second laser beam using at least a portion of a third electric charge quantity, which remains after discharging a part of a second electric charge quantity remaining after emitting the first laser beam from the first electric charge quantity.

Also, the controller is configured to measure the distance by: obtaining a first subset and a second subset of the histogram; determining whether the first subset is distorted, based on the first subset including a number of photon detections in time bins corresponding to a predetermined time interval from the emitting timing of the first laser beam, and the second subset including a number of photon detections in time bins corresponding to a predetermined time interval from the emitting timing of the second laser beam; and measuring the distance using the second subset, based on determining whether the first subset is distorted.

Hereafter, a LiDAR device according to the present disclosure is described.

However, the LiDAR device described in the specification may be understood as a concept including various devices that measure distance using a laser, and may be understood as a concept that includes, for example, Light Detection And Ranging (LiDAR), a Time-of-Flight sensor (TOF) sensor, etc., but is not limited thereto.

A LIDAR device is a device for detecting the distance between an object and the LiDAR device (hereinafter, the distance to an object refers to the distance between the object and the LiDAR device) and a relative location of the object with respect to the LiDAR device using a laser. For example, a LiDAR device can emit a laser, and when an emitted laser is reflected from an object, the LiDAR device can measure the distance between the object and the LiDAR device and the location of the object by receiving or sensing the reflected laser. In this case, the distance and location of the object can be expressed through a coordinate system. For example, the distance and location of an object can be expressed in a spherical coordinate system (r, θ, ϕ). However, they are not limited thereto, and can be expressed in coordinate systems such as Cartesian coordinates (X, Y, Z), cylindrical coordinates (r, θ, z), or the like.

Further, in this case, an object may refer to at least one object or at least a portion of the object.

Further, the LiDAR device according to an embodiment can use a laser emitted from the LiDAR device and reflected from the object to measure the distance to the object.

For example, the LiDAR device according to an embodiment can use the Time Of Flight (TOF) of a laser until the laser is sensed after emission to measure the distance to the object.

For a more specific example, the LiDAR device according to an embodiment can measure the distance to an object using the difference between a time value based on the emission time of the emitted laser and the time value based on the sensing time of the laser reflected from the object and then sensed.

In this case, the time value based on the emission time of the laser can be acquired on the basis of a controller included in the LiDAR device according to an embodiment.

For example, the time value based on the emission time of the laser can be acquired on the basis of the generation timing of a trigger signal generated by the controller included in the LiDAR device according to an embodiment, but is not limited thereto.

Further, the time value based on the emission time of the laser can be acquired on the basis of a laser emitting unit included in the LiDAR device according to an embodiment.

For example, the time value based on the emission time of the laser can be acquired by sensing operation of the laser emitting unit included in the LiDAR device according to an embodiment, but is not limited thereto.

In this case, sensing of the operation of the laser emitting unit may refer to sensing of the flow of current in the laser emitting unit, variation in the electric field, etc., but is not limited thereto.

Further, the time value based on the emission time of the laser can be acquired on the basis of a detector unit included in the LiDAR device according to an embodiment.

For example, the time value based on the emission time of the laser can be acquired on the basis of a time value at which the detector unit included in the LiDAR device according to an embodiment senses a laser not reflected from the object, but is not limited thereto.

In this case, a reference optical path for the laser emitted from the laser output unit to be received by the detector unit may be provided, the present disclosure is not limited thereto. For example, among a plurality of laser beams generated by the laser emitting unit and emitted toward the field of view (FOV) at the same time point, some of them are transmitted to the detector unit instead of being emitted outside the LiDAR device, so the exact time point at which the lasers is emitted can be sensed by the detector unit.

Further, the time value based on the sensing time of the laser reflected from the object and then sensed can be acquired on the basis of the detector unit included in the LiDAR device according to an embodiment.

For example, the time value based on the sensing time of the laser reflected from the object and then sensed can be acquired on the basis of a time value at which the detector included in the LiDAR device according to an embodiment senses a laser reflected from the object, but is not limited thereto.

The time length between the emitting timing of a laser emitted from the LiDAR device and the sensing timing of the laser sensed by the detector unit can be the Time of Flight (TOF). That is, since the speed of laser (light) is known with high precision, under the assumption that a laser emitted from the LiDAR device, reflected by an object, and returned back generates the sensing result by the detector unit, the distance between the object and the LiDAR device is calculated on the basis of the already known speed of light and the measured time of flight.

Further, the LiDAR device according to an embodiment may use methods such as the triangulation method, interferometry method, phase shift measurement, etc., in addition to the time of flight to measure the distance to an object, but is not limited thereto.

The LiDAR device according to an embodiment may be installed on a vehicle. For example, a LiDAR device may be installed on the roof, hood, headlamp, bumper, etc. of a vehicle.

The purposes of a plurality of LiDAR devices installed on a vehicle may be the same or may be distinguished from each other.

The range of the field of view of each of the plurality of LiDAR devices installed on a vehicle (for example, the range of the field of view determined with respect to the vehicle) can be determined in accordance with the purposes (i.e., the objectives) of the LiDAR devices.

Further, in accordance with the determined range of the field of view, the installation position of each LiDAR device (where on the vehicle it will be installed), the maximum sensing distance, the minimum sensing distance, the distance resolution, the angular resolution, the vertical sensing range, and the horizontal sensing range, etc., can be determined.

For example, when two LiDAR devices are installed on a vehicle, one LiDAR device is installed on the vehicle for the purpose of observing the front of the vehicle, and the other LiDAR device is installed on the vehicle for the purpose of observing the rear of the vehicle, for the one LiDAR device, the installation position may be determined to be the front part of the vehicle's roof, the vehicle's front lamp, the vehicle's front bumper, etc., the maximum sensing distance may be determined to be 150M to 300M, the minimum sensing distance may be set to be 1M to 5M, the vertical sensing range may be determined to be 10 degrees to 45 degrees, and the horizontal sensing range may be determined to be 10 degrees to 120 degrees. Further, for the other LiDAR device, the installation position may be determined to be the rear part of the vehicle's roof, the vehicle's rear signal lamp, and the vehicle's rear bumper, etc., the maximum sensing distance may be determined to be 50M to 100M, the minimum sensing distance may be determined to be 1M to 5M, the vertical sensing range may be determined to be 10 degrees to 60 degrees, and the horizontal sensing range may be determined to be 30 degrees to 120 degrees. However, the number of LiDAR devices that are installed on a vehicle is not limited to this and may be greater. The purposes of LiDAR devices that are installed on a vehicle was described only for recognizing/sensing the external environment of the vehicle, but, as described below, the purposes of LiDAR device that are installed on a vehicle may also be for recognizing the internal environment of the vehicle, in addition to recognizing the external environment.

Further, according to an embodiment, the field of view of a LiDAR device installed on a vehicle may be directed toward the interior of the vehicle. For example, the field of view of a LiDAR device installed on a vehicle may be pre-set to recognize gestures of a driver during driving. That is, the installation position of a LiDAR device and the optical system of the LiDAR device may be pre-set to facilitate monitoring of the driver's gestures. As another example, the field of view of a LiDAR device installed on a vehicle may be pre-set to recognize the driver's face. That is, the installation position of LiDAR devices and the optical system of the LiDAR devices may be pre-set to facilitate monitoring of the driver's gestures. In this case, the LiDAR devices installed on the vehicle may be installed on the exterior of the vehicle (i.e., the vehicle's exterior) or in the interior of the vehicle (i.e., the vehicle's interior).

The LiDAR device according to an embodiment may be installed on an unmanned aerial vehicle. For example, the LiDAR device may be installed on a UAV System, a drone, a Remote Piloted Vehicle (RPV), an Unmanned Aerial Vehicle System (UAVS), an Unmanned Aircraft System (UAV), a Remote Piloted Air/Aerial Vehicle (RPAV), a Remote Piloted Aircraft System (RPAS), or the like.

Further, a plurality of LiDAR devices according to an embodiment may be installed on an unmanned aerial vehicle. For example, when two LiDAR devices are installed on an unmanned aerial vehicle, one LiDAR device may be for observing the front, and the other may be for observing the rear, but they are not limited thereto. Further, when two LiDAR devices are installed on an unmanned aerial vehicle, one LiDAR device may be for observing the left, and the other may be for observing the right, but they are not limited thereto.

The LiDAR device according to an embodiment may be installed on a robot. For example, LiDAR devices may be installed on personal robots, professional robots, public service robots, other industrial robots, manufacturing robots, or the like.

Further, according to some embodiments, a plurality of LiDAR device may be installed on a robot.

The purposes of a plurality of LiDAR devices installed on a robot may be the same or may be distinguished from each other.

The range of the field of view of each of the plurality of LiDAR devices installed on a robot (for example, the range of the field of view determined with respect to the robot) can be determined in accordance with the purposes (i.e., the objectives) of the LiDAR devices.

Further, in accordance with the determined range of the field of view, the installation position of each LiDAR device (where on the robot it will be installed), the maximum sensing distance, the minimum sensing distance, the distance resolution, the angular resolution, the vertical sensing range, and the horizontal sensing range, etc., can be determined.

For example, when two LiDAR devices are installed on a robot, one LiDAR device may be for observing the front, and the other may be for observing the rear, but they are not limited thereto. Further, when two LiDAR devices are installed on a robot, one LiDAR device may be for observing the left, and the other may be for observing the right, but they are not limited thereto.

Further, the LiDAR device according to an embodiment may be installed on a robot. For example, LiDAR devices are installed on robots, they may be for observing the face of human, but are not limited thereto.

Further, the LiDAR device according to an embodiment may be installed for industrial security. For example, LiDAR devices may be installed in smart factories for industrial security.

Further, a plurality of LiDAR devices according to an embodiment may be installed in a smart factory for industrial security. For example, when two LiDAR devices are installed in a smart factory, one LiDAR device may be for observing the front, and the other may be for observing the rear, but they are not limited thereto. Further, when two LiDAR devices are installed in a smart factory, one LiDAR device may be for observing the left, and the other may be for observing the right, but they are not limited thereto.

Further, the LiDAR device according to an embodiment may be installed for industrial security. For example, LiDAR devices are installed for industrial security, they may be for observing human face, but are not limited thereto.

Meanwhile, in the present disclosure, for convenience of explanation, the terms “scan cycle” and “cycle” may be used interchangeably. However, unless otherwise specified in the present disclosure, the terms “scan cycle” and “cycle” should be construed as having the same meaning.

Further, in the present disclosure, for convenience of explanation, the terms “detector device” and “detecting device” may be used interchangeably. However, unless otherwise specified in the present disclosure, the “detector device” and “detecting device” should be construed as having the same meaning. In other words, both the “detector device” and “detecting device” may be photon detecting devices included in the detector unit. For example, the detector unit may include a plurality of detecting units, the plurality of detecting units each may include a plurality of photon detecting devices, and in the present disclosure, the photon detecting device may be referred to as a “detector device” or a “detecting device”. For example, the “detector device” and “detecting device” may be Single Photon Avalanche Diodes (SPAD). However, as in the example to be described below, the “detector device” and “detecting device” may be photon detecting devices other than SPADs.

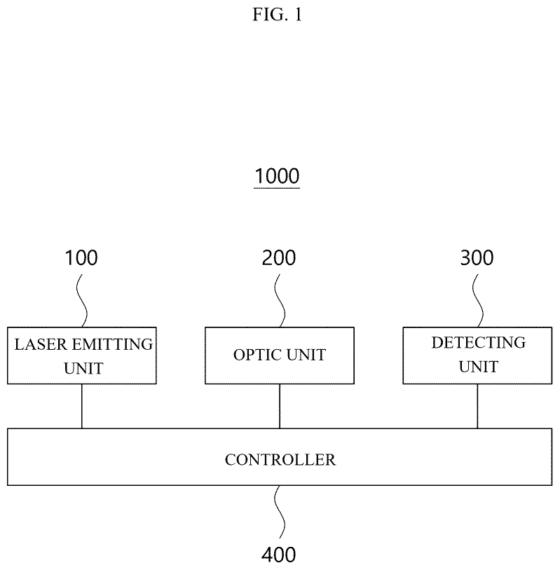

FIG. 1 is a diagram illustrating a LiDAR device according to an embodiment.

Referring to FIG. 1, a LiDAR device 1000 according to an embodiment may include a laser emitting unit 100.

In this configuration, the laser emitting unit 100 according to an embodiment can generate or emit a laser.

Further, the laser emitting unit 100 according to an embodiment may include one or more laser emission element.

For example, the laser emitting unit 100 according to an embodiment may include one laser emission element and may include a plurality of laser emission elements.

Further, the laser emitting unit 100 according to an embodiment may be configured as an array in which a plurality of laser emission elements is arranged in the form of an array, but is not limited thereto.

For example, the laser emitting unit 100 according to an embodiment may be implemented as a Vertical Cavity Surface Emitting Laser (VCSEL) array in which a plurality of VSCELs is arranged in the form of an array.

Further, the laser emitting unit 100 according to an embodiment may include laser emission elements such as a Laser Diode (LD), a solid-state laser, a high power laser, a Light Emitting Diode (LED), a Vertical Cavity Surface Emitting Laser (VCSEL), an External Cavity Diode Laser (ECDL), etc., but is not limited thereto.

Further, the wavelength of the laser emitted from the laser emitting unit 100 according to an embodiment may be within a specific wavelength range.

For example, the wavelength of the laser emitted from the laser emitting unit 100 according to an embodiment may be within the 905 nm band, the 940 nm band, or the 1550 nm band, but is not limited thereto.

In this case, the band of the wavelength may be a band within a predetermined range on the basis of a central wavelength.

For example, the 905 nm band may refer to a band within 10 nm difference from 905 nm, the 940 nm band may refer to a band within 10 nm difference from 940 nm, and the 1550 nm band may refer to a band within 10 nm difference from 1550 nm, but the present disclosure is not limited thereto.

Further, the wavelength of the laser emitted from the laser emitting unit 100 according to an embodiment may be within various wavelength ranges.

For example, the wavelength of a first laser emitted from a first laser emission element included in the laser emitting unit 100 according to an embodiment may be within the 905 nm band, and the wavelength of a second laser emitted from a second laser emission element included in the laser emitting unit 100 according to an embodiment may be within the 1550 nm band, but the present disclosure is not limited thereto.

Further, the wavelengths of the lasers emitted from the laser emitting unit 100 according to an embodiment may be within a specific wavelength range and may be different from each other.

For example, the wavelength of the first laser emitted from the first laser emission element included in the laser emitting unit 100 according to an embodiment may be within the 940 nm band and may be 939 nm, and the wavelength of the second laser emitted from the second laser emission element included in the laser emitting unit 100 according to an embodiment may be within the 940 nm band and may be 943 nm, but the present disclosure is not limited thereto.

Referring to FIG. 1 again, a LiDAR device 1000 according to an embodiment may include an optic unit 200.

In this configuration, the optic unit may be expressed in various ways such as a steering unit, a scanning unit, etc., for explaining the present disclosure, but is not limited thereto.

The optic unit 200 according to an embodiment can function to change the flight path of a laser. The optic unit 200 may be designed to change (steer) the direction of a laser generated by the laser emitting unit 100 to a preset direction before the generated laser is emitted to the outside of the LiDAR device. Further, the optic unit 200 may be designed to change the optical path of the laser entering the LiDAR device from the outside to a preset direction so that the entering laser can be sensed by the detector unit 300.

For example, the optic unit 200 according to an embodiment can function to change the flight path of a laser emitted from the laser emitting unit 100, and when a laser emitted from the laser emitting unit 100 is reflected from an object, the optic unit 200 can function to change the flight path of the laser reflected from the object, but is not limited thereto.

Further, according to some embodiments, the optic unit 200 may include an optical element or an optical means that reflects light. For example, the optic unit 200 may include a mirror. That is, the optic unit 200 may include an optical element that reflects light to change the flight path (or optical path) of a laser.

For example, the optic unit 200 according to an embodiment can function to change the flight path of a laser emitted from the laser emitting unit 100 by reflecting the laser, and when a laser emitted from the laser emitting unit 100 is reflected from an object, the optic unit 200 can function to change the flight path by reflecting the laser reflected from the object, but is not limited thereto.

In this configuration, the optical element or optical means that reflects light may be one of a mirror, a resonance scanner, a MEMS mirror, a Voice Coil Mirror (VCM), a polygonal mirror, a rotating mirror, or a galvanic mirror. However, the optical element or optical means that reflects light is only an example, and other than the optical means, the optic unit 200 may include other types of optical elements as long as the optical elements have the function capable of reflecting light.

In addition, the optic unit 200 may include one or both of the optical element or the optical means that reflects light, if necessary, but the optic unit 200 does not necessarily include the optical element or the optical means that reflects light.

Further, according to some embodiments, the optic unit 200 may include an optical element or an optical means that refracts light. For example, the optic unit 200 may include a lens. That is, the optic unit 200 may include an optical element that refracts light to change the flight path (or optical path) of a laser.

For example, the optic unit 200 according to an embodiment can function to change the flight path of a laser emitted from the laser emitting unit 100 by refracting the laser, and when a laser emitted from the laser emitting unit 100 is reflected from an object, the optic unit 200 can function to change the flight path by refracting the laser reflected from the object, but is not limited thereto.

The optical element that refracts light may be one of a lens, a prism, a micro lens, a Microfluidic lens, or a metasurface. However, the optical element or optical means that refracts light is only an example, and other than the optical means, the optic unit 200 may include other types of optical elements as long as the optical elements have the capability of refracting light.

In addition, the optic unit 200 may include one or both of the optical element or the optical means that refracts light, if necessary, but the optic unit 200 does not necessarily include the optical element or the optical means that refracts light.

Further, the optic unit 200 according to an embodiment can change the flight path of a laser by changing the phase of the laser.

For example, the optic unit 200 according to an embodiment may be designed to change a flight path by changing the phase of a laser generated by the laser emitting unit 100 to a preset phase before the generated laser is emitted to the outside of the LiDAR device. Further, the optic unit 200 may be designed to change a flight path by changing the phase of the laser entering the LiDAR device from the outside to a preset phase so that the entering laser can be sensed by the detector unit 300.

In this configuration, the optical element that changes the phase of the laser may be one of an Optical Phased Array (OPA), a meta lens, or a metasurface. However, the optical element or optical means that changes the phase of a light is only an example, and other than the optical means, the optic unit 200 may include other types of optical elements as long as the optical elements have the capability of reflecting light.

In addition, the optic unit 200 may include one or both of the optical element or the optical means that reflects light, if necessary, but the optic unit 200 does not necessarily include the optical element or the optical means that reflects light.

Further, the optic unit 200 according to an embodiment may include two or more optic units (or sub-optic units).

For example, the optic unit 200 according to an embodiment may include a transmitting optic unit for directing a laser, which is emitted from the laser emitting unit 100 according to an embodiment, to a scan area of the LiDAR device and a receiving optic unit for transmitting a laser reflected from an object to the detector unit 300, but is not limited thereto.

Further, the optic unit 200 according to an embodiment may include a first optic unit or changing the flight path of a laser emitted from the laser emitting unit 100 to a direction of a first group, and a second optic unit for changing the flight path of a laser emitted from the laser emitting unit 100 to a direction of a second group, but is not limited thereto.

The optical characteristics of the optic unit 200 should be determined on the basis of at least one or more requirements among a field of view, a maximum sensing distance, a minimum sensing distance, a horizontal sensing range, and a vertical sensing range that should be determined appropriately for the purpose (or application) of the LiDAR device. The optic unit 200 may be designed using the various optical elements to meet the requirements of the LiDAR device described above. Accordingly, the optic unit 200 may be designed to include one type of optical element among the optical element that reflects light, the optical element that refracts light, and the optical element that changes the phase of light, or a combination of two or more types thereof, and the number of each type of optical element may also be determined to have an appropriate number of optical elements in accordance with the requirements.

Referring to FIG. 1 again, the LiDAR device 1000 according to an embodiment may include a detector unit 300.

In this configuration, the detector unit may be expressed in various ways such as light receiving unit, a receiving unit, a sensor unit, etc., for explaining the present disclosure, but is not limited thereto.

The detector unit 300 according to an embodiment has a function of sensing light. The detector unit 300, for example, can sense light entering the detector unit 300 and output an electrical signal corresponding thereto.

According to some embodiments, the detector unit 300 can sense a laser reflected from an object located in the scan area of the LiDAR device 1000 according to an embodiment. However, when the detector unit 300 senses all light that enters the detector unit 300 (all light having a specific wavelength when the LiDAR device is configured to include an optical filter that selectively transmits light of the specific wavelength), and does not selectively sense only a laser reflected from an object.

Further, the detector unit 300 according to an embodiment may be disposed to receive a laser and can function to generate an electrical signal on the basis of the received laser.

For example, the detector unit 300 according to an embodiment may be disposed to receive a laser reflected from an object located in the scan area of the LiDAR device 1000 according to an embodiment and can generate an electrical signal on the basis of the received laser.

In this configuration, the detector unit 300 according to an embodiment may be disposed to receive a laser reflected from an object located in the scan area of the LiDAR device 1000 according to an embodiment through at least one optical means, and the at least one optical means may be included in the optic unit described above and may include an optical filter or the like, but is not limited thereto.

Further, the detector unit 300 according to an embodiment can create sensing information of a laser on the basis of the generated electrical signal. As described above, when the detector unit 300 does not selectively detect only a laser reflected from an object, but detects all light entering the detector unit 300 (all light having a specific wavelength when the LiDAR device is configured to include an optical filter that selectively transmits light of the specific wavelength). Accordingly, in order to achieve the original purpose of the LiDAR device, information about a laser reflected from an object should be selectively acquired by interpreting an electrical signal generated by the detector unit 300. To this end, the detector unit 300 may have a signal interpretation function capable of interpreting the generated electrical signal.

In order to interpret information about a laser reflected from an object, the detector unit 300 can adopt various signal interpretation methods.

For example, the detector unit 300 can create sensing information of a laser by comparing a predetermined threshold value with the rising edge, falling edge, or the midpoint of the rising edge and falling edge of a generated electrical signal, but is not limited thereto.

Further, for example, the detector unit 300 can create histogram data corresponding to the sensing information of a laser on the basis of the generated electrical signal, but is not limited thereto.

Further, the detector unit 300 according to an embodiment can determine a sensing timing of a laser on the basis of sensing information of a generated laser. The sensing timing of a laser is used to determine the flight time of the laser described above. As already known, the speed of light is very fast, so even a very small range of errors that may occur at the sensing timing of a laser can cause an error in the flight time of a laser, and such an error can incur a very large error in the distance between an object and a LiDAR device.

For example, the detector unit 300 according to an embodiment can determine a sensing timing of a laser on the basis of sensing information of a generated laser created on the basis of a rising edge of a generated electrical signal, can determine a sensing timing of a laser on the basis of sensing information of a laser created on the basis of a falling edge of a generated electrical signal, and can determine a sensing timing of a laser on the basis of sensing information of a laser created on the basis of a rising edge of a generated electrical signal and sensing information of a laser created on the basis of a falling edge, but is not limited thereto.

Further, for example, the detector unit 300 can determine a sensing timing of a laser on the basis of histogram data created on the basis of a generated electrical signal, but is not limited thereto.

To give a more specific example, the detector unit 300 according to an embodiment can determine a sensing timing of a laser on the basis of determination of the peak of the created histogram data, and a rising edge and a falling edge based on a predetermined value, etc., but is not limited thereto.

In this case, the histogram data may be created on the basis of an electrical signal generated from the detector unit 300 according to an embodiment over at least one or more scan cycles.

Further, the detector unit 300 according to an embodiment may be implemented using various electro-optical devices that receive photons and output corresponding electrical signals.

The electro-optical devices may include a PN photo diode, a photo transistor, a PIN photo diode, an Avalanche Photodiode (APD), a Single-Photon Avalanche Diode (SPAD), Silicon PhotoMultipliers (SiPM), a comparator, a Complementary Metal-Oxide-Semiconductor (CMOS), or a Charge Coupled Device (CCD). The detector unit 300 may be implemented using one or a combination of the exemplary electro-optical devices described above. However, the detector unit 300 may be implemented using electro-optical devices other than the exemplary electro-optical devices if they are optical devices that generate an electrical signal by sensing light.

Further, the detector unit 300 according to an embodiment may include one or more electro-optical devices (hereafter, referred to as detector devices).

For example, the detector unit 300 according to an embodiment may include a single detector device and may include a plurality of detector devices.

Further, the detector unit 300 according to an embodiment may be configured as an array in which a plurality of detector devices is arranged in the form of an array, but is not limited thereto.

For example, For example, the detector unit 300 may be implemented as a SPAD array, in which a plurality of Single Photon Avalanche Diodes (SPAD) is arranged in an array, but is not limited thereto.

Referring to FIG. 1 again, the LiDAR device 1000 according to an embodiment may include a controller 400.

In this configuration, the controller may be expressed in various ways such as a control unit, etc., for explaining the present disclosure, but is not limited thereto.

The controller 400 according to an embodiment can control the operation of the laser emitting unit 100, the optic unit 200, or the detector unit 300.

Further, the controller 400 according to an embodiment can control the operation of the laser emitting unit 100.

For example, the controller 400 can control the emitting timing of a laser that is emitted from the laser emitting unit 100. Further, the controller 400 can control the power of a laser that is emitted from the laser emitting unit 100. Further, the controller 400 can control the pulse width of a laser that is emitted from the laser emitting unit 100. Further, the controller 400 can control the cycle of a laser that is emitted from the laser emitting unit 100. Further, when the laser emitting unit 100 includes a plurality of laser emission elements, the controller 400 can select some of the plurality of laser emission elements and control the laser emitting unit 100 such that only the selected laser emission elements operate selectively. In this case, the meaning of the laser emission elements operating can be interpreted as enabling a laser to be emitted from the laser emission elements.

Further, the controller 400 according to an embodiment can control the operation of the optic unit 200. The optic unit 200, as described above, includes an optical element or an optical means. In this case, for some optical elements, optical characteristics of the optical elements, relative positions of the optical elements, movements of the optical elements, etc. may need to be controlled. In this case, the controller 400 can control the operation of the optic unit 200.

For example, the controller 400 can control the operation speed of the optic unit 200. In detail, when the optic unit 200 includes a rotating mirror, the rotation speed of the rotating mirror may be controlled, and when the optic unit 200 includes a MEMS mirror, a repetition cycle of the MEMS mirror may be controlled, but the present disclosure is not limited thereto.

Further, the controller 400 can control the operation degree of the optic unit 200. In detail, when the optic unit 200 includes a MEM mirror, it is possible to control the operation angle of the MEM mirror, but the present disclosure is not limited thereto.

Further, the controller 400 according to an embodiment can control the operation of the detector unit 300.

For example, the controller 400 can control the sensitivity of the detector unit 300. In detail, the controller can control the sensitivity of the detector unit 300 by adjusting a predetermined threshold value, but the present disclosure is not limited thereto.

Further, the controller 400 can control the operation of the detector unit 300. In detail, the controller 400 control On/Off of the detector unit 300, and when the detector unit 300 includes a plurality of detector devices, the controller 400 can select some of the plurality of detector devices and control the operation of the detector unit 300 such that only the selected detector devices operate selectively. In this case, the controller 400 can control the detector unit 300 such that the detector devices that are not selected do not operate. In this case, the detector devices being inactive may not only mean that no electrical input is provided to the detector devices such that they cannot output an electrical signal even if light is received, but may also mean that an electrical signal output by the detector devices in response to the reception of light is not interpreted.

Further, the controller 400 according to an embodiment can create sensing information of a laser on the basis of an electrical signal generated from the detector unit 300. That is, interpretation of an electrical signal created and output by the detector unit 300 may be performed by the detector unit 300, but may be performed by the controller 400.

For example, the controller 400 according to an embodiment can create sensing information of a laser by comparing a predetermined threshold value with the rising edge, falling edge, or the midpoint of the rising edge and falling edge of an electrical signal generated from the detector unit 300, but is not limited thereto.

Further, for example, the controller 400 according to an embodiment can create histogram data corresponding to the sensing information of a laser on the basis of an electrical signal generated from the detector unit 300, but is not limited thereto.

Further, the controller 400 according to an embodiment can determine a sensing timing of a laser on the basis of sensing information of sensing information of a laser generated from the detector unit 300.

For example, the controller according to an embodiment can determine a sensing timing of a laser on the basis of sensing information of a laser created on the basis of a rising edge of an electrical signal generated from the detector unit 300, can determine a sensing timing of a laser on the basis of sensing information of a laser created on the basis of a falling edge of a generated electrical signal, and can determine a sensing timing of a laser on the basis of sensing information of a laser created on the basis of a rising edge of a generated electrical signal and sensing information of a laser created on the basis of a falling edge, but is not limited thereto.

Further, for example, the controller 400 according to an embodiment can determine a sensing timing of a laser on the basis of histogram data created on the basis of an electrical signal generated from the detector unit 300, but is not limited thereto.

To give a more specific example, the controller 400 according to an embodiment can determine a sensing timing of a laser on the basis of determination of the peak of the histogram data created from the detector unit 300, and a rising edge and a falling edge based on a predetermined value, etc., but is not limited thereto.

In this case, the histogram data may be created on the basis of an electrical signal generated from the detector unit 300 according to an embodiment over at least one or more scan cycles.

Further, the controller 400 according to an embodiment can acquire distance information to an object on the basis of the determined sensing timing of a laser.

For example, the controller 400 according to an embodiment can acquire distance information to an object on the basis of the determined emitting timing of a laser and the determined sensing timing of a laser, but is not limited thereto.

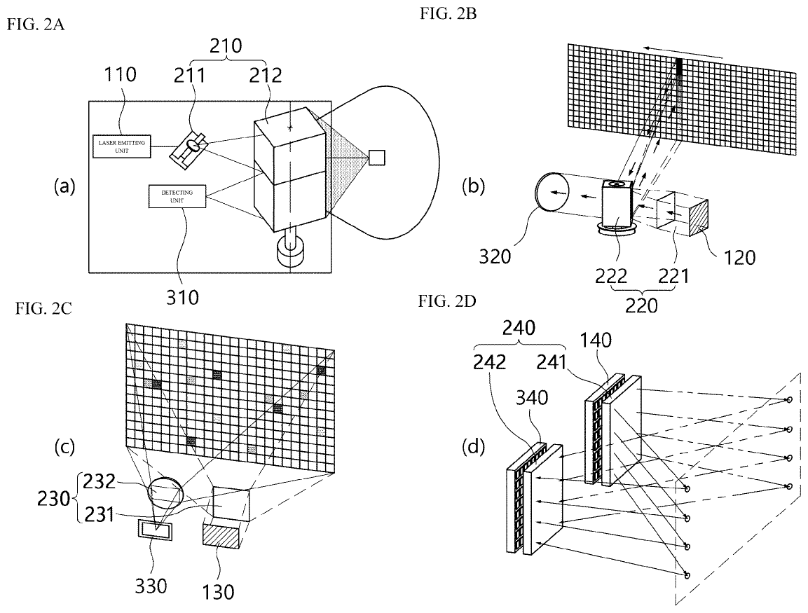

FIGS. 2A through 2D are diagrams showing various embodiments of a LiDAR device.

Referring to FIG. 2A, a LiDAR device according to an embodiment may include a laser emitting unit 110, an optic unit 210, and a detector unit 310, in which the optic unit 210 may include a nodding mirror 211 that nods within a predetermined range and a multi-faceted mirror 212 that rotates around at least one axis, but the present disclosure is not limited thereto.

In this configuration, since the above descriptions regarding the laser emitting unit 110, the optic unit 210, and the detector unit 310 can be applied, repetitive descriptions are omitted, and FIG. 2A is a simplified diagram illustrating one of various embodiments of a LiDAR device. Various embodiments of a LiDAR device are not limited to FIG. 2A.

Further, referring to FIG. 2B, a LiDAR device according to an embodiment may include a laser emitting unit 120, an optic unit 220, and a detector unit 320, in which the optic unit 220 may include at least one lens 221, which can collimate and steer a laser emitted from the laser emitting unit 120, and a multi-faceted mirror 222 that rotates around at least one axis, but the present disclosure is not limited thereto.

In this configuration, since the above descriptions regarding the laser emitting unit 120, the optic unit 220, and the detector unit 320 can be applied, repetitive descriptions are omitted, and FIG. 2B is a simplified diagram illustrating one of various embodiments of a LiDAR device. Various embodiments of a LiDAR device are not limited to FIG. 2B.

Further, referring to FIG. 2C, a LiDAR device according to an embodiment may include a laser emitting unit 130, an optic unit 230, and a detector unit 330, in which the optic unit 230 may include at least one lens 231, which can collimate and steer a laser emitted from the laser emitting unit 130, and at least one lens 232 that transmits a laser reflected from an object to the detector unit 330, but the present disclosure is not limited thereto.

In this configuration, since the above descriptions regarding the laser emitting unit 130, the optic unit 230, and the detector unit 330 can be applied, repetitive descriptions are omitted, and FIG. 2C is a simplified diagram illustrating one of various embodiments of a LiDAR device. Various embodiments of a LiDAR device are not limited to FIG. 2C.

Further, referring to FIG. 2D, a LiDAR device according to an embodiment may include a laser emitting unit 140, an optic unit 240, and a detector unit 340, in which the optic unit 240 may include at least one lens 241, which can collimate and steer a laser emitted from the laser emitting unit 130, and at least one lens 242 that transmits a laser reflected from an object to the detector unit 340, but the present disclosure is not limited thereto.

In this configuration, since the above descriptions regarding the laser emitting unit 140, the optic unit 240, and the detector unit 340 can be applied, repetitive descriptions are omitted, and FIG. 2D is a simplified diagram illustrating one of Various embodiments of a LiDAR device. Various embodiments of a LiDAR device are not limited to FIG. 2D.

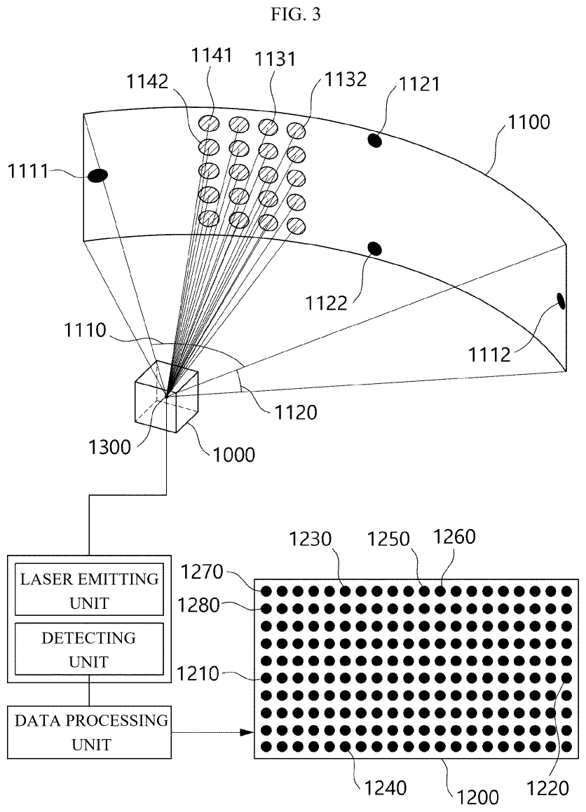

FIG. 3 is a diagram illustrating the operation of a LiDAR device according to an embodiment and LiDAR data.

Referring to FIG. 3, a LiDAR device 1000 according to an embodiment includes a laser emitting unit for emitting a laser and a detector unit for detecting a laser, and the laser emitting unit and the detector unit have been described above, so repetitive descriptions are omitted.

Further, referring to FIG. 3, a data processing unit according to an embodiment can acquire LiDAR data 1200 on the basis of a laser detected by the LiDAR device 1000.

In this configuration, the data processing unit may be included in the LiDAR device 1000 and may be included in the controller of the LiDAR device 1000 described above, but is not limited thereto. If the data processing unit is connected to the LiDAR device 1000 through at least one communication method and is able to acquire signals generated from the detector unit included in the LiDAR device 1000, it may be implemented independently from the controller 400 of the LiDAR device 1000. Alternatively, if the data processing unit is connected to the LiDAR device 1000 through at least one communication method and is able to acquire signals generated from the detector unit included in the LiDAR device 1000, it may be positioned outside the LiDAR device 1000.

Further, referring to FIG. 3, the LiDAR device 1000 according to an embodiment can form a field of view 1100 by emitting lasers, and can acquire LiDAR data 1200 by sensing lasers reflected within the field of view 1100.

In this case, the field of view 1100 of the LiDAR device 1000 refers to the area to which lasers are emitted or the area in which the location of an object can be effectively sensed by the LiDAR device 1000.

Further, the LiDAR data 1200 may refer to various types of data acquired from the LiDAR device 1000, and for example, may refer to point data, point cloud, frame data, etc. that are acquired from the LiDAR device 1000, but is not limited thereto.

In this case, the point data may be data including distance information, location information, etc., and the point cloud may refer to cluster data of the point data, but they are not limited thereto.

Further, the frame data may refer to a group of the point data, but is not limited thereto.

The field of view 1100 of the LiDAR device 1000 is defined by a maximum sensing distance, a minimum sensing distance, a horizontal scan range 1110 (horizontal sensing range, hereinafter referred to as a horizontal angular range), and a vertical scan range 1120 (vertical sensing range, hereinafter referred to as a vertical angular range).

Further, the horizontal angular range 1110 and the vertical angular range 1120 may be defined by a plurality of lasers emitted by the LiDAR device 1000.

For example, the horizontal angular range 1110 of the LiDAR device 1000 may be defined by the horizontal angle between a first laser 1111 directed at the far-left and a second laser 1112 directed at the far-right. In more detail, the horizontal angular range 1110 may be defined as the difference between the horizontal angle of the first laser 1111 (i.e., a ϕ value, hereafter, first angle) defined in a spherical coordinate system set on the basis of the virtual optical origin of the LiDAR device and the horizontal angle of the second laser 1112 (i.e., a ϕ value, hereafter, second angle) defined in the spherical coordinate system.

Further, for example, the vertical angular range 1120 of the LiDAR device 1000 can be defined by the vertical angle between a third laser 1121 directed at the uppermost direction and a fourth laser 1122 directed at the lowermost direction. In more detail, the vertical angular range 1120 may be defined as the difference between the angle of the third laser 1121 (i.e., a θ value, hereafter, third angle) defined in a spherical coordinate system set on the basis of the virtual optical origin of the LiDAR device and the angle of the fourth laser 1122 (i.e., a θ value, hereafter, fourth angle) defined in the spherical coordinate system set on the basis of the virtual optical origin of the LiDAR device.

However, the definitions of the horizontal angular range 1110 the vertical angular range 1120 of the LiDAR device 1000 are not limited to the examples described above, and they can be defined by various methods for representing the area to which lasers are emitted from the LiDAR device 1000.

Further, the horizontal angular range 1110 the vertical angular range 1120 may be defined by sensed lasers. In more detail, the horizontal angular range 1110 the vertical angular range 1120 may be defined by point data created by sensed lasers.

For example, the horizontal angular range 1110 of the LiDAR device 1000 may be defined by first point data 1210 and second point data 1220, and more specifically, may be defined by a laser emission angle corresponding to the first point data 1210 and a laser emission angle corresponding to the second point data 1220, but is not limited thereto.

Further, for example, the vertical angular range 1120 of the LiDAR device 1000 may be defined by third point data 1230 and fourth point data 1240 and, more specifically, may be defined by a laser emission angle corresponding to the third point data 1230 and a laser emission angle corresponding to the fourth point data 1240, but is not limited thereto.

However, the definitions of the horizontal angular range 1110 the vertical angular range 1120 of the LiDAR device 1000 are not limited to the examples described above, and they can be defined by various methods for representing the area in which the LiDAR device 1000 can sense lasers.

Meanwhile, though not clearly shown in the figures, the field of view (FOV) can be further defined by the maximum sensing distance and the minimum sensing distance that can be sensed by the LiDAR.

Further, referring to FIG. 3, the lasers forming the field of view 1100 of the LiDAR device 1000 according to an embodiment can be emitted to have an angular resolution.

In this case, the angular resolution may include a horizontal angular resolution for the resolution in the horizontal direction and a vertical angular resolution for the resolution in the vertical direction.

Further, the horizontal angular resolution and the vertical angular resolution may be defined by a plurality of emitted lasers.

For example, the horizontal angular resolution of the LiDAR device 1000 may be defined by the horizontal angle between a fifth laser 1131 and a sixth laser 1132 adjacent to the fifth laser 1131 in the horizontal direction. In more detail, the horizontal angular resolution may be defined as the difference between the horizontal angle of the fifth laser 1131 (hereafter, fifth angle) defined in a spherical coordinate system set on the basis of the virtual optical origin of the LiDAR device and the horizontal angle of the sixth laser 1132 (hereafter, sixth angle) defined in the spherical coordinate system set on the basis of the virtual optical origin of the LiDAR device.

Further, for example, the vertical angular resolution of the LiDAR device 1000 may be defined by the vertical angle between a seventh laser 1141 and an eighth laser 1142 adjacent to the seventh laser 1141 in the vertical direction. In more detail, the vertical angular resolution may be defined as the difference between the vertical angle of the seventh laser 1141 (hereafter, seventh angle) defined in a spherical coordinate system set on the basis of the virtual optical origin of the LiDAR device and the vertical angle of the eighth laser 1142 (hereafter, eighth angle) defined in the spherical coordinate system set on the basis of the virtual optical origin of the LiDAR device, but is not limited thereto.

However, the definitions of the horizontal angular resolution and the vertical angular resolution of the LiDAR device 1000 are not limited to the examples described above, and may be defined by various methods for representing angular resolutions capable of distinguishing a sensing target object.

Further, referring to FIG. 3, the LiDAR data 1200 acquired from the LiDAR device 1000 according to an embodiment may include pointer data having an angular resolution.

In this case, the angular resolution may include a horizontal angular resolution for the resolution in the horizontal direction and a vertical angular resolution for the resolution in the vertical direction.

Further, the horizontal angular resolution and the vertical angular resolution may be defined by sensed lasers. In more detail, the horizontal angular resolution and the vertical angular resolution may be defined by point data created by sensed lasers.

For example, the horizontal angular resolution of the LiDAR device 1000 may be defined by fifth point data 1250 and sixth point data 1260, and more specifically, may be defined by a laser emission angle corresponding to the fifth point data 1250 and a laser emission angle corresponding to the sixth point data 1260, but is not limited thereto.

For example, the vertical angular resolution of the LiDAR device 1000 may be defined by seventh point data 1270 and eighth point data 1280, and more specifically, may be defined by a laser emission angle corresponding to the seventh point data 1270 and a laser emission angle corresponding to the eighth point data 1280, but is not limited thereto.

However, the definitions of the horizontal angular resolution and the vertical angular resolution of the LiDAR device 1000 are not limited to the examples described above, and may be defined by various methods for representing angular resolutions capable of distinguishing a sensing target object.

Further, a plurality of lasers that is emitted from the LiDAR device 1000 each may have a size and a divergence angle.

The size of a laser may be defined on the basis of the shape of the image of the laser formed on a surface located at an arbitrary distance from the LiDAR device. For example, when the shape of the image of laser is a circle-like shape, the size of the laser may be defined on the basis of a general method for defining the size of the circle. That is, the size of the laser can be defined by the area of the circle, or the size of the laser can be defined by the radius or diameter of the circle.

In some embodiments, the shape of the image of laser may be an ellipse-like shape. In this case, the size of the laser may be defined by the length of the major axis and the length of the minor axis of the ellipse.

In this case, the divergence angle of the laser can be determined on the basis of the distance between the arbitrary surface and the LiDAR device, and the size of the laser. Alternatively, the divergence angle of the laser may be determined on the basis of the size of the image of the laser formed on two or more surfaces.

Meanwhile, the vertical divergence angle of the laser may be the same as the horizontal divergence angle of the laser, but they may also differ.

Further, the point data included in the LiDAR data 1200 each may include distance information.

Further, an optical origin 1300 may be defined with respect to the LiDAR device 1000.

In this case, the optical origin 1300 may refer to the origin of a coordinate system for representing the LiDAR data described above.

Further, the optical origin 1300 may refer to the origin defined under the assumption that lasers that are emitted from the LiDAR device 1000 are emitted from one point.

Further, the optical origin 1300 may refer to the origin of distance measurement for measuring distance using a laser by the LiDAR device 1000.

Further, the optical origin 1300 may refer to the origin for describing point data acquired by the LiDAR device 1000.

Further, the optical origin 1300 may refer to a physically derived optical origin, but it is not limited thereto, and may also refer to an artificially assigned optical origin with respect to the LiDAR device 1000, but it is not limited thereto.

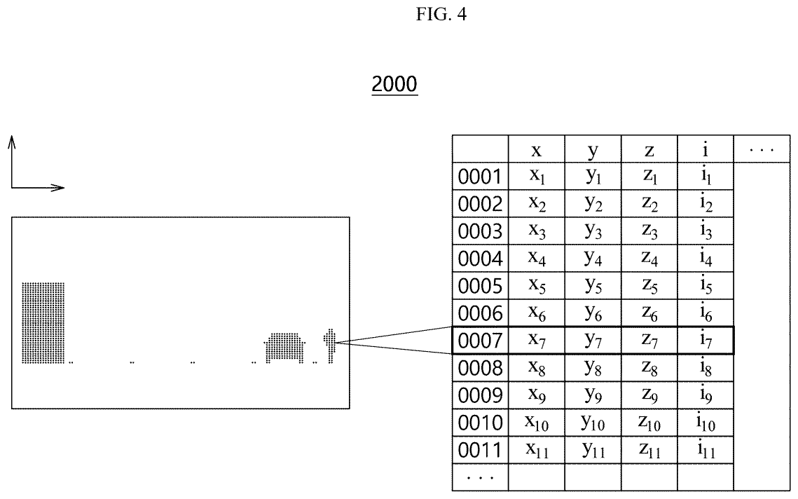

FIG. 4 is a diagram illustrating LiDAR data according to an embodiment.

LiDAR data according to an embodiment may be represented in various formats such as a point cloud, a depth map, and an intensity map.

In this case, the point cloud may be a format in which the information of each measurement point is converted into positional information, and the point cloud according to an embodiment may include position coordinate values x, y, and z and intensity value I, which are acquired on the basis of the angle information and distance information at which a laser is emitted or acquired, but is not limited thereto.

Further, in this case, the depth map may be a format that includes two-dimensional pixel position information and distance information for each measurement point, and the depth map according to an embodiment may include pixel values x and y and a distance value D, which are acquired on the basis of the angle information at which a laser is emitted or acquired, but is not limited thereto.

Further, the intensity map may be a format that includes two-dimensional pixel position information and intensity information for each measurement point, and the intensity map according to an embodiment may include pixel values x and y and an intensity value I, which are acquired on the basis of the angle information at which a laser is emitted or acquired, but is not limited thereto.

Further, in addition to the examples described above, LiDAR data may be acquired in various formats, but, for the convenience of explanation, the following description will be based on LiDAR data acquired in the format of a point cloud.

Referring to FIG. 4, LiDAR data according to an embodiment may include point cloud data 2000.

Further, the point cloud data 2000 according to an embodiment may include a plurality of point data. In other words, the point cloud data 2000 may be a point data set that includes a plurality of point data.

Further, a plurality of point data according to an embodiment each may include position coordinate values x, y, and z and an intensity value i, but is not limited thereto.

A method of determining position coordinates of point data is briefly explained for better understanding. A plurality of laser emission directions determined within the field of view (FOV) of the LiDAR device 1000 described above may correspond to the laser emission elements (e.g., VCSELs), respectively. That is, the laser emission direction of each of the laser emission elements, with respect to the optical origin, may be defined by the horizontal angle ϕ and the vertical angle θ in a spherical coordinate system. In this case, the flight time of a laser and the intensity of sensed light may be acquired on the basis of electrical emission information detected by the detector elements corresponding to the laser emission elements, respectively. The flight time, as described above, can be converted into distance, and the distance can be converted into an r-value in a spherical coordinate system with respect to the optical origin. That is, the location of an object sensed by a plurality of lasers or a reflective surface that is at least a portion of an object can be represented by spherical coordinates (r, θ, q) defined by the horizontal angle, vertical angle, and distance value in the spherical coordinate system. Of course, the spherical coordinates described above can be converted into Cartesian coordinates (x, y, z).

That is, the position coordinate values included in each of the plurality of point data can be acquired on the basis of the distance value between an object and the LiDAR device (more specifically, the optical origin of the LiDAR device) that is converted on the basis of the emission direction and flight time of a laser.

For example, the position coordinate values included in each of the plurality of point data can be acquired on the basis of an angle (or coordinate) value at which a laser is emitted and a distance value acquired on the basis of the emitted laser, but the present disclosure is not limited thereto.

Further, the position coordinate values included in each of the plurality of point data can be acquired on the basis of the coordinate values of a detector that acquires a laser and a distance value acquired on the basis of the acquired laser, but the present disclosure is not limited thereto.

Further, the intensity value included in each of the plurality of point data can be acquired on the basis of an electrical signal acquired from the detector unit.

For example, the intensity value included in each of the plurality of point data can be acquired on the basis of characteristics such as the magnitude and width of an electrical signal acquired from the detector unit, but is not limited thereto, and can be acquired by various algorithms for an electrical signal acquired from the detector unit.

Further, for example, the intensity value included in each of the plurality of point data can be acquired on the basis of histogram data created on the basis of an electrical signal acquired from the detector unit, but is not limited thereto.

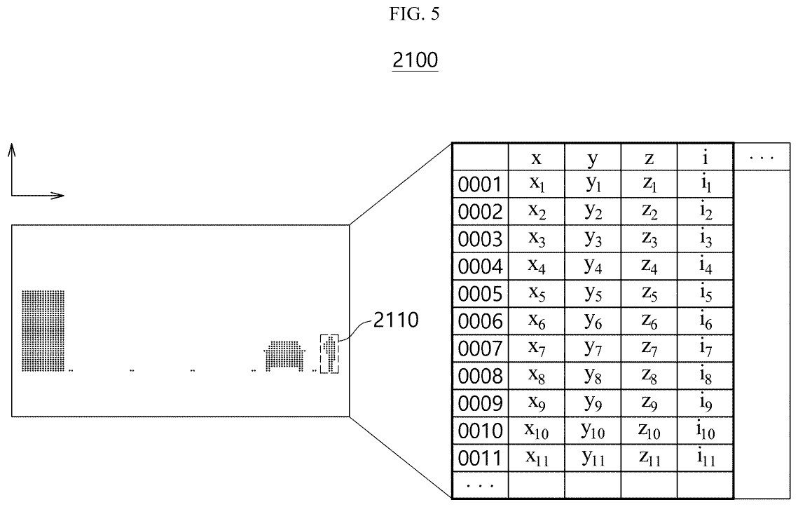

FIG. 5 is a diagram illustrating LiDAR data according to an embodiment.

Referring to FIG. 5, LiDAR data according to an embodiment may include point cloud data 2100.

In this case, since the above descriptions can be applied to the point cloud data 2100, repetitive descriptions are omitted.

The point cloud data 2100 according to an embodiment may include at least one sub-point data set 2110.

In this case, the at least one sub-point data set 2110 may refer to a set of point data grouped by a specific rule, algorithm, or the like.

For example, the at least one sub-point data set 2110 may refer to a set of point data grouped by human input, but is not limited thereto.

Further, for example, the at least one sub-point data set 2110 may refer to a set of point data grouped by a segment algorithm for the same object, but is not limited thereto.

Further, for example, the at least one sub-point data set 2110 may refer to a set of point data grouped by a clustering algorithm, but is not limited thereto.

Further, for example, the at least one sub-point data set 2110 may refer to a set of point data grouped by a trained machine learning model, but is not limited thereto.

Further, for example, the at least one sub-point data set 2110 may refer to a set of point data grouped by a trained deep learning model, but is not limited thereto.

Further, the LiDAR data processing unit according to an embodiment may acquire attribute data for the at least one sub-point data set 2110 described above.

For example, the LiDAR data processing unit may acquire at least one piece of attribute data for the at least one sub-point data set 2110 in accordance with human input, but is not limited thereto.

Further, for example, the LiDAR data processing unit may acquire at least one piece of attribute data for the at least one sub-point data set 2110 using a specific algorithm, but is not limited thereto.

Further, for example, the LiDAR data processing unit may acquire at least one piece of attribute data for the at least one sub-point data set 2110 using a trained machine learning model, but is not limited thereto.

Further, for example, the LiDAR data processing unit may acquire at least one piece of attribute data for the at least one sub-point data set 2110 using a trained deep learning model, but is not limited thereto.

Further, the machine learning model or deep learning model described above may include at least one Artificial Neural Network (ANN).

For example, the machine learning model or deep learning model described above may include at least one artificial neural network layer of various artificial neural network layers such as a feedforward neural network, a radial basis function network or a Kohonen self-organizing network, a Deep Neural Network (DNN), a Convolutional Neural Network (CNN), a Recurrent Neural Network (RNN), a Long Short Term Memory (LSTM) network, or Gated Recurrent Units (GRU), but is not limited thereto.

Further, the at least one artificial neural network layer included in the machine learning model or deep learning model described above may be designed to use the same or different activation functions.

In this case, the activation function may include a Sigmoid Function, a Tan h Function, a Rectified Linear unit Function (Relu Function), a leaky Relu Function, an Exponential Linear unit (ELU) function, a Softmax function, etc., but is not limited thereto, and may include various activation functions (including custom activation functions) for outputting or transmitting a result value to other artificial neural network layers.

Further, the machine learning model or deep learning model described above can be trained using at least one loss function.

In this case, the at least one loss function may include Mean Squared Error (MEM), Root Mean Squared Error (RMSE), Binary Crossentropy, Categorical Crossentropy, and Sparse Categorical Crossentropy, but is not limited thereto, and may include various functions (including custom loss functions) for calculating the difference between a predicted result value and an actual result value.

Further, the machine learning model or deep learning model described above can be trained using at least one optimizer.

In this case, the optimizer can be used to update relationship-defining parameters between an input value and a result value.

In this case, the at least one optimizer may include Gradient descent, Batch Gradient Descent, Stochastic Gradient Descent, Mini-batch Gradient Descent, Momentum, AdaGrad, RMSProp, AdaDelta, Adam, NAG, NAdam, RAdam, AdamW, etc., but is not limited thereto.

Hereafter, acquired attribute data are described in more detail.

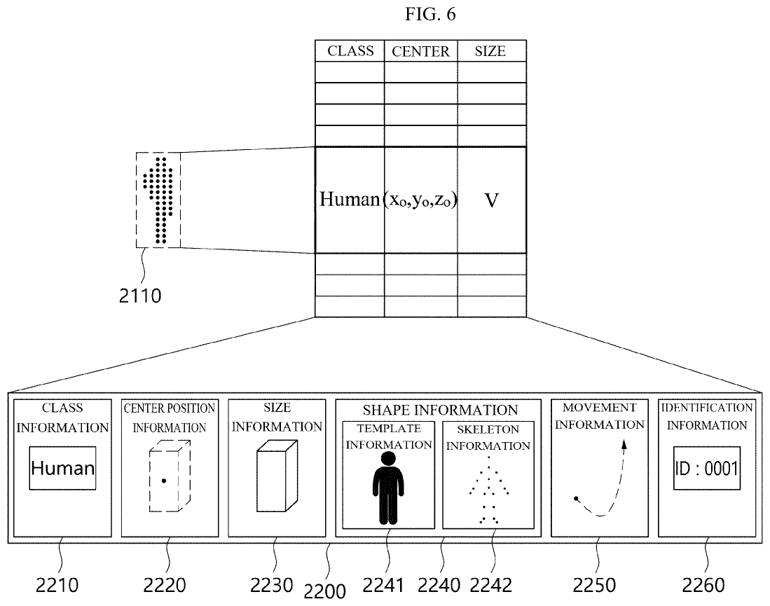

FIG. 6 is a diagram illustrating pieces of information included in attribute data according to an embodiment.

Referring to FIG. 6, the LiDAR data processing unit according to an embodiment can acquire at least one piece of attribute data 2200 for the sub-point data set 2110 according to the embodiment.

In this case, the at least one piece of attribute data 2200 may include class information 2210, center position information 2220, size information 2230, shape information 2240, movement information 2250, identification information 2260, etc. of an object represented by the sub-point data set 2110, but is not limited thereto.

Further, in order to acquire each of the attribute data included in the at least one piece of attribute data 2200, the same algorithm or model may be used, and different algorithms or models may also be used.

Further, the at least one piece of attribute data 2200 can be acquired on the basis of point cloud data included in one piece of frame data.

For example, the attribute data, such as the class information 2210, center position information 2220, size information 2230, and shape information 2240 of an object included in the at least one piece of attribute data 2200, can be acquired on the basis of point cloud data included in one piece of frame data, but is not limited thereto.

Further, the at least one piece of attribute data 2200 can be acquired on the basis of point cloud data included in a plurality of frame data.

For example, attribute data such as movement information 2250 and identification information 2260, which are included in the at least one piece of attribute data 2200, may be acquired on the basis of point cloud data included in a plurality of frame data, but are not limited thereto.

Further, although LiDAR data acquired in the form of a point cloud was described with reference to FIG. 4 to FIG. 6, the contents described above may also be applicable to LiDAR data acquired in formats such as a depth map and an intensity map other than the form of a point cloud, as described above.

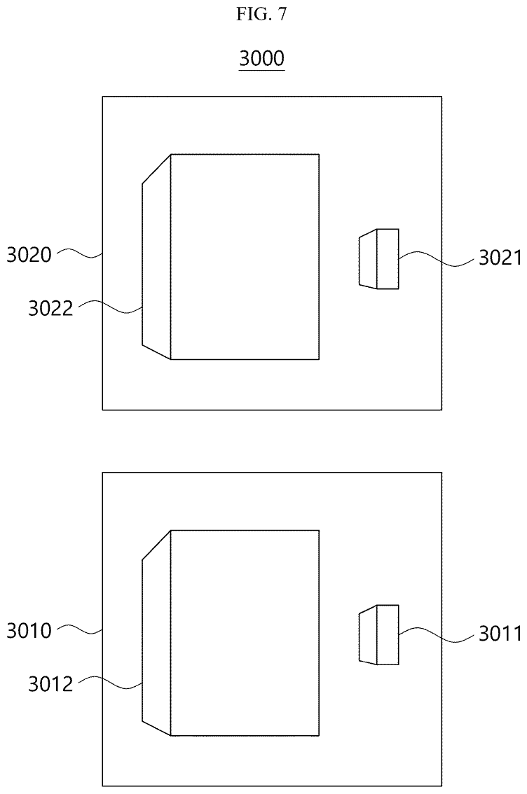

FIG. 7 is a diagram illustrating a LiDAR device according to an embodiment.

Referring to FIG. 7, a LiDAR device 3000 according to an embodiment may include a transmission module 3010 and a reception module 3020.

Further, the transmission module 3010 may include a laser emission array 3011 and a first lens assembly 3012, but is not limited thereto.

In this case, since the above descriptions of the laser emitting unit, etc. can be applied to the laser emission array 3011, repetitive descriptions are omitted.

Further, the laser emission array 3011 can emit at least one or more lasers. For example, the laser emission array 3011 can emit a plurality of lasers, but is not limited thereto.

Further, the laser emission array 3011 can emit at least one or more lasers at a first wavelength. For example, the laser emission array 3011 can output at least one or more lasers at a wavelength of 940 nm, and can emit a plurality of lasers at a wavelength of 940 nm, but is not limited thereto.

In this case, the first wavelength may be in a wavelength range including a tolerance range. For example, the first wavelength may refer to a wavelength range from 935 nm to 945 nm, as a 940 nm wavelength with a 5 nm tolerance range, but is not limited thereto.

Further, the laser emission array 3011 can emit at least one laser at the same time point. For example, the laser emission array 3011 can emit a first laser at a first time point or can emit first and second lasers at a second time point, that is, can emit at least one or more lasers at the same time point.

In this configuration, lasers that are emitted from the laser emission array 3011 can be emitted in a direction perpendicular to the plane in which the laser emission elements are arranged, and can be emitted with a predetermined divergence angle.

For example, a first laser emission element included in the laser emission array 3011 can emit a first laser that travels in a direction perpendicular to the plane in which the first laser emission element is disposed, and has a divergence angle of 40 degrees, and the second laser emission element can emit a second laser that travels in a direction perpendicular to the plane in which the second laser emission element is disposed, and has a divergence angle of 40 degrees.

Therefore, in some embodiments, it is necessary to reduce the divergence angle of the lasers that are emitted from the laser emission array 3011, and it is necessary to steer the lasers that are emitted from the laser emission array 3011 to be emitted in different directions.

Further, the first lens assembly 3012 may include at least two or more lens layers. For example, the first lens assembly 3012 may include at least four lens layers, but is not limited thereto.

Further, the first lens assembly 3012 can collimate lasers emitted from the laser emission array 3011. For example, the first lens assembly 3012 can change the divergence angle of a first laser emitted from the laser emission array 3011 by collimating the first laser. However, the first lens assembly 3012 does not necessarily have to have the collimating function.

Further, the first lens assembly 3012 can steer lasers emitted from the laser emission array 3011. For example, the first lens assembly 3012 can steer the first laser emitted from the laser emission array 3011 in a first direction, and can steer the second laser emitted from the laser emission array 3011 in a second direction, but is not limited thereto.

Further, the first lens assembly 3012 can steer a plurality of lasers emitted from the laser emission array 3011 to direct the lasers at different angles within a range of x degrees to y degrees. For example, the first lens assembly 3012 can steer the first laser emitted from the laser emission array 3011 in a first direction to direct the first laser at x degrees, and can steer the second laser emitted from the laser emission array 3011 in a second direction to direct the second layer at y degrees, but is not limited thereto. That is, when the laser emitting unit 100 includes a first laser emission element and a second laser emission element that is physically separated from the first laser emission element, the first lens assembly 3012 can make the steering direction of the laser generated by the first laser emission element (for example, the first direction) different from the steering direction of the laser generated by the second laser emission element (for example, the second direction). However, the first lens assembly 3012 does not necessarily have to have the steering function. That is, only when it is necessary to steer the laser emission directions of the individual laser emission elements, the first lens assembly 3012 is required to have the steering function, but, if not so, the steering function is not a function necessarily required for the first lens assembly 3012.

Accordingly, even though the first laser emission element and the second laser emission element are arranged on the same plane, and the first laser emitted from the first laser emission element and the second laser emitted from the second laser emission element are emitted to travel with a large divergence angle in the same direction, they are collimated and steered in different directions by the first lens assembly 3012, whereby the first laser and the second laser can be directed with small divergence angles in different directions.

Further, the reception module 3020 may include a laser detecting array 3021 and a second lens assembly 3022, but is not limited thereto.

In this case, since the above descriptions of the detector unit, etc. can be applied to the laser detecting array 3021, repetitive descriptions are omitted.

Further, the laser detecting array 3021 can sense light. For example, the laser detecting array 3021 can sense a plurality of lasers.

Further, the laser detecting array 3021 may include a plurality of detectors. For example, the laser detecting array 3021 may include a first detector and a second detector, but is not limited thereto.

Further, a plurality of detectors included in the laser detecting array 3021 can receive different lasers, respectively. For example, the first detector included in the laser detecting array 3021 can receive a first laser that is received in a first direction, and the second detector can receive a second laser that is received in a second direction, but the present disclosure is not limited thereto.

However, in this case, the meaning that a plurality of detectors receives different lasers, respectively, may include the meaning that even though a plurality of detectors included in the laser detecting array 3021 physically have the same function, they are disposed to receive different lasers by the second lens assembly 3022.

Further, the laser detecting array 3021 can sense at least a portion of a laser emitted from the transmission module 3010. For example, the laser detecting array 3021 can sense at least part of a first laser emitted from the transmission module 3010 when the first laser is reflected from an object, and can sense at least part of a second laser when the second laser is reflected from an object, but the present disclosure is not limited thereto. Further, the second lens assembly 3022 can transmit lasers emitted from the transmission module 3010 to the laser detecting array 3021. For example, when a first laser emitted in a first direction from the transmission module 3010 is reflected from an object located in the first direction, the second lens assembly 3022 can transmit the first laser to the laser detecting array 3021, and when a second laser emitted in a second direction is reflected from an object located in the second direction, the second lens assembly 3022 can transmit the second laser to the laser detecting array 3021, but the present disclosure is not limited thereto.

Further, the second lens assembly 3022 can distribute a laser emitted from the transmission module 3010 to at least two or more different detectors. For example, when a first laser emitted in a first direction from the transmission module 3010 is reflected from an object located in the first direction, the second lens assembly 3022 can distribute the first laser to the first detector included in the laser detecting array 3021, and when a second laser emitted in a second direction is reflected from an object located in the second direction, the second lens assembly 3022 can transmit the second laser to the second detector included in the laser detecting array 3021, but the present disclosure is not limited thereto.

Further, the laser emission array 3011 and the laser detecting array 3021 can be at least partially matched. For example, the first laser emitted from the first laser emission element included in the laser emission array 3011 can be sensed by the first detector included in the laser detecting array 3021, and the second laser emitted from the second laser emission element included in the laser emission array 3011 can be sensed by the second detector included in the laser detecting array 3021, but the present disclosure is not limited thereto.

Further, this configuration can be implemented as the laser emission array 3011 is aligned with the first lens assembly 3012, the laser detecting array 3021 is aligned with the second lens assembly 3022, and the transmission module 3010 is aligned with the reception module 3020.

For example, in order to implement this configuration, the laser emission array 3011 and the first lens assembly 3012 may be aligned such that the first laser emitted from the first laser emission element is directed in the first direction and the second laser emitted from the second laser emission element is directed in the second direction; the laser detecting array 3021 and the second lens assembly 3022 may be aligned such that the first detector receives light that is received at the second lens assembly 3022 from the third direction and the second detector receives light that is received at the second lens assembly 3022 from the fourth direction; and the transmission module 3010 and the reception module 3020 may be aligned such that the first direction and the third direction correspond to each other, and the second direction and the fourth direction correspond to each other.

FIG. is a diagram illustrating a laser emission array and a laser detecting array included in a LiDAR device according to an embodiment.

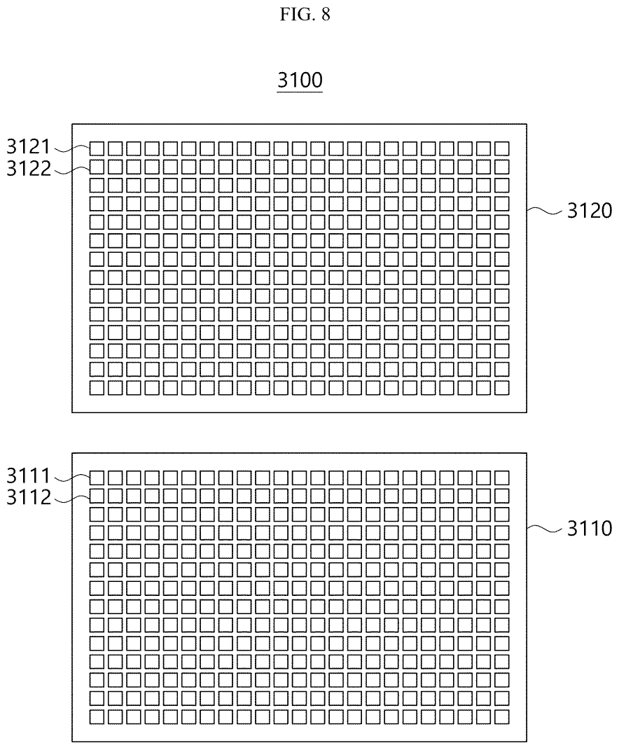

Referring to FIG. 8, a LiDAR device 3100 according to an embodiment may include a laser emission array 3110 and a laser detecting array 3120.

In this case, since the above descriptions can be applied to the laser emission array 3110 and the laser detecting array 3120, repetitive descriptions are omitted.

The laser emission array 3110 may include a plurality of laser emission units.

For example, the laser emission array 3110 may include a first laser emission unit 3111 and a second laser emission unit 3112.

Further, the laser emission array 3110 may be an array in which a plurality of laser emission units is arranged in a two-dimensional matrix form.

For example, the laser emission array 3110 may be an array in which a plurality of laser emission units is arranged in a two-dimensional matrix form having M rows and N columns, but is not limited thereto.

Further, the plurality of laser emission units each may include at least one laser emission element.

For example, a first laser emission unit 3111 included in the plurality of laser emission units may be composed of one laser emission element, and a second laser emission unit 3112 may be composed of one laser emission element, but the present disclosure is not limited thereto.

Further, for example, the first laser emission unit 3111 included in the plurality of laser emission units may be composed of two or more laser emission elements, and the second laser emission unit 3112 may be composed of two or more laser emission element, but the present disclosure is not limited thereto.

Further, lasers emitted from the plurality of laser emission units, respectively, can be directed in different directions.

This may mean that the lasers emitted from the plurality of laser emission units, respectively, are directed in different directions through a transmission optic (not shown), and in this case, since the above descriptions regarding the first lens assembly can be applied to the transmission optic (not shown), repetitive descriptions are omitted.

For example, the first laser emitted from the first laser emission unit 3111 included in the plurality of laser emission units can be directed in the first direction through the transmission optic, and the second laser emitted from the second laser emission unit 3112 can be directed in the second direction through the transmission optic, but the present disclosure is not limited thereto.

Further, the lasers emitted from the plurality of laser emission units, respectively, and directed through the transmission optic may not overlap each other at the target location.

For example, the first laser emitted from the first laser emission unit 3111 included in the plurality of laser emission units and directed through the transmission optic may not overlap the second laser emitted from the second laser emission unit 3112 and directed through the transmission optic at a distance of 100 m, but the present disclosure is not limited thereto.

The laser detecting array 3120 may include a plurality of detecting units.

For example, the laser detecting array 3120 may include a first detecting unit 3121 and a second detecting unit 3122.

Further, the laser detecting array 3120 may be an array in which a plurality of detecting units is arranged in a two-dimensional matrix form.

For example, the laser detecting array 3120 may be an array in which a plurality of detecting units is arranged in a two-dimensional matrix form having M rows and N columns, but is not limited thereto.

Further, the plurality of laser detecting units each may include at least one laser detecting device.

For example, a first detecting unit 3121 included in the plurality of detecting units may be composed of one laser detecting device, and a second detecting unit 3132 may be composed of one laser detecting device, but the present disclosure is not limited thereto.

For example, the first detecting unit 3121 included in the plurality of detecting units may be composed of two or more laser detecting devices, and a second detecting unit 3132 may be composed of two or more laser detecting devices, but the present disclosure is not limited thereto.

Further, the plurality of detecting units can sense lasers emitted in different directions, respectively.

This may mean that the plurality of detecting units senses lasers directed in different direction through a transmission optic (not shown) and reflected from objects located in different directions, and in this case, since the above descriptions regarding the second lens assembly can be applied to the transmission optic (not shown), repetitive descriptions are omitted.

For example, when a first laser emitted in the first direction is reflected from an object located in the first direction, the first detecting unit 3121 included in the plurality of laser emission units can sense at least a portion of the first laser reflected and received at the transmission optic from the first direction, and when a second laser emitted in the second direction is reflected from an object located in the second direction, the second detecting unit 3122 can sense at least a portion of the second laser reflected and received at the transmission optic from the second direction, but the present disclosure is not limited thereto.

Further, the plurality of detecting units can sense lasers emitted from laser emission units disposed to correspond to them, respectively.

For example, when the first laser emitted from the first laser emission unit 3111 disposed to correspond to the first detecting unit 3121 is reflected from an object, the first detecting unit 3121 included in the plurality of detecting units can sense the reflected first laser, and when the second laser emitted from the second laser emission unit 3112 disposed to correspond to the second laser detecting unit 3122 is reflected from an object, the second detecting unit 3122 can sense the reflected second laser, but the present disclosure is not limited thereto.

Further, the plurality of detecting units each can sense lasers emitted from at least two or more laser emission units, depending on the location of objects.

For example, when an object is located within a first distance range, the second detecting unit 3122 included in the plurality of detecting units can sense the second laser emitted from the second laser emission unit 3112, and when an object is located within a second distance range, the second detecting unit 3122 can sense the first laser emitted from the first laser emission unit 3111, but the present disclosure is not limited thereto.

That is, when the second detecting unit 3122 is disposed to sense light received from the second direction through the transmission optic and an object is located within a first distance range in the second direction, the second laser emitted from the second laser emission unit 3112 reaches the object and is reflected, so the above description can be understood as that when an object is located within the first distance range, the second detecting unit 3122 senses the second laser emitted from the second laser emission unit 3112. Further, when an object is located within a second distance range (a near range closer than the first distance range) in the second direction, the first laser emitted from the first laser emission unit 3111 reaches the object and is reflected, so the above description can be understood as that when an object is located within the second distance range, the second detecting unit 3122 senses the first laser emitted from the first laser emission unit 3111.

Further, at least one detecting value can be created on the basis of a signal acquired from each of the plurality of detecting units.

In this case, the detecting value may include a depth value (distance value), an intensity value, etc., but is not limited thereto.

Further, the coordinates of the detecting value can be determined on the basis of the arrangement of each of the plurality of detecting units.

For example, the first detecting unit 3121 included in the plurality of detecting units may be disposed at a position of (1,1) in the laser detecting array, and the coordinates of the first detecting value created on the basis of a signal acquired from the first detecting unit 3121 may be determined as (1,1), but the present disclosure is not limited thereto.

Further, for example, the second detecting unit 3122 included in the plurality of detecting units may be disposed at a position of (2,1) in the laser detecting array, and the coordinates of the second detecting value created on the basis of a signal acquired from the second detecting unit 3122 may be determined as (2, 1), but the present disclosure is not limited thereto.

Further, in this case, the physical meaning of the coordinates of the detecting value may be determined by the alignment between the laser detecting array and the reception optic.

For example, when, in accordance with the alignment between the laser detecting array and the reception optic, a light received at the receiving optic in the first direction reaches the first laser detecting unit 3121 disposed at the position of (1,1) in the laser detecting array, and a light received at the reception optic in the second direction reaches the second laser detecting unit 3122 disposed at the position of (2,1) in the laser detecting array, the coordinate (1,1) of the first detecting value may indicate an angle of the first direction with respect to an optical origin (for example, an angle according to a spherical coordinate system), and the coordinate (2,1) of the second detecting value may indicate an angle of the second direction with respect to the optical origin (for example, an angle according to a spherical coordinate system).

Further, the examples described above merely describe examples in which coordinate values directly corresponding to the respective arrangement positions of the plurality of detecting units are calculated, and the present disclosure is not limited thereto and may include various rules by which the coordinates of the detecting value can be determined on the basis of the arrangement of each of the plurality of detecting units.

Further, the laser emission array 3110 and the laser detecting array 3120 may be arranged as arrays having the same dimension.

For example, the laser emission array 3110 and the laser detecting array 3120 each may be arranged as an array in which a plurality of laser emission units and a plurality of detecting units respectively have M rows and N columns, but they are not limited thereto.

Further, the laser emission array 3110 and the laser detecting array 3120 may be arranged as arrays having different dimensions.

For example, the laser emission array 3110 may be arranged as an array in which a plurality of laser emission units have M rows and N columns, whereas the laser detecting array 3120 may be arranged as an array in which a plurality of detecting units have M+3 rows and N columns, but they are not limited thereto.

Further, the number of a plurality of laser emission units included in the laser emission array 3110 may be the same as the number of a plurality of detecting units included in the laser detecting array 3120.

For example, the laser emission array 3110 may include M*N laser emission units, and the laser detecting array 3120 may include M*N detecting units, but they are not limited thereto.

Further, the number of a plurality of laser emission units included in the laser emission array 3110 may be different from the number of a plurality of detecting units included in the laser detecting array 3120.

For example, the laser emission array 3110 may include M*N laser emission units, and the laser detecting array 3120 may include (M+3)*N detecting units, but they are not limited thereto.

Further, for example, the laser emission array 3110 may include (M*N)/2 laser emission units, and the laser detecting array 3120 may include M*N detecting units, but they are not limited thereto.

Further, for example, the laser emission array 3110 may include (M*N)/2 laser emission units, and the laser detecting array 3120 may include (M+3)*N detecting units, but they are not limited thereto.

Further, the number of laser emission elements included in each of the plurality of laser emission units included in the laser emission array 3110 may be different from the number of laser detecting elements included in each of the plurality of laser detecting units included in the laser detecting array 3120.

For example, when the number of laser emission elements included in the first laser emission unit 3111 is 1, the number of laser detecting elements included in the first laser detecting unit 3121 may be 9, but the present disclosure is not limited thereto.

Further, for example, when the number of laser emission elements included in the second laser emission unit 3112 is 1, the number of laser detecting elements included in the second laser detecting unit 3122 may be 9, but the present disclosure is not limited thereto.

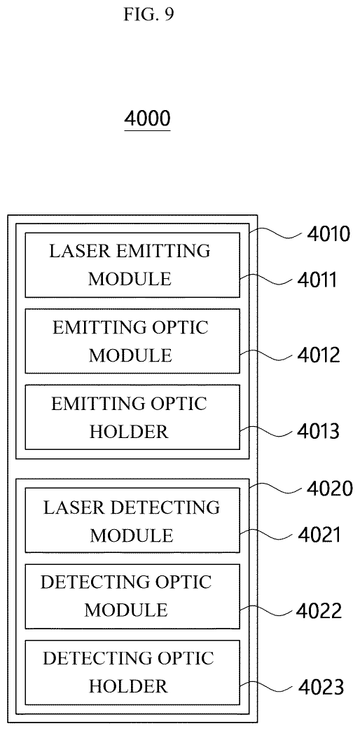

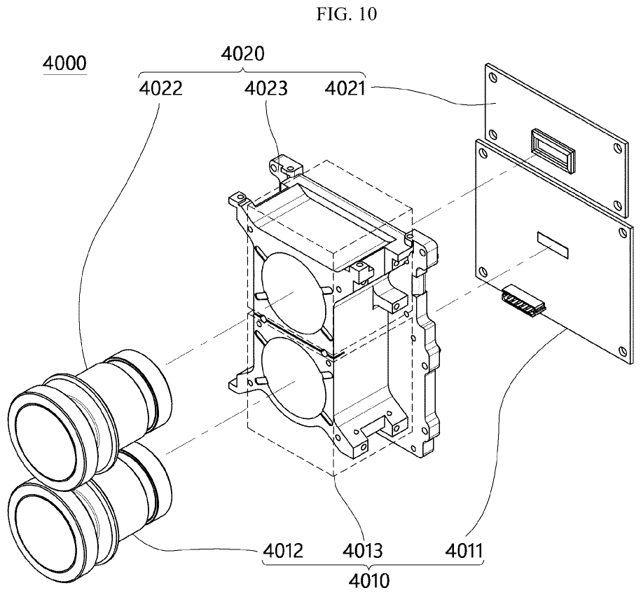

FIG. 9 and FIG. 10 are diagrams illustrating a LiDAR device according to an embodiment.

Referring to FIG. 9 and FIG. 10, a LiDAR device 4000 according to an embodiment may include a transmission module 4010 and a reception module 4020.

Further, referring to FIG. 9 and FIG. 10, the transmission module 4010 may include a laser emitting module 4011, an emitting optic module 4012, and an emitting optic holder 4013.

In this configuration, the laser emitting module 4011 may include a laser emission array, and since the above descriptions can be applied to the laser emission array, repetitive descriptions are omitted.

Further, the emitting optic module 4012 may include a lens assembly, and since the above descriptions of the first lens assembly, etc. can be applied to the lens assembly, repetitive descriptions are omitted.

Further, the emitting optic holder 4013 may be positioned between the laser emitting module 4011 and the emitting optic module 4012.

For example, the emitting optic holder 4013 may be positioned between the laser emitting module 4011 and the emitting optic module 4012 to fix the relative positional relationship between the laser emitting module 4011 and the emitting optic module 4012, but the present disclosure is not limited thereto.

Further, the emitting optic holder 4013 may be formed to fix movement of the emitting optic module 4012.

For example, the emitting optic holder 4013 may be formed to include a hole in which at least a portion of the emitting optic module 4012 is inserted, to restrict movement of the emitting optic module 4012, but the present disclosure is not limited thereto.

Further, referring to FIG. 9 and FIG. 10, the reception module 4020 according to an embodiment may include a laser detecting module 4021, a detecting optic module 4022, and a detecting optic holder 4023.

In this configuration, the laser detecting module 4021 may include a laser detecting array, and since the above descriptions can be applied to the laser detecting array, repetitive descriptions are omitted.

Further, the detecting optic module 4022 may include a lens assembly, and since the above descriptions of the second lens assembly, etc. can be applied to the lens assembly, repetitive descriptions are omitted.

Further, the detecting optic holder 4023 may be positioned between the laser detecting module 4021 and the detecting optic module 4022.

For example, the detecting optic holder 4023 may be positioned between the laser detecting module 4021 and the detecting optic module 4022 to fix the relative positional relationship between the laser detecting module 4021 and the detecting optic module 4022, but the present disclosure is not limited thereto.

Further, the detecting optic holder 4023 may be formed to fix movement of the detecting optic module 4022.

For example, the detecting optic holder 4023 may be formed to include a hole in which at least a portion of the detecting optic module 4022 is inserted, to restrict movement of the detecting optic module 4022, but the present disclosure is not limited thereto.

Further, the emitting optic holder 4013 and the detecting optic holder may be integrally formed.

For example, the emitting optic holder 4013 and the detecting optic holder 4023 may be integrally formed and two holes of one optic holder may be formed such that the emitting optic module 4012 and the detecting optic module 4022 are at least partially inserted therein, respectively, but the present disclosure is not limited thereto.

Further, the emitting optic holder 4013 and the detecting optic holder 4023 may not be physically separated and may conceptually refer to a first part and a second part of one optic holder, but the present disclosure is not limited thereto.

Further, FIG. 10 is a diagram illustrating an embodiment of the LiDAR device of FIG. 9, and the shapes shown in FIG. 10 do not limit the contents described in FIG. 9 and the present disclosure.

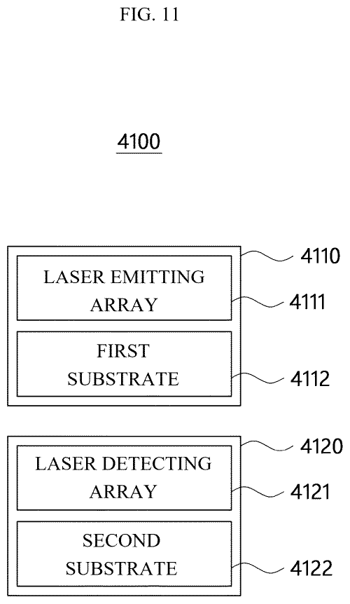

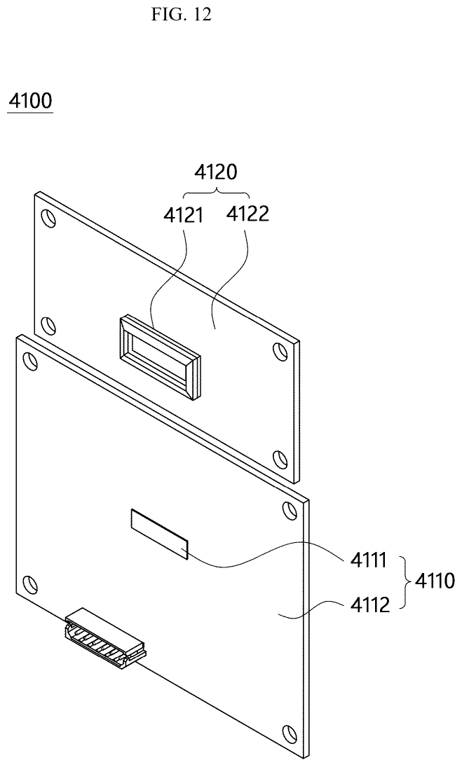

FIG. 11 and FIG. 12 are diagrams illustrating a laser emitting module and a laser detecting module according to an embodiment.

Referring to FIG. 11 and FIG. 12, a LiDAR device 4100 according to an embodiment may include a laser emitting module 4110 and a laser detecting module 4120.

Further, referring to FIG. 11 and FIG. 12, the laser emitting module 4110 according to an embodiment may include a laser emitting array 4111 and a first substrate 4112.

In this case, since the above descriptions can be applied to the laser emitting array 4111, repetitive descriptions are omitted.

The laser emitting array 4111 according to an embodiment may be provided in the form of a chip with a plurality of laser emitting units arranged in an array, but is not limited thereto.

For example, the laser emitting array 4111 may be provided in the form of a laser emitting chip, but is not limited thereto.

Further, the laser emitting array 4111 may be positioned on the first substrate 4112, but is not limited thereto.

Further, the first substrate 4112 may include a laser emitting driver for controlling the operation of the laser emitting array 4111, but is not limited thereto.

Further, referring to FIG. 11 and FIG. 12, the laser detecting module 4120 according to an embodiment may include a laser detecting array 4121 and a second substrate 4122.

In this case, since the above descriptions can be applied to the laser detecting array 4121, repetitive descriptions are omitted.

The laser detecting array 4121 according to an embodiment may be provided in the form of a chip with a plurality of laser detecting units arranged in an array, but is not limited thereto.

For example, the laser detecting array 4121 may be provided in the form of a laser detecting chip, but is not limited thereto.

Further, the laser detecting array 4121 may be positioned on the second substrate 4122, but is not limited thereto.

Further, the second substrate 4122 may include a laser detecting driver for controlling the operation of the laser detecting array 4121, but is not limited thereto.

Further, the first substrate 4112 and the second substrate 4122, as shown in FIG. 11, may be provided separately from each other, but they are not limited thereto and may be provided as one substrate.

Further, FIG. 12 is a diagram illustrating an embodiment of the LiDAR device of FIG. 11, and the shapes shown in FIG. 12 do not limit the contents described in FIG. 11 and the present disclosure.

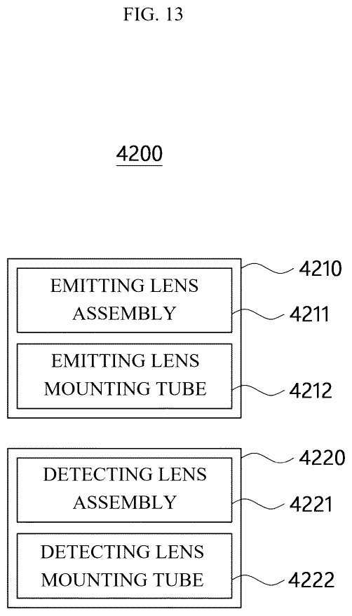

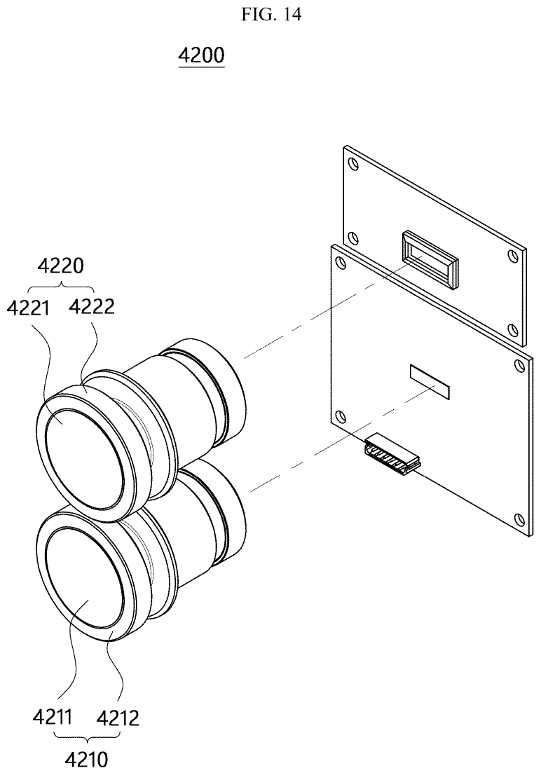

FIG. 13 and FIG. 14 are diagrams illustrating an emitting lens module and a detecting lens module according to an embodiment.

Referring to FIG. 13 and FIG. 14, a LiDAR device 4200 according to an embodiment may include an emitting lens module 4210 and a detecting lens module 4220.

Further, referring to FIG. 13 and FIG. 14, the emitting lens module 4210 according to an embodiment may include an emitting lens assembly 4211 and an emitting lens mounting tube 4212.

In this case, since the above descriptions can be applied to the emitting lens assembly 4211, repetitive descriptions are omitted.

The emitting lens assembly 4211 according to an embodiment may be disposed in the emitting lens mounting tube 4212.

Further, the emitting lens mounting tube 4212 may refer to a cylindrical tube surrounding the emitting lens assembly 4211, but is not limited thereto.

Further, referring to FIG. 13 and FIG. 14, the detecting lens module 4220 according to an embodiment may include a detecting lens assembly 4221 and a detecting lens mounting tube 4222.

In this case, since the above descriptions can be applied to the detecting lens assembly 4221, repetitive descriptions are omitted.

The detecting lens assembly 4221 according to an embodiment may be disposed in the detecting lens mounting tube 4222.

Further, the detecting lens mounting tube 4222 may refer to a cylindrical tube surrounding the detecting lens assembly 4221, but is not limited thereto.

Further, referring to FIG. 14, the emitting optic module 4210 may be disposed to be aligned with the laser emitting module described above.

In this case, the meaning that the emitting optic module 4210 is disposed to be aligned with the laser emitting module described above may include the meaning that it is disposed to have a preset relative physical positional relationship and the meaning that it is aligned to be able to emit a laser at an optically targeted angle, but is not limited thereto.

Further, referring to FIG. 14, the detecting optic module 4220 may be disposed to be aligned with the laser detecting module described above.

In this case, the meaning that the detecting optic module 4220 is disposed to be aligned with the laser detecting module described above may include the meaning that it is disposed to have a preset relative physical positional relationship and the meaning that it is aligned to be able to sense a laser that is received at an optically targeted angle, but is not limited thereto.

Further, FIG. 14 is a diagram illustrating an embodiment of the LiDAR device of FIG. 13, and the shapes shown in FIG. 14 do not limit the contents described in FIG. 13 and the present disclosure.

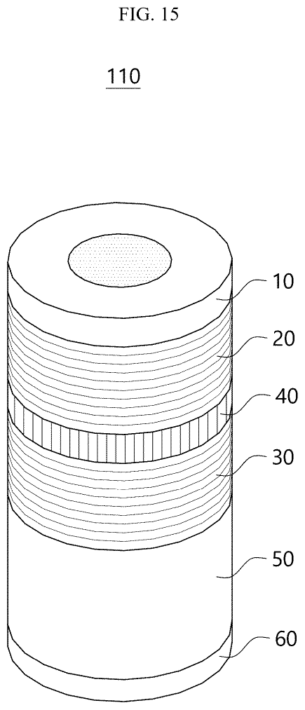

FIG. 15 is a diagram illustrating a laser emitting unit according to an embodiment.

Referring to FIG. 15, a laser emitting unit 100 according to an embodiment may include a VCSEL emitter 110.

The VCSEL emitter 110 according to an embodiment may include an upper metal contact 10, an upper Distributed Bragg reflector (DBR) layer 20, an active layer 40 (quantum well), a lower DBR layer 30, a substrate 50, and a lower metal contact 60.

Further, the VCSEL emitter 110 according to an embodiment may emit a laser beam vertically from its top surface. For example, the VCSEL emitter 110 can emit a laser beam in a direction perpendicular to the surface of the upper metal contact 10. Further, for example, the VCSEL emitter 110 can emit a laser beam perpendicularly to the active layer 40.

The VCSEL emitter 110 according to an embodiment may include an upper DBR layer 20 and a lower DBR layer 30.

The upper DBR layer 20 and the lower DBR layer 30 according to an embodiment may be composed of a plurality of reflective layers. For example, the plurality of reflective layers may include high-reflectivity reflective layers and low-reflectivity reflective layers alternately arranged. In this case, the thickness of the plurality of reflective layers may be one fourth of the wavelength of a laser emitted from the VCSEL emitter 110, but is not limited thereto.

Further, the upper DBR layer 20 and the lower DBR layer 30 according to an embodiment may be doped as p-type and n-type, respectively. For example, the upper DBR layer 20 may be doped as p-type and the lower DBR layer 30 may be doped as n-type. Alternatively, the upper DBR layer 20 may be doped as n-type and the lower DBR layer 30 may be doped as p-type.

Further, according to an embodiment, the substrate 50 may be disposed between the lower DBR layer 30 and the lower metal contact 60. When the lower DBR layer 30 is doped as p-type, the substrate 50 may be a p-type substrate, and when the lower DBR layer 30 is doped as n-type, the substrate 50 may also be an n-type substrate.

The VCSEL emitter 110 according to an embodiment may include the active layer 40.

The active layer 40 according to an embodiment may be disposed between the upper DBR layer 20 and the lower DBR layer 30.

The active layer 40 according to an embodiment may include a plurality of quantum wells generating a laser beam. The active layer 40 can emit a laser beam.

The VCSEL emitter 110 according to an embodiment may include a metal contact for electrical connection with a power source, etc. For example, the VCSEL emitter 110 may include the upper metal contact 10 and the lower metal contact 60.

Further, the VCSEL emitter 110 according to an embodiment may be electrically connected to the upper DBR layer 20 and the lower DBR layer 30 through a metal contact.

For example, when the upper DBR layer 20 is doped as p-type and the lower DBR layer 30 is doped as n-type, p-type power is supplied to the upper metal contact 10, so the upper metal contact 10 can be electrically connected to the upper DBR layer 20, and n-type power is supplied to the lower metal contact 60, so the lower metal contact 60 can be electrically connected to the lower DBR layer 30.

Further, for example, when the upper DBR layer 20 is doped as n-type and the lower DBR layer 30 is doped as p-type, n-type power is supplied to the upper metal contact 10, so the upper metal contact 10 can be electrically connected to the upper DBR layer 20, and p-type power is supplied to the lower metal contact 60, so the lower metal contact 60 can be electrically connected to the lower DBR layer 30.

The VCSEL emitter 110 according to an embodiment may include an oxidation area. The oxidation area may be disposed over the active layer.

The oxidation area according to an embodiment may be insulating. For example, the oxidation area may limit electrical flow. For example, the oxidation area may limit electrical connection.

Further, the oxidation area according to an embodiment may serve as an aperture. In detail, since the oxidation area is insulating, a beam generated from the active layer 40 can be emitted only from the portion other than the oxidation area.

A laser emitting unit according to an embodiment may include a plurality of VCSEL emitters 110.

Further, the laser emitting unit according to an embodiment can turn on the plurality of VCSEL emitters 110 at once or individually.

The laser emitting unit according to an embodiment can emit laser beams of various wavelengths. For example, the laser emitting unit may emit a laser beam with a wavelength of 905 nm. Further, for example, the laser emitting unit may emit a laser beam with a wavelength of 940 nm. Further, for example, the laser emitting unit may emit a laser beam with a wavelength of 1550 nm.

Further, the wavelength of the laser emitted from the laser emitting unit according to an embodiment may be changed by the surrounding environment. For example, the wavelength of the laser emitted from the laser emitting unit may increase as the temperature of the surrounding environment increases. Alternatively, the wavelength of the laser emitted from the laser emitting unit may decrease as the temperature of the surrounding environment decreases. The surrounding environment may include temperature, humidity, pressure, concentration of dust, ambient light level, altitude, gravity, acceleration, and the like, but is not limited thereto.

The laser emitting unit can emit a laser beam in a direction perpendicular to a supporting surface. Alternatively, the laser emitting unit can emit a laser beam in a direction perpendicular to the emission surface.

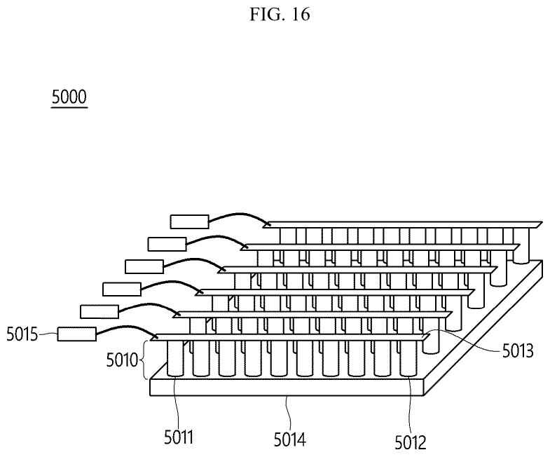

FIG. 16 is a diagram illustrating a laser emission array according to an embodiment.

Referring to FIG. 16, a laser emission array 5000 according to an embodiment may include a plurality of laser emission units, at least one subarray, at least one upper conductor, at least one lower conductor, and at least one power supply.

In this case, the at least one subarray may refer to a group of laser emission units operatively connected among the plurality of laser emission units, may refer to a group of laser emission units physically connected, may refer to a group of laser emission units connected to the same power supply, may refer to a group of laser emission units defined by the at least one upper conductor, and may refer to a group of laser emission units defined by a capacitor electrically connected to the at least one power supply, but is not limited thereto.

At least one subarray according to an embodiment may include a plurality of subarrays.

For example, at least one subarray according to an embodiment may include a plurality of subarrays including a first subarray 5010, but is not limited thereto.

At least one subarray according to an embodiment may include a plurality of laser emission units.

For example, the first laser subarray 5010 may include a plurality of laser emission units, but is not limited thereto.

To give a more specific example, the first subarray 5010 may include a first laser emission unit 5011 and a second laser emission unit 5012, but is not limited thereto.

Further, a plurality of laser emission units included in at least one subarray according to an embodiment may be connected to at least one upper conductor.

For example, a plurality of laser emission units included in the first subarray 5010 according to an embodiment may be connected to a first upper conductor 5013 through the upper metal contact, but is not limited thereto.

Further, for example, the first laser emission unit 5011 and the second laser emission unit 5012 included in the first subarray 5010 according to an embodiment may be connected to the first upper conductor 5013 through their respective upper metal contacts, but are not limited thereto.

Further, a plurality of laser emission units included in at least one subarray according to an embodiment may be connected to at least one lower conductor.

For example, a plurality of laser emission units included in at least one subarray according to an embodiment may be connected to a first lower conductor 5014 through the lower metal contact, but is not limited thereto.

Further, for example, the first laser emission unit 5011 and the second laser emission unit 5012 included in at least one subarray according to an embodiment may be connected to the first lower conductor 5014 through their respective lower metal contacts, but are not limited thereto.

Further, a plurality of laser emission units included in at least one subarray according to an embodiment may be supplied with energy from at least one power supply.

For example, the first laser emission unit 5011 and the second laser emission unit 5012 included in the first subarray 5010, which is included in at least one subarray according to an embodiment, may be connected to a first power supply 5015 through the first upper conductor 5013, whereby they can be supplied with energy from the first power supply 5015, but are not limited thereto.

For example, the first laser emission unit 5011 and the second laser emission unit 5012 included in the first subarray 5010, which is included in at least one subarray according to an embodiment, may be connected to the first power supply 5015 through the first lower conductor 5014, whereby they can be supplied with energy from the first power supply 5015, but are not limited thereto.

Further, a plurality of laser emission units included in at least one subarray according to an embodiment may receive a voltage applied from at least one power supply.

For example, the first laser emission unit 5011 and the second laser emission unit 5012 included in the first subarray 5010, which is included in at least one subarray according to an embodiment, may be connected to the first power supply 5015 through the first upper conductor 5013, whereby they can receive a voltage applied from the first power supply 5015, but are not limited thereto.

For example, the first laser emission unit 5011 and the second laser emission unit 5012 included in the first subarray 5010, which is included in at least one subarray according to an embodiment, may be connected to the first power supply 5015 through the first lower conductor 5014, whereby they can receive a voltage applied from the first power supply 5015, but are not limited thereto.

Further, the lengths of electrical paths between at least one laser emission unit included in at least one subarray according to an embodiment and at least one power supply may differ from each other.

For example, as shown in FIG. 16, the electrical path between the first laser emission unit 5011 included in the first subarray 5010 and the first power supply 5015 may be shorter than the electrical path between the second laser emission unit 5012 and the first power supply 5015, but the present disclosure is not limited thereto.

In this case, the electrical path may refer to a path along which current or electrons travel from the power supply to each laser emission unit, and may include a concept that can be understood as an electrical path by those skilled in the art.

Further, the above descriptions based on the first subarray 5010, etc., can be applied to other subarrays, etc., so repetitive descriptions are omitted.

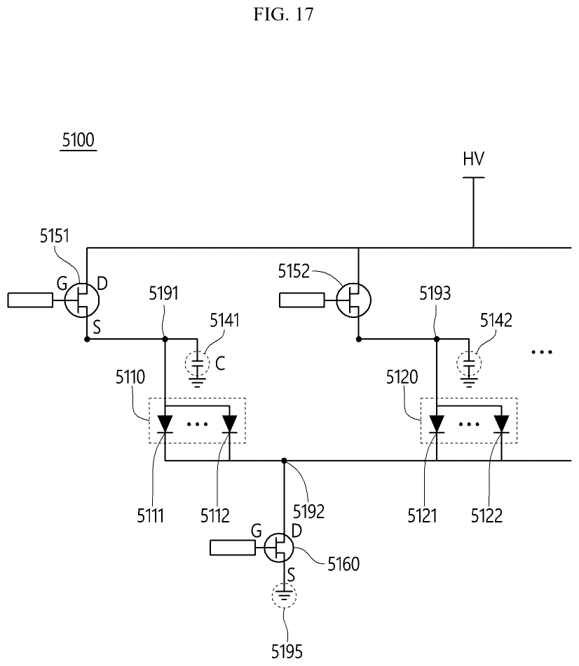

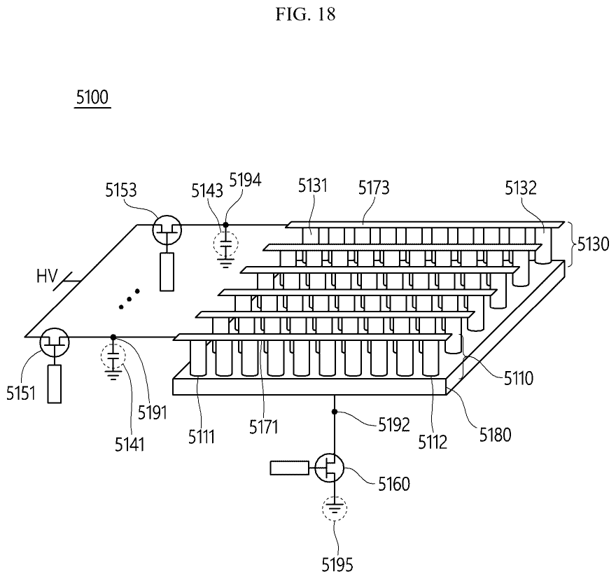

FIG. 17 and FIG. 18 are diagrams illustrating a laser emission array according to an embodiment.

Prior to describing FIG. 17 and FIG. 18, the corresponding description above can be applied to the components to be described with reference to FIG. 17 and FIG. 18, so repetitive descriptions are omitted.

Referring to FIG. 17, a laser emission array 5100 according to an embodiment may include a plurality of laser emission units, at least one subarray, at least one upper conductor, at least one lower conductor, at least one power supply, at least one switch, and at least one capacitor.

In this case, the at least one subarray may refer to a group of laser emission units operatively connected among the plurality of laser emission units, may refer to a group of laser emission units physically connected, may refer to a group of laser emission units connected to the same power supply, may refer to a group of laser emission units defined by the at least one upper conductor, and may refer to a group of laser emission units defined by a capacitor electrically connected to the at least one power supply, but is not limited thereto.

The laser emission array 5100 according to an embodiment may include a plurality of laser emission units.

For example, the laser emission array 5100 according to an embodiment may include a first laser emission unit 5111, a second laser emission unit 5112, a third laser emission unit 5121, a fourth laser emission unit 5122, a fifth laser emission unit 5131, and a sixth laser emission unit 5132, but is not limited thereto.

The laser emission array 5100 according to an embodiment may include a plurality of subarrays including at least one laser emission unit.

For example, the laser emission array 5100 according to an embodiment may include a first subarray 5110 including the first laser emission unit 5111 and the second laser emission unit 5112, a second subarray 5120 including the third laser emission unit 5121 and the fourth laser emission unit 5122, and a third subarray 5130 including the fifth laser emission unit 5131 and the sixth laser emission unit 5132, but is not limited thereto.

Further, a plurality of laser emission units included in the laser emission array 5100 according to an embodiment may be positioned between nodes having different voltages when each of the plurality of laser emission units emits a laser.

For example, the first laser emission unit 5111 included in the laser emission array 5100 according to an embodiment may be positioned between a first node 5191 and a second node 5192 having different voltages when the first laser emission unit 5111 emits a first laser, but the present disclosure is not limited thereto.

In this case, energy is supplied to the first laser emission unit 5111 by the voltage difference between the first node 5191 and the second node 5192, so the first laser can be emitted, but the present disclosure is not limited thereto.

Further, for example, the third laser emission unit 5121 included in the laser emission array 5100 according to an embodiment may be positioned between a third node 5193 and the second node 5192 having different voltages when the third laser emission unit 5121 emits a third laser, but the present disclosure is not limited thereto.

In this case, energy is supplied to the third laser emission unit 5121 by the voltage difference between the third node 5193 and the second node 5192, so the third laser can be emitted, but the present disclosure is not limited thereto.

Further, for example, the fifth laser emission unit 5131 included in the laser emission array 5100 according to an embodiment may be positioned between a fourth node 5194 and the second node 5192 having different voltages when the fifth laser emission unit 5131 emits a fifth laser, but the present disclosure is not limited thereto.

In this case, energy is supplied to the fifth laser emission unit 5121 by the voltage difference between the fourth node 5194 and the second node 5192, so the fifth laser can be emitted, but the present disclosure is not limited thereto.

Further, a plurality of laser emission units included in at least one subarray included in the laser emission array 5100 according to an embodiment may be positioned between the same nodes.

For example, the first laser emission unit 5111 and the second laser emission unit 5112 included in the first subarray 5110 may be positioned between the first node 5191 and the second node 5192, but they are not limited thereto.

For example, the third laser emission unit 5121 and the fourth laser emission unit 5122 included in the second subarray 5120 may be positioned between the third node 5193 and the second node 5192, but they are not limited thereto.

For example, the fifth laser emission unit 5131 and the sixth laser emission unit 5132 included in the third subarray 5130 may be positioned between the fourth node 5194 and the second node 5192, but they are not limited thereto.

Further, the laser emission array 5100 according to an embodiment may include at least one capacitor for supplying energy to at least one laser emission unit.

In this case, the energy that is supplied to the at least one laser emission unit may be represented as voltage, current, charge, or the like for convenience, and may be represented in various terms related to the energy required for laser emission from the at least one laser emission unit.

For example, the laser emission array 5100 according to an embodiment may include a first capacitor 5141, and the first capacitor 5141 can function to supply energy to the first laser emission unit 5111, but is not limited thereto.

Further, for example, the laser emission array 5100 according to an embodiment may include a second capacitor 5142, and the second capacitor 5142 can function to supply energy to the third laser emission unit 5121, but is not limited thereto.

Further, for example, the laser emission array 5100 according to an embodiment may include a third capacitor 5143, and the third capacitor 5143 can function to supply energy to the fifth laser emission unit 5131, but is not limited thereto.

Further, at least one capacitor included in the laser emission array 5100 according to an embodiment can function to supply energy to at least one subarray included in the laser emission array 5100.

For example, the first capacitor 5141 can function to supply energy to the first subarray 5110 including the first laser emission unit 5111 and the second laser emission unit 5112, but is not limited thereto.

Further, for example, the second capacitor 5142 can function to supply energy to the second subarray 5120 including the third laser emission unit 5121 and the fourth laser emission unit 5122, but is not limited thereto.

Further, for example, the third capacitor 5143 can function to supply energy to the third subarray 5130 including the fifth laser emission unit 5131 and the fifth laser emission unit 5132, but is not limited thereto.

Further, at least one capacitor included in the laser emission array 5100 according to an embodiment may be connected (coupled) to at least one node.

For example, the first capacitor 5141 may be connected to the first node 5191, but is not limited thereto.

Further, for example, the second capacitor 5142 may be connected to the third node 5193, but is not limited thereto.

Further, for example, the third capacitor 5143 may be connected to the fourth node 5194, but is not limited thereto.

Further, at least one capacitor included in the laser emission array 5100 according to an embodiment may be electrically connected to the upper conductor that is connected to the upper metal contact of each of a plurality of laser emission units included in at least one subarray.

For example, referring to FIG. 18, the first capacitor 5141 may be electrically connected to the first upper conductor 5171, which is connected to the upper metal contact of the first laser emission unit 5111 and the upper metal contact of the second laser emission unit 5112, but is not limited thereto.

Further, for example, referring to FIG. 18, the third capacitor 5143 may be electrically connected to the third upper conductor 5173, which is connected to the upper metal contact of the fifth laser emission unit 5131 and the upper metal contact of the sixth laser emission unit 5132, but is not limited thereto.

Further, the laser emission array 5100 according to an embodiment may include at least one power supply HV for charging the at least one capacitor.

For example, the laser emission array 5100 according to an embodiment may include a power supply HV for charging the first capacitor 5141, the second capacitor 5142, and the third capacitor 5143, but is not limited thereto.

In this case, the power supply HV may be provided as one, but is not limited thereto, and may be provided as multiple to charge one capacitor each, or may be provided as multiple to charge multiple capacitors each.

However, FIG. 17 and FIG. 18 are described on the basis of the laser emission array 5100 including one power supply for convenience of explanation, but this is only for convenience of explanation and does not limit the spirit of the present disclosure.

Further, at least one power supply HV included in the laser emission array 5100 according to an embodiment can function to charge the at least one capacitor through the node connected to the at least one capacitor.

For example, the power supply HV according to an embodiment can function to charge the first capacitor 5141 through the first node 5191, but is not limited thereto.

Further, for example, the power supply HV according to an embodiment can function to charge the second capacitor 5142 through the third node 5193, but is not limited thereto.

Further, for example, the power supply HV according to an embodiment can function to charge the third capacitor 5143 through the fourth node 5194, but is not limited thereto.

Further, the laser emission array 5100 according to an embodiment may include at least one charging switch for controlling charging of the at least one capacitor and a charging switch driver for controlling driving of the at least one charging switch.

In this case, the at least one charging switch may be implemented as a Field Effect Transistor (FET), but is not limited thereto.

For example, the laser emission array 5100 according to an embodiment may include a first charging switch 5151 for controlling charging of the first capacitor 5141 and a first charging switch driver for controlling driving of the first charging switch 5151, but is not limited thereto.

To give more specific example, the laser emission array 5100 according to an embodiment may include a first charging switch 5151 for controlling charging of the first capacitor 5141 and a first charging switch driver connected to a gate of the first charging switch 5151 to control a voltage that is applied, but is not limited thereto.

Further, for example, the laser emission array 5100 according to an embodiment may include a second charging switch 5152 for controlling charging of the second capacitor 5142 and a second charging switch driver for controlling driving of the second charging switch 5152, but is not limited thereto.

To give more specific example, the laser emission array 5100 according to an embodiment may include a second charging switch 5152 for controlling charging of the second capacitor 5142 and a second charging switch driver connected to a gate of the second charging switch 5152 to control a voltage that is applied, but is not limited thereto.

Further, for example, the laser emission array 5100 according to an embodiment may include a third charging switch 5153 for controlling charging of the third capacitor 5143 and a third charging switch driver for controlling driving of the third charging switch 5153, but is not limited thereto.

To give more specific example, the laser emission array 5100 according to an embodiment may include a third charging switch 5153 for controlling charging of the third capacitor 5143 and a third charging switch driver connected to a gate of the third charging switch 5153 to control a voltage that is applied, but is not limited thereto.

Further, at least one charging switch according to an embodiment may be positioned between the at least one power supply included in the laser emission array 5100 and the at least one capacitor.

For example, the first charging switch 5151 according to an embodiment may be positioned between the power supply HV and the first capacitor 5141, but is not limited thereto.

Further, for example, the second charging switch 5152 according to an embodiment may be positioned between the power supply HV and the second capacitor 5142, but is not limited thereto.

Further, for example, the third charging switch 5153 according to an embodiment may be positioned between the power supply HV and the third capacitor 5143, but is not limited thereto.

Further, at least one charging switch included in the laser emission array 5100 according to an embodiment may be connected (coupled) to at least one node.

For example, the first charging switch 5151 may be connected to the first node 5191, but is not limited thereto.

Further, for example, the second charging switch 5152 may be connected to the third node 5193, but is not limited thereto.

Further, for example, the third charging switch 5153 may be connected to the fourth node 5194, but is not limited thereto.

Further, the laser emission array 5100 according to an embodiment may include at least one common driving switch for controlling the driving of at least one laser emission unit and a common driving switch driver for controlling driving of the at least one common driving switch.

In this case, the at least one common driving switch may be implemented as a Field Effect Transistor (FET), but is not limited thereto.

For example, the laser emission array 5100 according to an embodiment may include a common driving switch 5160 for controlling driving of the first laser emission unit 5111 and a common driving switch driver for controlling driving of the common driving switch 5160, but is not limited thereto.

Further, the laser emission array 5100 according to an embodiment may include at least one common driving switch for controlling the driving of a plurality laser emission units included in at least one subarray and a common driving switch driver for controlling driving of the at least one common driving switch.

For example, the laser emission array 5100 according to an embodiment may include a common driving switch 5160 for controlling driving of the first laser emission unit 5111 and the second laser emission unit 5112 included in the first subarray 5110, and a common driving switch driver for controlling driving of the common driving switch 5160, but is not limited thereto.

Further, at least one common driving switch according to an embodiment may be positioned between at least one laser emission unit included in the laser emission array 5100 and a ground.

For example, the common driving switch 5160 according to an embodiment may be positioned between the first laser emission unit 5111 and a first ground 5195, but is not limited thereto.

Further, for example, the common driving switch 5160 according to an embodiment may be positioned between the third laser emission unit 5121 and the first ground 5195, but is not limited thereto.

Further, for example, the common driving switch 5160 according to an embodiment may be positioned between the fifth laser emission unit 5131 and the first ground 5195, but is not limited thereto.

Further, at least one common driving switch according to an embodiment may be positioned between a lower conductor connected to the lower metal of a plurality of laser emission units included in the laser emission array 5100 and a ground.

For example, the common driving switch 5160 according to an embodiment may be positioned between the lower conductor 5180 connected to the lower metal of each of the first to sixth laser emission units 5111 to 5132 included in the laser emission array 5100 and the first ground 5195, but is not limited thereto.

Further, at least one common driving switch included in the laser emission array 5100 according to an embodiment may be connected (coupled) to at least one node.

For example, the common driving switch 5160 may be connected to the second node 5192, but is not limited thereto.

Hereafter, the operation of the laser emission array having the configuration described above is described in more detail.

[Laser emission operation of the first laser emission unit 5111 and the second laser emission unit 5112 included in the first subarray 5110]

In a first charging sequence according to an embodiment, the first charging switch 5151 can be turned on.

For example, in the first charging sequence according to an embodiment, the first charging switch 5151 can be turned on by the operation of a first charging switch driver connected to the gate of the first charging switch 5151, but is not limited thereto.

Further, in the first charging sequence according to an embodiment, as the first charging switch 5151 is turned on, the first capacitor 5141 can be charged by the power supply HV.

For example, in the first charging sequence according to an embodiment, as the first charging switch 5151 is turned on, current can flow from the power supply HV to the first capacitor 5141 through the first charging switch 5151 and the first node 5191, whereby the first capacitor 5141 can be charged, but the present disclosure is not limited thereto.

Further, in the first charging sequence according to an embodiment, the common driving switch 5160 can be turned on.

For example, in the first charging sequence according to an embodiment, the common driving switch 5160 can be turned on by the operation of the common driving switch driver connected to the gate of the common driving switch 5160, but is not limited thereto.

Further, in the first driving sequence according to an embodiment, as the common driving switch 5160 is turned on, energy can be supplied to the first laser emission unit 5111 and the second laser emission unit 5112 included in the first subarray 5110 by the first capacitor 5141, whereby a first laser and a second laser can be emitted.

For example, in the first driving sequence according to an embodiment, as the common driving switch 5160 is turned on, the electric charges stored in the first capacitor 5141 are discharged, current can flow between the first capacitor 5141 and the first ground 5195, at least a portion of the current can generate light in the active area of the first laser emission unit 5111 by passing through the first laser emission unit 5111, another at least portion of the current can generate light in the active area of the second laser emission unit 5112 by passing through the second laser emission unit 5112, and the light generated from the first and second laser emission units 5111 and 5112 can be emitted from their respective surfaces, which can be represented as the third laser and the fourth laser, respectively, but the present disclosure is not limited thereto.

### [Laser Emission Operation of the Third Laser Emission Unit 5121 and the Fourth Laser Emission Unit 5122 Included in the Second Subarray 5120]

In a second charging sequence according to an embodiment, the second charging switch 5152 can be turned on.

For example, in the second charging sequence according to an embodiment, the second charging switch 5152 can be turned on by the operation of a second charging switch driver connected to the gate of the second charging switch 5152, but is not limited thereto.

Further, in the second charging sequence according to an embodiment, as the second charging switch 5152 is turned on, the second capacitor 5142 can be charged by the power supply HV.

For example, in the second charging sequence according to an embodiment, as the second charging switch 5152 is turned on, current can flow from the power supply HV to the second capacitor 5142 through the second charging switch 5152 and the third node 5193, whereby the second capacitor 5142 can be charged, but the present disclosure is not limited thereto.

Further, in the second charging sequence according to an embodiment, the common driving switch 5160 can be turned on.

For example, in the second charging sequence according to an embodiment, the common driving switch 5160 can be turned on by the operation of the common driving switch driver connected to the gate of the common driving switch 5160, but is not limited thereto.

Further, in the second driving sequence according to an embodiment, as the common driving switch 5160 is turned on, energy can be supplied to the third laser emission unit 5121 and the fourth laser emission unit 5122 included in the second subarray 5120 by the second capacitor 5142, whereby a third laser and a fourth laser can be emitted.

For example, in the second driving sequence according to an embodiment, as the common driving switch 5160 is turned on, the electric charges stored in the second capacitor 5142 are discharged, current can flow between the second capacitor 5142 and the first ground 5195, at least a portion of the current can generate light in the active area of the third laser emission unit 5121 by passing through the third laser emission unit 5111, another at least portion of the current can generate light in the active area of the fourth laser emission unit 5122 by passing through the fourth laser emission unit 5122, and the light generated from the third and fourth laser emission units 5121 and 5122 can be emitted from their respective surfaces, which can be represented as the third laser and the fourth laser, respectively, but the present disclosure is not limited thereto.

### [Laser Emission Operation of the Fifth Laser Emission Unit 5131 and the Sixth Laser Emission Unit 5132 Included in the Third Subarray 5130]

In a third charging sequence according to an embodiment, the third charging switch 5153 can be turned on.

For example, in the third charging sequence according to an embodiment, the third charging switch 5153 can be turned on by the operation of a third charging switch driver connected to the gate of the third charging switch 5153, but is not limited thereto.

Further, in the third charging sequence according to an embodiment, as the third charging switch 5153 is turned on, the third capacitor 5143 can be charged by the power supply HV.

For example, in the third charging sequence according to an embodiment, as the third charging switch 5153 is turned on, current can flow from the power supply HV to the third capacitor 5143 through the third charging switch 5152 and the fourth node 5194, whereby the third capacitor 5143 can be charged, but the present disclosure is not limited thereto.

Further, in the third charging sequence according to an embodiment, the common driving switch 5160 can be turned on.

For example, in the third charging sequence according to an embodiment, the common driving switch 5160 can be turned on by the operation of the common driving switch driver connected to the gate of the common driving switch 5160, but is not limited thereto.

Further, in the third driving sequence according to an embodiment, as the common driving switch 5160 is turned on, energy can be supplied to the fifth laser emission unit 5131 and the sixth laser emission unit 5132 included in the third subarray 5130 by the third capacitor 5143, whereby a fifth laser and a sixth laser can be emitted.

For example, in the third driving sequence according to an embodiment, as the common driving switch 5160 is turned on, the electric charges stored in the third capacitor 5143 are discharged, current can flow between the third capacitor 5143 and the first ground 5195, at least a portion of the current can generate light in the active area of the fifth laser emission unit 5131 by passing through the fifth laser emission unit 5131, another at least portion of the current can generate light in the active area of the sixth laser emission unit 5132 by passing through the sixth laser emission unit 5132, and the light generated from the fifth and sixth laser emission units 5131 and 5132 can be emitted from their respective surfaces, which can be represented as the fifth laser and the sixth laser, respectively, but the present disclosure is not limited thereto.

### [Selection of Laser Emission Channel (Subarray)]

As described above, in the case of a laser emission array that controls final laser emission using a common driving switch, like the laser emission array 5100 according to an embodiment, a laser emission channel (subarray from which a laser is emitted) may be selected by a capacitor that is charged.

For example, when the common driving switch 5160 is driven, if the first capacitor 5141 has been charged, the first subarray 5110 can be selected as a laser emission channel; when the common driving switch 5160 is driven, if the second capacitor 5142 has been charged, the second subarray 5120 may be selected as a laser emission channel; and when the common driving switch 5160 is driven, if the third capacitor 5143 has been charged, the third subarray 5130 may be selected as a laser emission channel. Depending on the intention, one capacitor may have been charged, or a plurality of capacitors may have been charged, but the present disclosure is not limited thereto.

This may ultimately mean that a channel can be selected depending on whether the capacitor connected to each subarray has been charged, and may also mean that independent control is possible for each operating unit (subarray).

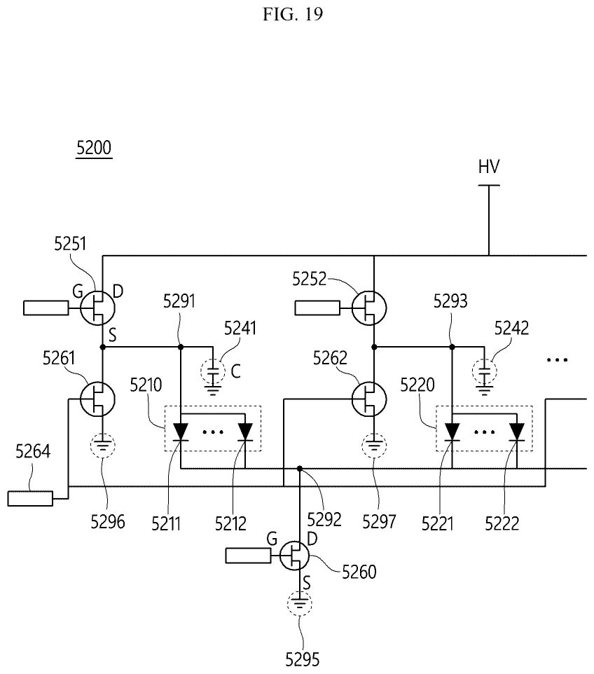

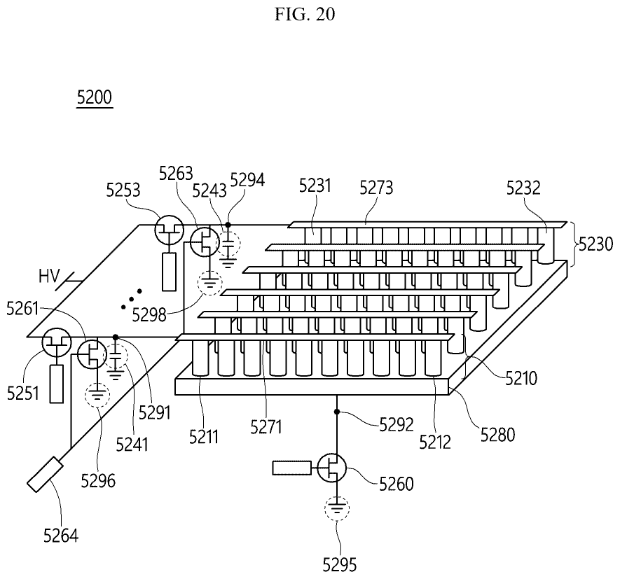

FIG. 19 and FIG. 20 are diagrams illustrating a laser emission array according to another embodiment.

Before describing FIG. 19 and FIG. 20, the above corresponding description can be applied to the components described with reference to FIG. 19 and FIG. 20, respectively, so repetitive descriptions are omitted.

Referring to FIG. 19, a laser emission array 5200 according to an embodiment may include a plurality of laser emission units, at least one subarray, at least one upper conductor, at least one lower conductor, at least one power supply, at least one switch, and at least one capacitor.

In this case, the at least one subarray may refer to a group of laser emission units operatively connected among the plurality of laser emission units, may refer to a group of laser emission units physically connected, may refer to a group of laser emission units connected to the same power supply, may refer to a group of laser emission units defined by the at least one upper conductor, and may refer to a group of laser emission units defined by a capacitor electrically connected to the at least one power supply, but is not limited thereto.

The laser emission array 5200 according to an embodiment may include a plurality of laser emission units.

For example, the laser emission array 5200 according to an embodiment may include a first laser emission unit 5211, a second laser emission unit 5212, a third laser emission unit 5221, a fourth laser emission unit 5222, a fifth laser emission unit 5231, and a sixth laser emission unit 5232, but is not limited thereto.

In this case, since the above descriptions related to the laser emission units with reference to FIG. 17 and FIG. 18 can be applied to the first laser emission unit 5211, the second laser emission unit 5212, the third laser emission unit 5221, the fourth laser emission unit 5222, the fifth laser emission unit 5231, and the sixth laser emission unit 5232, repetitive descriptions are omitted.

Further, the laser emission array 5200 according to an embodiment may include at least one subarray.

For example, the laser emission array 5200 according to an embodiment may include a first subarray 5210, a second subarray 5220, and a third subarray 5230, but is not limited thereto.

Since the above descriptions related to the subarrays with reference to FIG. 17 and FIG. 18 can be applied to the first subarray 5210, the second subarray 5220, and the third subarray 5230, repetitive descriptions are omitted.

Further, the laser emission array 5200 according to an embodiment may include at least one capacitor.

For example, the laser emission array 5200 according to an embodiment may include a first capacitor 5241, a second capacitor 5242, and a third capacitor 5243, but is not limited thereto.

In this case, since the above descriptions related to the capacitors with reference to FIG. 17 and FIG. 18 can be applied to the first capacitor 5241, the second capacitor 5242, and the third capacitor 5243, repetitive descriptions are omitted.

Further, the laser emission array 5200 according to an embodiment may include at least one charging switch and charging switch driver.

For example, the laser emission array 5200 according to an embodiment may include a first charging switch 5251, a first charging switch driver, a second charging switch 5252, a second charging switch driver, a third charging switch 5253, and a third charging switch driver, but is not limited thereto.

In this case, since the above descriptions related to the charging switches and charging switch drivers with reference to FIG. 17 and FIG. 18 can be applied to the first charging switch 5251, the first charging switch driver, the second charging switch 5252, the second charging switch driver, the third charging switch 5253, and the third charging switch driver, repetitive descriptions are omitted.

Further, the laser emission array 5200 according to an embodiment may include at least one common driving switch and common driving switch driver.

For example, the laser emission array 5200 according to an embodiment may include a common driving switch 5260 and a common driving switch driver, but is not limited thereto.

In this case, since the above descriptions related to the common driving switches and the common driving switch drivers with reference to FIG. 17 and FIG. 18 can be applied to the common driving switch 5260 and the common driving switch driver, repetitive descriptions are omitted.

Further, the laser emission array 5200 according to an embodiment may include at least one upper conductor.

For example, the laser emission array 5200 according to an embodiment may include a first upper conductor 5271 and a third upper conductor 5273, but is not limited thereto.

In this case, since the above descriptions related to the upper conductors with reference to FIG. 17 and FIG. 18 can be applied to the first upper conductor 5271 and the third upper conductor 5273, repetitive descriptions are omitted.

Further, the laser emission array 5200 according to an embodiment may include at least one lower conductor.

For example, the laser emission array 5200 according to an embodiment may include a lower conductor 5280, but is not limited thereto.

In this case, since the above descriptions related to the lower conductors with reference to FIG. 17 and FIG. 18 can be applied to the lower conductor 5280, repetitive descriptions are omitted.

Further, the laser emission array 5200 according to an embodiment may include at least one node.

For example, the laser emission array 5200 according to an embodiment may include a first node 5291, a second node 5292, a third node 5293, and a fourth node 5295, but is not limited thereto.

In this case, since the above descriptions related to the nodes with reference to FIG. 17 and FIG. 18 can be applied to the first node 5291, the second node 5292, the third node 5293, and the fourth node 5295, repetitive descriptions are omitted.

Further, the laser emission array 5200 according to an embodiment may include at least one ground.

For example, the laser emission array 5200 according to an embodiment may include a first ground 5295, but is not limited thereto.

In this case, since the above descriptions related to the grounds with reference to FIG. 17 and FIG. 18 can be applied to the first ground 5295, repetitive descriptions are omitted.

Further, since the descriptions provided above with reference to FIG. 17 and FIG. 18 can also be applied to the relationships between various components included in the laser emission array 5200 according to an embodiment, repetitive descriptions are omitted.

Referring to FIG. 19 and FIG. 20 again, the laser emission array 5200 according to an embodiment may include at least one discharging switch for controlling discharging of the at least one capacitor.

In this case, the at least one discharging switch may be implemented as a Field Effect Transistor (FET), but is not limited thereto.

For example, the laser emission array 5200 according to an embodiment may include a first discharging switch 5261 for controlling discharging of the first capacitor 5241, but is not limited thereto.

Further, for example, the laser emission array 5200 according to an embodiment may include a second discharging switch 5262 for controlling discharging of the second capacitor 5242, but is not limited thereto.

Further, for example, the laser emission array 5200 according to an embodiment may include a third discharging switch 5263 for controlling discharging of the third capacitor 5243, but is not limited thereto.

Further, at least one discharging switch according to an embodiment may be positioned between the at least one capacitor included in the laser emission array 5200 and a ground.

For example, the first discharging switch 5261 according to an embodiment may be positioned between the first capacitor 5241 and a second ground 5296, but is not limited thereto.

For example, the second discharging switch 5262 according to an embodiment may be positioned between the second capacitor 5242 and a third ground 5297, but is not limited thereto.

For example, the third discharging switch 5263 according to an embodiment may be positioned between the third capacitor 5243 and a fourth ground 5298, but is not limited thereto.

Further, at least one discharging switch according to an embodiment may be connected (coupled) to at least one node.

For example, the first discharging switch 5261 may be connected to the first node 5291, but is not limited thereto.

Further, for example, the second discharging switch 5262 may be connected to the third node 5293, but is not limited thereto.

Further, for example, the third discharging switch 5263 may be connected to the fourth node 5294, but is not limited thereto.

Further, the laser emission array 5200 according to an embodiment may include a discharging switch driver for controlling driving of the at least one discharging switch.

For example, as shown in FIG. 19 and FIG. 20, the laser emission array 5200 according to an embodiment may include a discharging switch common driver 5264 for controlling driving of the first discharging switch 5261, the second discharging switch 5262, and the third discharging switch 5263, but is not limited thereto.

Further, for example, though not shown in FIG. 19 and FIG. 20, the laser emission array 5200 according to an embodiment may include a first discharging switch driver for controlling driving of the first discharging switch 5261, a second discharging switch driver for controlling driving of the second discharging switch 5262, and a third discharging switch driver for controlling driving of the third discharging switch 5263, but is not limited thereto.

Further, according to an embodiment, the at least one discharging switch and the at least one charging switch may be formed on the same substrate, and the at least one common driving switch may be formed on a different substrate.

For example, the at least one discharging switch and the at least one charging switch may be formed on a first substrate, the at least one common driving switch may be formed on a second substrate, and the composition of the materials constituting the first substrate and the second substrate may be different from each other, but the present disclosure is not limited thereto.

Further, according to an embodiment, the at least one common driving switch can operate at a higher speed than the at least one charging switch.

Further, according to an embodiment, the at least one common driving switch can operate at a higher speed than the at least one discharging switch.

Further, according to an embodiment, the emitting timing of a laser may be determined on the basis of a trigger signal for operating the at least one common driving switch.

For example, the laser emission array 5200 according to an embodiment can acquire a first trigger signal for operating the first charging switch 5251, can acquire a second trigger signal for operating the first discharging switch 5261, and can acquire a third trigger signal for operating the common driving switch 5260, and the emitting timing of a laser can be determined on the basis of the third trigger signal, but the present disclosure is not limited thereto.

Hereafter, the operation of the laser emission array having the configuration described above is described in more detail.

### [Laser Emission Operation of First Laser Emission Unit 5211 and Second Laser Emission Unit 5212 Included in First Subarray 5210 for Plurality of Cycles]

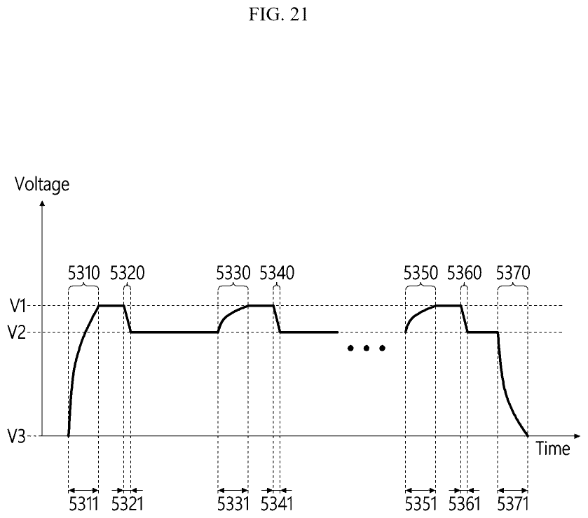

Hereafter, a more detailed description is provided with additional reference to FIG. 21.

FIG. 21 is a diagram illustrating an operation sequence of a laser emission array according to an embodiment and a charging voltage of a capacitor included in a laser emission array which changes in accordance with the operation sequence.

Prior to describing FIG. 21, it is noted that FIG. 21 is described, for the convenience of explanation, on the basis of the laser emission array 5200 and the first capacitor 5241 included in the laser emission array 5200 that have been described with reference to FIGS. 19 and 20.

Referring to FIG. 21, an operation sequence of the laser emission array 5200 according to an embodiment may include at least one charging sequence, at least one driving sequence, and at least one discharging sequence.

For example, the operation sequence of the laser emission array 5200 according to an embodiment may include a first charging sequence 5310, a second charging sequence 5330, and a third charging sequence 5350, but is not limited thereto.

For example, the operation sequence of the laser emission array 5200 according to an embodiment may include a first driving sequence 5320, a second driving sequence 5340, and a third driving sequence 5360, but is not limited thereto.

Further, for example, the operation sequence of the laser emission array 5200 according to an embodiment may include a first discharging sequence 5370, but is not limited thereto.

In this case, the sequence may refer to a time interval during which a series of operations is performed.

For example, the charging sequence may refer to a time interval during which a series of operations is performed to charge a capacitor according to an embodiment, the driving sequence may refer to a time interval during which a series of operations is performed to discharge a capacitor according to an embodiment and to emit a laser from the laser emission unit according to an embodiment, and the discharging sequence may refer to a time interval during which a series of operations is performed to discharge capacitor according to an embodiment.

Further, the sequence may refer to a time interval that is specified on the basis voltage variation of a capacitor.

For example, the charging sequence may refer to a time interval during which a capacitor according to an embodiment is charged and a voltage increases, the driving sequence may refer to a time interval during which a capacitor according to an embodiment is discharged so that a laser is emitted from the laser emitting unit in accordance with an embodiment, and the discharging sequence may refer to a time interval during which a capacitor according to an embodiment is discharged and a voltage decreases.

Further, a plurality of cycles may mean that the cycle is performed several time when it is assumed that a series of operations of emitting a laser from a LiDAR device that includes the laser emission array 5200 according to an embodiment and of sensing the laser reflected from an object after emitted is defined as one cycle, but this is not limited thereto and may include contents that are generally understood as a cycle.

In the first charging sequence 5310 according to an embodiment, the laser emission array 5200 can acquire a first trigger signal for operating the first charging switch driver.

For example, in the first charging sequence 5310 according to an embodiment, the laser emission array 5200 can acquire a first trigger signal for operating the first charging switch driver from the controller included in the LiDAR device, but the present disclosure is not limited thereto.

Further, in the first charging sequence 5310 according to an embodiment, the first charging switch 5251 can be turned on by the operation of the first charging switch driver.

For example, in the first charging sequence 5310 according to an embodiment, the first charging switch driver connected to a gate of the first charging switch 5251 can be operated by the first trigger signal, and the first charging switch 5251 can be turned on by the operation of the first charging switch driver, but the present disclosure is not limited thereto.

Further, in the first charging sequence 5310 according to an embodiment, as the charging switch 5251 is turned on, the first capacitor 5241 can be charged by the power supply HV.

For example, in the first charging sequence 5310 according to an embodiment, as the charging switch 5251 is turned on, a current can flow from the power supply HV to the first capacitor 5251 through the first charging switch 5251 and the first node 5291, whereby the first capacitor 5241 can be charged, but the present disclosure is not limited thereto.

Further, in the first charging sequence 5310 according to an embodiment, the first capacitor 5241 can be charged to have a specific voltage.

For example, in the first charging sequence 5310 according to an embodiment, the first capacitor 5241 can be charged to have a first voltage V1, but the present disclosure is not limited thereto.

Further, in the first charging sequence 5310 according to an embodiment, the first capacitor 5241 can be charged to have a specific electric charge quantity.

For example, in the first charging sequence 5310 according to an embodiment, the first capacitor 5241 can be charged to have a first electric charge quantity, but the present disclosure is not limited thereto.

In this case, the first voltage V1 of the first capacitor 5241 may vary depending on the capacitance of the first capacitor 5241 and the magnitude of the voltage of the power supply HV.

Further, in the first charging sequence 5310 according to an embodiment, the time during which the first charging switch 5251 is turned on may have a specific time duration.

For example, the time during which the first charging switch 5251 is turned on in the first charging sequence 5310 according to an embodiment may have a first time duration 5311, but the present disclosure is not limited thereto.

Further, in the first driving sequence 5320 according to an embodiment, the laser emission array 5200 can acquire a second trigger signal for operating the common driving switch driver.

For example, in the first driving sequence 5320 according to an embodiment, the laser emission array 5200 can acquire a second trigger signal for operating the common driving switch driver from the controller included in the LiDAR device, but the present disclosure is not limited thereto.

Further, in the first driving sequence 5320 according to an embodiment, the common driving switch 5260 can be turned on by the operation of the common driving switch driver.

For example, in the first driving sequence 5320 according to an embodiment, the common driving switch driver connected to a gate of the common driving switch 5260 can be operated by the second trigger signal, and the common driving switch 5260 can be turned on by the operation of the common driving switch driver, but the present disclosure is not limited thereto.

Further, in the first driving sequence 5320 according to an embodiment, as the common driving switch 5260 is turned on, energy can be supplied to the first laser emission unit 5211 and the second laser emission unit 5212 included in the first subarray 5210 by the first capacitor 5241, whereby a first laser and a second laser can be emitted.

For example, in the first driving sequence 5320 according to an embodiment, as the common driving switch 5260 is turned on, the electric charges stored in the first capacitor 5241 are discharged, a current can flow between the first capacitor 5241 and the first ground 5295, at least a portion of the current can generate light in the active area of the first laser emission unit 5211 by passing through the first laser emission unit 5211, another at least portion of the current can generate light in the active area of the second laser emission unit 5212 by passing through the second laser emission unit 5212, and the light generated from the first and second laser emission units 5211 and 5212 can be emitted from their respective surfaces, which can be represented as a third laser and a fourth laser, respectively, but the present disclosure is not limited thereto.

Further, in the first driving sequence 5320 according to an embodiment, the voltage of the first capacitor 5241 may vary.

For example, in the first driving sequence 5320 according to an embodiment, the voltage of the first capacitor 5241 may vary from a first voltage V1 to a second voltage V2, but the present disclosure is not limited thereto.

In this case, in order to reduce the load of the laser emission units included in the non-operating channel (e.g., the second subarray 5220) by the voltage of the first capacitor 5241, the second voltage V2 may be less than 50% of the first voltage V1, but the present disclosure is not limited thereto.

Further, in this case, in order to reduce the load of the laser emission units included in the non-operating channel (e.g., the second subarray 5220) by the voltage of the first capacitor 5241, the second voltage V2 may be less than 30% of the first voltage V1, but the present disclosure is not limited thereto.

Further, in this case, in order to reduce the power that is consumed in the laser emission array 5200, the second voltage V2 may be 10% or more of the first voltage V1, but the present disclosure is not limited thereto.

Further, in this case, in order to reduce the power that is consumed in the laser emission array 5200, the second voltage V2 may be 50% or more of the first voltage V1, but the present disclosure is not limited thereto.

Further, in the first driving sequence 5320 according to an embodiment, the electric charge quantity of the first capacitor 5241 may vary.

For example, in the first driving sequence 5320 according to an embodiment, the electric charge quantity of the first capacitor 5241 may vary from the first electric charge quantity to a second electric charge quantity, but the present disclosure is not limited thereto.

In this case, in order to reduce the load of the laser emission units included in the non-operating channel (e.g., the second subarray 5220) by the voltage of the first capacitor 5241, the second electric charge quantity may be less than 50% of the first electric charge quantity, but the present disclosure is not limited thereto.

In this case, in order to reduce the load of the laser emission units included in the non-operating channel (e.g., the second subarray 5220) by the voltage of the first capacitor 5241, the second electric charge quantity may be less than 30% of the first electric charge quantity, but the present disclosure is not limited thereto.

Further, in this case, in order to reduce the power that is consumed in the laser emission array 5200, the second electric charge quantity may be 50% or more of the first electric charge quantity, but the present disclosure is not limited thereto.

Further, in this case, in order to reduce the power that is consumed in the laser emission array 5200, the second electric charge quantity may be 70% or more of the first electric charge quantity, but the present disclosure is not limited thereto.

In this case, in order to reduce the load of the laser emission units included in the non-operating channel (e.g., the second subarray 5220) by the voltage of the first capacitor 5241 and in order to reduce the power that is consumed in the laser emission array 5200, the second electric charge quantity may be 10% or more and less than 50% of the first electric charge quantity, but the present disclosure is not limited thereto.

Further, in the first driving sequence 5320 according to an embodiment, the first capacitor 5241 can be discharged by a specific voltage difference.

For example, in the first driving sequence 5320 according to an embodiment, the first capacitor 5241 can be discharged by a first voltage difference V1−V2, but the present disclosure is not limited thereto.

Further, the electric charge quantity discharged from the first capacitor 5241 in the first driving sequence 5320 according to an embodiment may be less than the electric charge quantity charged into the first capacitor 5241 in the first charging sequence 5310.

For example, in the first driving sequence 5320 according to an embodiment, the electric charge quantity discharged from the first capacitor 5241 may be the first electric charge quantity—the second electric charge quantity, and the electric charge quantity charged into the first capacitor 5241 in the first charging sequence 5310 may be the first electric charge quantity, so the electric charge quantity discharged from the first capacitor 5241 in the first driving sequence 5320 according to an embodiment may be less than the electric charge quantity charged into the first capacitor 5241 in the first charging sequence 5310, but the present disclosure is not limited thereto.

Further, in the first driving sequence 5320 according to an embodiment, the time during which the common driving switch 5260 is turned on may have a specific time duration.

For example, in the first driving sequence 5320 according to an embodiment, the time during which the common driving switch 5260 is turned on may have a second time duration 5321, but the present disclosure is not limited thereto.

Further, the time during which the common driving switch 5260 is turned on in the first driving sequence 5320 according to an embodiment may have a shorter time duration than the time during which the first charging switch 5251 is turned on in the first charging sequence 5310 according to an embodiment.

For example, in the first driving sequence 5320 according to an embodiment, the time during which the common driving switch 5260 is turned on has a second time duration 5321, and in the first charging sequence 5310 according to an embodiment, the time during which the first charging switch 5251 is turned on has a first time duration 5311, and the second time duration 5321 may be shorter than the first time duration 5311.

That is, the common driving switch 5260 needs to perform high-speed switching operation, while the first charging switch 5251 may perform relatively low-speed switching operation.

Further, the second time duration 5321, which is the time duration during which the common driving switch 5260 is turned on in the first driving sequence 5320 according to an embodiment, can be determined on the basis of the second voltage V2.

For example, the second time duration 5321 when the second voltage V2 is 50% of the first voltage V1 may be shorter than the second time duration 5321 when the second voltage V2 is 30% of the first voltage V1.

That is, the lower the second voltage V2, the longer the second time duration 5321 can be.

Further, the second time duration 5321, which is the time duration during which the common driving switch 5260 is turned on in the first driving sequence 5320 according to an embodiment, can be determined on the basis of the second electric charge quantity.

For example, the second time duration 5321 when the electric charge quantity is 50% of the first electric charge quantity may be shorter than the second time duration 5321 when the second electric charge quantity is 30% of the first electric charge quantity.

That is, the smaller the second electric charge quantity, the longer the second time duration 5321 can be.

Further, the second time duration 5321, which is the time duration during which the common driving switch 5260 is turned on in the first driving sequence 5320 according to an embodiment, can be determined on the basis of the electric charge quantity that is discharged in the first driving sequence 5320.

For example, the second time duration 5321 when the electric charge quantity discharged in the first driving sequence 5320 (the first electric charge quantity−the second electric charge quantity) is 50% of the first electric charge quantity may be shorter than the second time duration 5321 when the electric charge quantity discharged in the first driving sequence 5320 (the first electric charge quantity−the second electric charge quantity) is 70% of the first electric charge quantity.

That is, the larger the electric charge quantity discharged in the first driving sequence 5320 (the first electric charge quantity−the second electric charge quantity), the longer the second time duration 5321 can be.

Further, according to an embodiment, the first charging sequence described above and the first driving sequence described above can be alternately performed during a plurality of cycles.

For example, according to an embodiment, the first charging sequence described above and the first driving sequence described above may be alternately performed N times each, but are not limited thereto.

This may be represented as a second charging sequence 5330, a third charging sequence 5350, a second driving sequence 5340, and a third driving sequence 5360. Therefore, repetitive descriptions for the second charging sequence 5330, the third charging sequence 5350, the second driving sequence 5340, and the third driving sequence 5360 are omitted.

Further, in the second charging sequence 5330 according to an embodiment, the first capacitor 5241 can be charged to have a specific voltage.

For example, in the second charging sequence 5330 according to an embodiment, the first capacitor 5241 can be charged to have a first voltage V1, but the present disclosure is not limited thereto.

Further, in the second charging sequence 5330 according to an embodiment, the first capacitor 5241 can be charged to have a specific electric charge quantity.

For example, in the second charging sequence 5330 according to an embodiment, the first capacitor 5241 can be charged to have the first electric charge quantity, but the present disclosure is not limited thereto.

Further, the amount of variation in the voltage of the first capacitor 5241 in the second charging sequence 5330 according to an embodiment may be different from the amount of variation in the voltage of the first capacitor 5241 in the first charging sequence 5310.

For example, in the second charging sequence 5330 according to an embodiment, the amount of variation in the voltage of the first capacitor 5241 may be the first voltage V1 minus the second voltage V2, but in the first charging sequence 5310, the amount of variation in the voltage of the first capacitor 5241 may be the first voltage V1 minus the third voltage V3.

In this case, the magnitude of the first voltage V1 minus the second voltage V2 may be smaller than the magnitude of the first voltage V1 minus the third voltage V3.

Further, the amount of variation in the electric charge quantity of the first capacitor 5241 in the second charging sequence 5330 according to an embodiment may be different from the amount of variation in the electric charge quantity of the first capacitor 5241 in the first charging sequence 5310.

For example, in the second charging sequence 5330 according to an embodiment, the amount of variation in the electric charge quantity of the first capacitor 5241 may be the first electric charge quantity minus the second electric charge quantity, but in the first charging sequence 5310, the amount of variation in the electric charge quantity of the first capacitor 5241 may be the first electric charge quantity minus the third electric charge quantity.

In this case, the magnitude of the first electric charge quantity minus the second electric charge quantity may be smaller than the magnitude of the first electric charge quantity−the third electric charge quantity.

Further, the amount of variation in the voltage of the first capacitor 5241 in the second charging sequence 5330 according to an embodiment may be substantially the same as the amount of variation in the voltage of the first capacitor 5241 in the first driving sequence 5320.

For example, in the second charging sequence 5330 according to an embodiment, the amount of variation in the voltage of the first capacitor 5241 may be the first voltage V1 minus the second voltage V2, but in the first driving sequence 5320, the amount of variation in the voltage of the first capacitor 5241 may be the first voltage V1 minus the third voltage V3, so the variation directions of the voltages are different, but the amounts of variation in the voltages can be substantially the same.

Further, the amount of variation in the electric charge quantity of the first capacitor 5241 in the second charging sequence 5330 according to an embodiment may be substantially the same as the amount of variation in the electric charge quantity of the first capacitor 5241 in the first driving sequence 5320.

For example, in the second charging sequence 5330 according to an embodiment, the amount of variation in the electric charge quantity of the first capacitor 5241 may be the first electric charge quantity minus the second electric charge quantity, but in the first driving sequence 5320, the amount of variation in the electric charge quantity of the first capacitor 5241 may be the first electric charge quantity minus the second electric charge quantity, so the variation directions of the electric charge quantities are different, but the amounts of variation in the electric charge quantities can be substantially the same.

Further, in the second charging sequence 5330 according to an embodiment, the time during which the first charging switch 5251 is turned on may have a specific time duration.

For example, the time during which the first charging switch 5251 is turned on in the second charging sequence 5330 according to an embodiment may have a third time duration 5331, but the present disclosure is not limited thereto.

In this case, the third time duration 5331 may be the same as the first time duration 5311, but is not limited thereto and may be set to be different.

Further, in this case, the third time duration 5331 may be longer than the second time duration 5321.

Further, the above descriptions related to the first driving sequence 5320 can be applied to the second driving sequence 5340 according to an embodiment.

However, the magnitude of the varying voltages, the amount of the varying electric charge quantities, etc., can be set to vary depending on the configuration and environmental conditions.

Further, in the second driving sequence 5340 according to an embodiment, the time during which the common driving switch 5260 is turned on may have a fourth time duration 5341, which may be the same as the second time duration 5321, but is not limited thereto and may be set to be different.

Further, the above descriptions related to the second charging sequence 5330 can be applied to the third charging sequence 5350 according to an embodiment.

However, the magnitude of the varying voltages, the amount of the varying electric charge quantities, etc., can be set to vary depending on the configuration and environmental conditions.

Further, in the third charging sequence 5350 according to an embodiment, the time during which the common driving switch 1 is turned on may have a fifth time duration 5351, which may be the same as the third time duration 5331, but is not limited thereto and may be set to be different.

Further, the above descriptions related to the first driving sequence 5320 can be applied to the third driving sequence 5360 according to an embodiment.

However, the magnitude of the varying voltages, the amount of the varying electric charge quantities, etc., can be set to vary depending on the configuration and environmental conditions.

Further, in the third driving sequence 5360 according to an embodiment, the time during which the common driving switch 5260 is turned on may have a sixth time duration 5361, which may be the same as the second time duration 5321, but is not limited thereto and may be set to be different.

Further, according to an embodiment, the first discharging sequence 5370 can be performed after the third driving sequence 5360.

Further, in the first discharging sequence 5370 according to an embodiment, the laser emission array 5200 can acquire a third trigger signal for operating the discharging switch common driver.

For example, in the first discharging sequence 5370 according to an embodiment, the laser emission array 5200 can acquire a third trigger signal for operating the discharging switch common driver 5264 from the controller included in the LiDAR device, but the present disclosure is not limited thereto.

Further, in the first discharging sequence 5370 according to an embodiment, the first discharging switch 5261 can be turned on by the operation of the discharging switch common driver 5264.

For example, in the first discharging sequence 5370 according to an embodiment, the discharging switch common driver 5264 connected to the gate of the first discharging switch 5261 can be operated by the third trigger signal, and the first discharging switch 5261 can be turned on by the operation of the discharging switch common driver 5264, but the present disclosure is not limited thereto.

Further, in the first discharging sequence 5370 according to an embodiment, as the first discharging switch 5261 is turned on, the electric charges charged in the first capacitor 5241 can be discharged.

For example, in the first discharging sequence 5370 according to an embodiment, as the first discharging switch 5261 is turned on, the electric charges charged in the first capacitor 5241 are discharged, and a current can flow between the first capacitor 5241 and the second ground 5296 through the first node 5291 and the first discharging switch 5261, but the present disclosure is not limited thereto.

Further, in the first discharging sequence 5370 according to an embodiment, the voltage of the first capacitor 5241 may vary.

For example, in the first discharging sequence 5370 according to an embodiment, the voltage of the first capacitor may vary from the second voltage V2 to the third voltage V3, but the present disclosure is not limited thereto.

In this case, the magnitude of the third voltage V3 may be 0.

Further, in the first discharging sequence 5370 according to an embodiment, the electric charge quantity of the first capacitor 5241 may vary.

For example, in the first discharging sequence 5370 according to an embodiment, the electric charge quantity of the first capacitor 5241 may vary from the second electric charge quantity to the third electric charge quantity, but the present disclosure is not limited thereto.

In this case, the magnitude of the electric charge quantity may be 0.

Further, in the first discharging sequence 5370 according to an embodiment, the first capacitor 5241 can be discharged by a specific voltage difference.

For example, in the first discharging sequence 5370 according to an embodiment, the first capacitor 5241 can be discharged by a second voltage difference V2−V3, but the present disclosure is not limited thereto.

Further, the electric charge quantity discharged from the first capacitor 5241 in the first discharging sequence 5370 according to an embodiment may be less than the electric charge quantity charged into the first capacitor 5241 in the first charging sequence 5310.

For example, in the first discharging sequence 5370 according to an embodiment, the electric charge quantity discharged from the first capacitor 5241 may be the second electric charge quantity, and the electric charge quantity charged into the first capacitor 5241 in the first charging sequence 5310 may be the first electric charge quantity, so the electric charge quantity discharged from the first capacitor 5241 in the first discharging sequence 5370 according to an embodiment may be less than the electric charge quantity charged into the first capacitor 5241 in the first charging sequence 5310, but the present disclosure is not limited thereto.

Further, the electric charge quantity discharged from the first capacitor 5241 in the first discharging sequence 5370 according to an embodiment may be greater than the electric charge quantity discharged from the first capacitor 5241 in the first driving sequence 5320.

For example, in the first discharging sequence 5370 according to an embodiment, the electric charge quantity discharged from the first capacitor 5241 may be the second electric charge quantity, and the electric charge quantity discharged from the first capacitor 5241 in the first driving sequence 5320 may be the first electric charge quantity minus the second electric charge quantity, so the electric charge quantity discharged from the first capacitor 5241 in the first discharging sequence 5370 according to an embodiment may be greater than the electric charge quantity discharged from the first capacitor 5241 in the first driving sequence 5320, but the present disclosure is not limited thereto.

Further, the electric charge quantity discharged from the first capacitor 5241 in the first discharging sequence 5370 according to an embodiment may be less than the electric charge quantity discharged from the first capacitor 5241 in the first driving sequence 5320. For example, in the first discharging sequence 5370 according to an embodiment, the electric charge quantity discharged from the first capacitor 5241 may be the second electric charge quantity, and the electric charge quantity discharged from the first capacitor 5241 in the first driving sequence 5320 may be the first electric charge quantity minus the second electric charge quantity, so the electric charge quantity discharged from the first capacitor 5241 in the first discharging sequence 5370 according to an embodiment may be less than the electric charge quantity discharged from the first capacitor 5241 in the first driving sequence 5320, but the present disclosure is not limited thereto.

Further, the electric charge quantity discharged from the first capacitor 5241 in the first discharging sequence 5370 according to an embodiment may be less than 50% of the first electric charge quantity that is the electric charge quantity charged in the first charging sequence 5310, but the present disclosure is not limited thereto.

Further, the electric charge quantity discharged from the first capacitor 5241 in the first discharging sequence 5370 according to an embodiment may be less than 20% of the first electric charge quantity that is the electric charge quantity charged in the first charging sequence 5310, but the present disclosure is not limited thereto.

Further, the electric charge quantity discharged from the first capacitor 5241 in the first discharging sequence 5370 according to an embodiment may be 50% or more of the first electric charge quantity that is the electric charge quantity charged in the first charging sequence 5310, but the present disclosure is not limited thereto.

Further, the electric charge quantity discharged from the first capacitor 5241 in the first discharging sequence 5370 according to an embodiment may be 70% or more of the first electric charge quantity that is the electric charge quantity charged in the first charging sequence 5310, but the present disclosure is not limited thereto.

Further, the electric charge quantity discharged from the first capacitor 5241 in the first discharging sequence 5370 according to an embodiment may be 10% or more and less than 50% of the first electric charge quantity that is the electric charge quantity charged in the first charging sequence 5310, but the present disclosure is not limited thereto.

Further, the electric charge quantity discharged from the first capacitor 5241 in the first discharging sequence 5370 according to an embodiment may be less than the electric charge quantity discharged from the first capacitor 5241 in the first driving sequence 5320.

For example, when the electric charge quantity discharged in the first driving sequence 5320 is (first electric charge quantity-second electric charge quantity) and the electric charge quantity discharged in the first discharging sequence 5370 is (second electric charge quantity minus third electric charge quantity), and the (first electric charge quantity minus second electric charge quantity) may be greater than the (second electric charge quantity-third electric charge quantity), and in this case, the second electric charge quantity may be less than 50% of the first electric charge quantity.

Further, in the first discharging sequence 5370 according to an embodiment, the time during which the first discharging switch 5261 is turned on may have a specific time duration.

For example, the time during which the first discharging switch 5261 is turned on in the first discharging sequence 5370 according to an embodiment may have a seventh time duration 5371, but the present disclosure is not limited thereto.

In this case, the seventh time duration 5371 may be substantially the same as the first time duration 5311, but is not limited thereto and may be set to be different.

Further, the seventh time duration 5371 may be set to be longer than the second time duration 5321.

That is, the common driving switch 5260 needs to perform high-speed switching operation, while the first charging switch 5251 and the first discharging switch 5261 may perform relatively low-speed switching operation.

Further, the voltage drop speed of the first capacitor 5241 in the first driving sequence 5320 according to an embodiment may be faster than the voltage drop speed of the first capacitor 5241 in the first discharging sequence 5370.

Further, when the magnitude of the electric charge quantity discharged in the first discharging sequence 5370 is smaller than the magnitude of the electric charge quantity discharged in the first driving sequence 5320, the seventh time duration 5371 may be set to be shorter than the second time duration 5321.

[Laser emission operation of third laser emission unit 5221 and fourth laser emission unit 5222 included in second subarray 5220 for plurality of cycles], [Laser emission operation of fifth laser emission unit 5231 and sixth laser emission unit 5232 included in third subarray 5230 for plurality of cycles], and [Selection of laser emission channel (sub-array)] can be sufficiently understood on the basis of the descriptions provided with reference to FIG. 19, FIG. 20, and FIG. 21, and the descriptions provided with reference to FIG. 17 and FIG. 18, and thus repetitive descriptions are omitted.

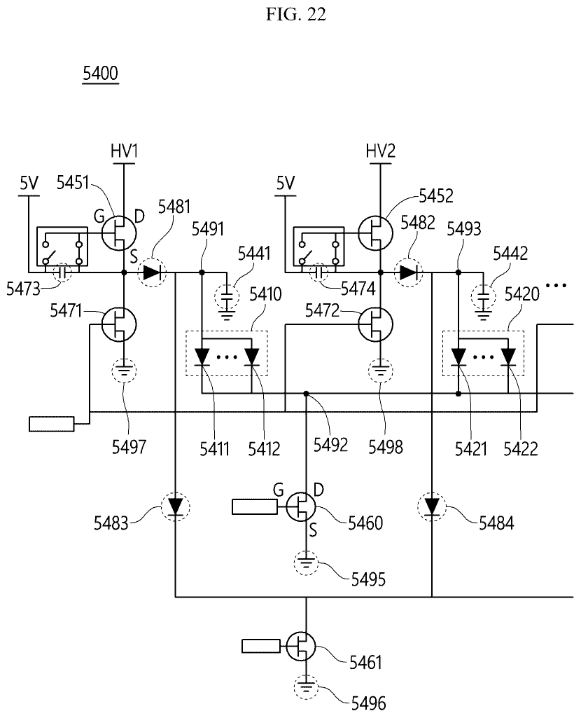

FIG. 22 is a diagram illustrating a laser emission array according to another embodiment.

Prior to describing FIG. 22, the corresponding description above can be applied to the components to be described with reference to FIG. 22, so repetitive descriptions are omitted.

Referring to FIG. 22, a laser emission array 5400 according to an embodiment may include a plurality of laser emission units, at least one subarray, at least one power supply, at least one switch, and at least one capacitor.

In this case, the at least one subarray may refer to a group of laser emission units operatively connected among the plurality of laser emission units, may refer to a group of laser emission units physically connected, may refer to a group of laser emission units connected to the same power supply, may refer to a group of laser emission units defined by the at least one upper conductor, and may refer to a group of laser emission units defined by a capacitor electrically connected to the at least one power supply, but is not limited thereto.

The laser emission array 5400 according to an embodiment may include a plurality of laser emission units.

For example, the laser emission array 5400 according to an embodiment may include a first laser emission unit 5411, a second laser emission unit 5412, a third laser emission unit 5421, and a fourth laser emission unit 5422, but is not limited thereto.

In this case, the above descriptions related to the laser emission units with reference to FIG. 17 to FIG. 21 can be applied to the first laser emission unit 5411, the second laser emission unit 5412, the third laser emission unit 5421, and the fourth laser emission unit 5422, so repetitive descriptions are omitted.

Further, the laser emission array 5400 according to an embodiment may include at least one subarray.

For example, the laser emission array 5400 according to an embodiment may include a first subarray 5410 and a second subarray 5420, but is not limited thereto.

In this case, since the above descriptions related to the subarrays with reference to FIG. 17 to FIG. 21 can be applied to the first subarray 5410 and the second subarray 5420, repetitive descriptions are omitted.

Further, the laser emission array 5400 according to an embodiment may include at least one capacitor.

For example, the laser emission array 5400 according to an embodiment may include a first capacitor 5441 and a second capacitor 5442, but is not limited thereto.

In this case, since the above descriptions related to the capacitors with reference to FIG. 17 to FIG. 21 can be applied to the first capacitor 5441 and the second capacitor 5442, repetitive descriptions are omitted.

Further, the laser emission array 5400 according to an embodiment may include at least one charging switch and charging switch driver.

For example, the laser emission array 5400 according to an embodiment may include a first charging switch 5451, a first charging switch driver, a second charging switch 5452, and a second charging switch driver, but is not limited thereto.

In this case, since the above descriptions related to the charging switches and charging switch drivers with reference to FIG. 17 to FIG. 21 can be applied to the first charging switch 5451, the first charging switch driver, the second charging switch 5452, and the second charging switch driver, repetitive descriptions are omitted.

Further, the laser emission array 5400 according to an embodiment may include at least one common driving switch and common driving switch driver.

For example, the laser emission array 5400 according to an embodiment may include a common driving switch 5460 and a common driving switch driver, but is not limited thereto.

In this case, since the above descriptions related to the common driving switches and the common driving switch drivers with reference to FIG. 17 to FIG. 21 can be applied to the common driving switch 5460 and the common driving switch driver, repetitive descriptions are omitted.

Further, the laser emission array 5400 according to an embodiment may include at least one node.

For example, the laser emission array 5400 according to an embodiment may include a first node 5491, a second node 5492, and a third node 5493, but is not limited thereto.

In this case, since the above descriptions related to the nodes with reference to FIG. 17 to FIG. 21 can be applied to the first node 5491, the second node 5492, and the third node 5493, repetitive descriptions are omitted.

Further, the laser emission array 5400 according to an embodiment may include at least one ground.

For example, the laser emission array 5400 according to an embodiment may include a first ground 5495 and a second ground 5496, but is not limited thereto.

In this case, since the above descriptions related to the first ground with reference to FIG. 17 to FIG. 21 can be applied to the first ground 5495 and the above descriptions related to the second ground with reference to FIG. 19 to FIG. 21 can be applied to the second ground 5496, repetitive descriptions are omitted.

Further, since the descriptions provided above with reference to FIG. 17 to FIG. 21 can also be applied to the relationships between various components included in the laser emission array 5400 according to an embodiment, repetitive descriptions are omitted.

Referring to FIG. 22 again, the laser emission array 5400 according to an embodiment may include at least one discharging switch for controlling discharging of the at least one capacitor.

In this case, the at least one discharging switch may be implemented as a Field Effect Transistor (FET), but is not limited thereto.

Further, in this case, the at least one discharging switch may be implemented as one common switch, which is different from what has been described with reference to FIGS. 19 to 21.

For example, referring to FIG. 22, the laser emission array 5400 according to an embodiment may include a common discharging switch 5461, which may be an implementation of the configurations corresponding to the first to third discharging switches described with reference to FIGS. 19 to 21 as one common switch, but is not limited thereto.

In this case, since the above descriptions of the first to third discharging switches with reference to FIGS. 19 to 21 can also be applied to the common discharging switch 5461, repetitive descriptions are omitted.

Referring to FIG. 22 again, the laser emission array 5400 according to an embodiment may include at least one charging switch for controlling charging of a capacitor for supplying energy to at least one charging switch driver.

For example, the laser emission array 5400 according to an embodiment may include a third charging switch 5471 for controlling charging of the third capacitor 5473 for supplying energy to a first charging driver, but is not limited thereto.

Further, for example, the laser emission array 5400 according to an embodiment may include a fourth charging switch 5472 for controlling charging of the fourth capacitor 5474 for supplying energy to a second charging driver, but is not limited thereto.

Further, the at least one charging switch for controlling charging of the capacitor for supplying energy to at least one charging switch driver may be positioned between the capacitor for supplying energy to the at least one charging switch driver and a ground.

For example, the third charging switch 5471 according to the embodiment may be positioned between the third capacitor 5473 and a third ground 5497, but is not limited thereto.

For example, the fourth charging switch 5472 according to the embodiment may be positioned between the fourth capacitor 5474 and a fourth ground 5498, but is not limited thereto.

Further, at least one charging switch for controlling charging of a capacitor for supplying energy to at least one charging switch driver according to an embodiment may be connected (coupled) to at least one node.

For example, the third charging switch 5471 may be connected to the first node 5491, but is not limited thereto.

Further, for example, the fourth charging switch 5472 may be connected to the third node 5293, but is not limited thereto.

Hereafter, for the convenience of explanation, the switch for controlling charging of a capacitor for supplying energy to the laser emission unit included in the laser emission array 5400 according to an embodiment is referred to as a high-side switch, and the switch for controlling charging of a capacitor for supplying energy to the driver for driving the high-side switch is referred to as a low-side switch.

That is, the first charging switch 5451 and the second charging switch 5452 described with reference to FIG. 22 are referred to as a first high-side switch 5451 and a second high-side switch 5452, respectively, and the third charging switch 5471 and the fourth charging switch 5472 are referred to as a first low-side switch 5471 and a second low-side switch 5472, respectively.

Referring to FIG. 22 again, the laser emission array 5400 according to an embodiment may include at least one diode for preventing discharge of a capacitor for supplying energy to at least one laser emission unit by driving at least one low-side switch.

For example, the laser emission array 5400 according to an embodiment may include a first diode 5481 for preventing discharge of the electric charge quantity stored in the first capacitor 5441 by driving the first low-side switch 5471, but the present disclosure is not limited thereto.

For example, the laser emission array 5400 according to an embodiment may include a second diode 5482 for preventing discharge of the electric charge quantity stored in the second capacitor 5442 by driving the second low-side switch 5472, but the present disclosure is not limited thereto.

Further, at least one diode according to an embodiment may be positioned between at least one low-side switch and a capacitor for supplying energy to at least one laser emission unit.

For example, the first diode 5481 according to an embodiment may be positioned between the first low-side switch 5471 and the first capacitor 5441.

Further, for example, the second diode 5482 according to an embodiment may be positioned between the second low-side switch 5472 and the second capacitor 5442.

Referring to FIG. 22 again, the laser emission array 5400 according to an embodiment may include at least one diode for preventing interference between channels.

For example, the laser emission array 5400 according to an embodiment may include a third diode 5483 for preventing the first capacitor 5441 from being charged by driving the second low-side switch 5452, but the present disclosure is not limited thereto.

This can be understood as preventing the first capacitor 5441 from being charged by not only driving of the second high-side switch 5452, but driving of other high-side switches, excluding the first high-side switch 5451, in order to prevent interference between the channels.

Further, for example, the laser emission array 5400 according to an embodiment may include a fourth diode 5484 for preventing the second capacitor 5442 from being charged by driving the first high-side switch 5451, but the present disclosure is not limited thereto.

This can be understood as preventing the first capacitor 5441 from being charged by not only driving of the first high-side switch 5451, but driving of other high-side switches, excluding the second high-side switch 5452, in order to prevent interference between the channels.

Further, at least one diode according to an embodiment may be positioned between at least one discharging switch and at least one capacitor.

For example, the third diode 5483 according to an embodiment may be positioned between the common discharging switch 5461 and the first capacitor 5441, but is not limited thereto.

For example, the fourth diode 5484 according to an embodiment may be positioned between the common discharging switch 5461 and the second capacitor 5442, but is not limited thereto.

Hereafter, the operation of the laser emission array having the configuration described above is described in more detail.

### [Laser Emission Operation of First Laser Emission Unit 5411 and Second Laser Emission Unit 5412 Included in First Subarray 5410 for Plurality of Cycles]

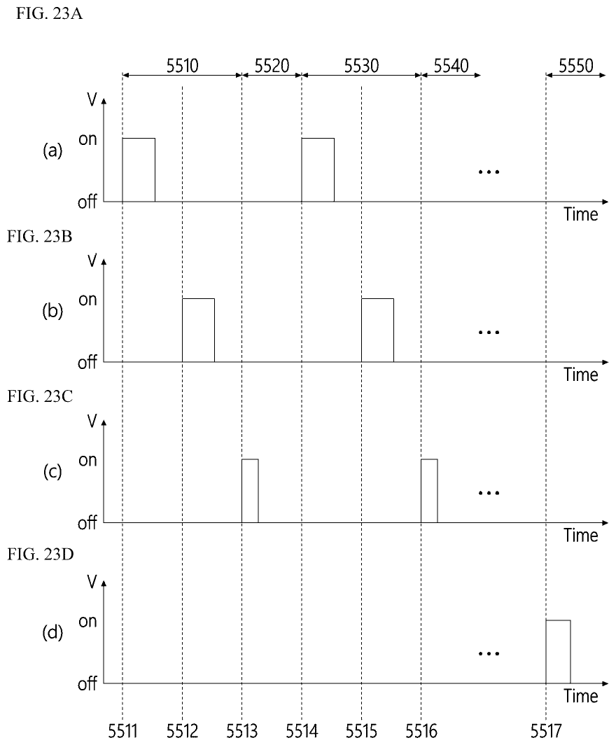

Hereafter, a more detailed description is provided with additional reference to FIGS. 23A through 23D.

FIGS. 23A through 23D are diagrams illustrating an operation sequence of a laser emission array according to an embodiment and driving of various switches depending on the operation sequence.

Prior to describing FIGS. 23A through 23D, it is noted that FIGS. 23A through 23D are described on the basis of the laser emission array 5400 described with reference to FIG. 22, for the convenience of explanation.

Referring to FIGS. 23A through 23D, an operation sequence of the laser emission array 5400 according to an embodiment may include at least one charging sequence, at least one driving sequence, and at least one discharging sequence.

For example, the operation sequence of the laser emission array 5400 according to an embodiment may include a first charging sequence 5310 and a second charging sequence 5330, but is not limited thereto.

Further, for example, the operation sequence of the laser emission array 5400 according to an embodiment may include a first driving sequence 5320 and a second driving sequence 5340, but is not limited thereto.

Further, for example, the operation sequence of the laser emission array 5400 according to an embodiment may include a first discharging sequence 5470, but is not limited thereto.

In this case, since the descriptions provided above with reference to FIG. 17 to FIG. 21 can be applied to the first charging sequence 5310, the second charging sequence 5330, the first driving sequence 5320, the second driving sequence 5340, and the first discharging sequence 5370, repetitive descriptions are omitted.

Prior to providing a more detailed description, a more specific description of FIGS. 23A through 23D are as follows: FIG. 23A is a graph illustrating, over time, a gate voltage of the first low-side switch 5471 included in the laser emission array 5400 according to an embodiment; FIG. 23B is a graph illustrating, over time, a gate voltage of the first high-side switch 5451 included in the laser emission array 5400 according to an embodiment; FIG. 23C is a graph illustrating, over time, a gate voltage of the common driving switch 5460 included in the laser emission array 5400 according to an embodiment; and FIG. 23D is a graph illustrating, over time, a gate voltage of the common discharging switch 5461 included in the laser emission array 5400 according to an embodiment.

Referring to FIG. 22 and FIG. 23, in the first charging sequence 5510 according to an embodiment, the first low-side switch 5471 can be turned on at a first time point 5511, and as the first low-side switch 5471 is turned on, the third capacitor 5473 can be charged.

Further, referring to FIG. 22 and FIG. 23, in the first charging sequence 5510 according to an embodiment, the first high-side switch 5451 can be turned on at a second time point 5512, which is after the first time point 5511, and as the first high-side switch 5451 is turned on, the first capacitor 5441 can be charged.

In this case, the flow of current between the first power supply HV1 and the first capacitor 5441 can be permitted by the direction of the first diode 5481.

Further, in this case, the flow of current between the first power supply HV1 and the second capacitor 5442 can be blocked by the fourth diode 5484.

Further, referring to FIG. 22 and FIG. 23, in the first driving sequence 5520 according to an embodiment, the common driving switch 5460 can be turned on at a third time point 5513, which is after the second time point 5512, and as the common driving switch 5460 is turned on, energy can be supplied from the first capacitor 5441 to the first laser emission unit 5411 and the second laser emission unit 5412 included in the first subarray 5410.

In this case, after the first driving sequence 5520, at least a portion of electric charges may remain in the first capacitor 5441, and a partial electric charge quantity may be charged in the first capacitor 5441.

Further, referring to FIG. 22 and FIG. 23, in the second charging sequence 5530 according to an embodiment, the first low-side switch 5471 can be turned on at a fourth time point 5514, which is after the third time point 5513, and as the first low-side switch 5471 is turned on, the third capacitor 5473 can be charged.

In this case, the flow of current between the first capacitor 5441 and the third ground 5497 can be blocked by the first diode 5481.

Further, referring to FIG. 22 and FIG. 23, in the second charging sequence 5530 according to an embodiment, the first high-side switch 5451 can be turned on at a fifth time point 5515, which is after the fourth time point 5514, and as the first high-side switch 5451 is turned on, the first capacitor 5441 can be charged.

In this case, the flow of current between the first power supply HV1 and the first capacitor 5441 can be permitted by the direction of the first diode 5481.

Further, in this case, the flow of current between the first power supply HV1 and the second capacitor 5442 can be blocked by the fourth diode 5484.

Further, referring to FIG. 22 and FIG. 23, in the second driving sequence 5540 according to an embodiment, the common driving switch 5460 can be turned on at a sixth time point 5516, which is after the fifth time point 5515, and as the common driving switch 5460 is turned on, energy can be supplied from the first capacitor 5441 to the first laser emission unit 5411 and the second laser emission unit 5412 included in the first subarray 5410.

In this case, after the second driving sequence 5540, at least a portion of electric charges may remain in the first capacitor 5441, and a partial electric charge quantity may be charged in the first capacitor 5441.

Further, referring to FIG. 23, the charging sequence and driving sequence described above can be repeated N times.

Further, referring to FIG. 22 and FIG. 23, in the first discharging sequence 5550 according to an embodiment, the common discharging switch 5461 can be turned on at a seventh time point 5517, which is after the sixth time point 5516, and as the common discharging switch 5461 is turned on, the electric charges remaining in the first capacitor 5441 can be discharged.

In this case, the flow of current between the first capacitor 5441 and the second ground 5496 can be permitted by the direction of the third diode 5483.

Since [Laser emission operation of third laser emission unit 5421 and the fourth laser emission unit 5422 included in second subarray 5420 for plurality of cycles] and [Selection of laser emission channel (subarray)] can be sufficiently understood on the basis of the descriptions provided with reference to FIG. 17 to FIG. 23, repetitive descriptions are omitted.

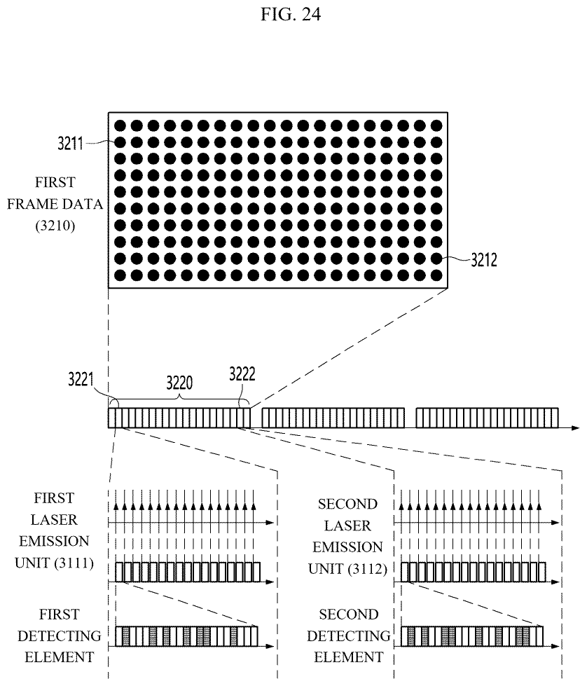

FIG. 24 is a diagram illustrating driving of the LiDAR device according to an embodiment.

The contents to be described with reference to FIG. 24 can be applied to the LiDAR device 1000, particularly one where the detector unit 300 includes a detector array and the laser emitting unit 100 includes a laser emission array, but are not limited thereto, and the following descriptions can be applied to the LiDAR device 1000 with various available structure.

Further, in FIG. 24, for the convenience of explanation, the operation of the laser emission unit (which includes at least one laser emission element for emitting a laser) included in the laser emitting unit 100 is utilized for description. Further, the operation of at least one detecting device corresponding to the laser emission unit is utilized for description, but when a plurality of detecting devices corresponds to the laser emission unit, it will be easily understood by those skilled in the art that each of the plurality of detecting devices can be operated in accordance with the description of FIG. 24.

Meanwhile, the LiDAR device 1000 is for obtaining the distance between the LiDAR device and an object located on an optical path between a laser emission element and a detecting device on the basis of a laser beam emitted by the laser emission element and an electrical signal generated by a photon detected by the detecting device corresponding to the laser emission element.

Meanwhile, the detecting device (particularly, SPAD) is a detection device that, when receiving a photon, converts the energy of the photon into electrical energy, thereby outputting an electrical signal. The detecting device becomes unable to detect an additional photon before the recovery time elapses once one photon is detected.

Further, the controller 400 can map the electrical signal output by the detecting device to a specific time bin and record the counting in the time bin mapped to the corresponding electrical signal.

A time bin is a unit time for measuring the time point when a detection signal is output from a detecting device. The length of the time bin is determined by the minimum measurable time using a system clock. For example, if the system clock of a LiDAR device is output at a frequency of 500 MHZ, the minimum length of the time bin can be 2 ns.

Meanwhile, a detecting device can be activated to detect photons, and can be deactivated during a period in which it does not detect photons. Further, a time interval during which a detecting device is activated to detect photons can be defined as a detecting window.

In this case, one detecting window may have a length identical to or corresponding to one “scan cycle” or “cycle” described with reference to FIG. 1 to FIG. 23. Further, the “scan cycle” or “cycle” in FIG. 1 to FIG. 23 may have a duration corresponding to the round-trip time required for a photon emitted by a LiDAR device to travel to the maximum measurement distance of the LiDAR device 1000, reflect, and then return back to the LiDAR device 1000. That is, the “scan cycle” or “cycle” can be determined by the speed of photon and a maximum measurement distance. For example, if the maximum measurement distance is 300 m, and the speed of photon is 3×10\hat{ }8 m/s, so the scan cycle can have a length of (300/(3×10\hat{ }8)×2)=2 μs.

In this case, the detecting window should be the length of the round-trip time or longer. That is, the length of the detecting window must be equal to or greater than the length of the round-trip time. However, for the convenience of explanation in the present disclosure, it is assumed that the length of the detecting window is the same as the round-trip time. For example, in the present disclosure, it is assumed that the length of a detecting window is the same as a scan cycle, but it will be apparent to those skilled in the art that the spirit of the present disclosure can also be applied even though the detecting window is longer than the scan cycle. For example, when a detecting window is longer than a scan cycle, a time interval for pre-activating a detecting device to measure noise or ambient light around a LiDAR device or to measure the level of noise or ambient light before the start of a specific scan cycle may be included in the detecting window.

Meanwhile, a plurality of time bins may be included in the detecting window described above, and a first time bin for photon detection counting may be synchronized with the emitting timing of a laser beam in a scan cycle. Further, a plurality of consecutive time bins after the first time bin can be distinguished in the scan cycle. For example, if the maximum measurement distance is 300 m, the time for photon to travel back and forth over the maximum measurement distance is 2 μs, so the length of a scan cycle would be 2 μs, and a total of 1000 consecutive time bins, including the first time bin, can be distinguished in a detecting window. Further, the distance from a LiDAR device to an object can be measured on the basis of the time bin in which a detected light was counted. For example, the meaning of “a photon was counted in the first time bin described above” is that it implies the possibility that the object may exist at a distance determined by the time taken for a laser beam, after being emitted, to reflect from the object and return to the LiDAR device 1000 (e.g., the length of the time bin section, 2 ns). That is, it can be interpreted that the object may exist at a distance of {3*10\hat{ }8 m/s*2*10\hat{ }(−9)s}/2=6*10(−1) m/2=0.3 m from the LiDAR device.

However, for example, when a detecting device is a SPAD, it is difficult to measure “one distance measurement” with just one emission of laser beam and one detection of photon due to the characteristics of the SPAD device. This is because, due to noise or ambient light, multiple photons may be detected in a plurality of time bins that are distinguished within one scan cycle. Among the detected multiple photons, it is difficult to distinguish which one was detected by the laser beam emitted by a laser emission unit. Therefore, measuring the distance between the LiDAR device and the object through only one detection of photon is difficult.

Therefore, a plurality of scan cycles may be performed for “one measurement of distance”. That is, a plurality of scan cycles is performed within a sub-time interval for “one measurement of distance”, so the detecting device detects light multiple times

For example, when a first time bin is set to be synchronized with the emitting timing of a laser beam, the time bin corresponding to the time point when the laser beam is reflected from an object and detected by a detecting device would be constant. Further, repeating this multiple times (e.g., 358 times), it can be expected that the number of photons counted in that time bin would be the highest. This is because the laser beam is emitted in accordance with a set time interval and would be detected by the detecting device at an expected detection time point depending on the distance to the object, but noise or ambient light would be randomly detected by the detecting device.

Therefore, by the processes described above, during a plurality of scan cycles included in one sub-time interval, a detecting device detects photons and counts the number of photons counted in corresponding time bins, and it is possible to estimate the distance between the LiDAR device and the object on the basis of the time bin with the highest counting value. Further, it is possible to create point data on the basis of the estimated distance as described above.

The foregoing description is provided again with reference to FIG. 24. Referring to FIG. 24, the LiDAR device 1000 according to an embodiment can acquire a plurality of pieces of point data corresponding to at least a piece of frame data.

In this case, the frame data may refer to a data set that constitutes one screen, and may refer to a point data set acquired over a predetermined time. Meanwhile, the point data set may mean that it is defined in a predetermined format. Further, the frame data may mean a point cloud acquired over a predetermined time, and the point cloud may mean that it is defined in a predetermined format.

Further, the frame data may refer to a point data set that is used in at least one data processing algorithm, and may also refer to a point cloud that is used in at least one data processing algorithm. However, it is not limited thereto and may correspond to various concepts that can be understood as frame data by those skilled in the art.

The at least one frame data may include first frame data 3210.

In this case, the first frame data 3210 shown in FIG. 24 is merely represented as a two-dimensional image for the convenience of explanation, but is not limited thereto.

Further, the first frame data 3210 may correspond to a point data set acquired during a first time interval 3220, and the point data set may include a plurality of point data. In this case, since the aforementioned details may be applied to the point data set and the plurality of point data, repetitive descriptions are omitted.

For example, as shown in FIG. 24, the first frame data 3210 may include first point data 3211 and second point data 3212, but is not limited thereto.

Further, each point data included in the first frame data 3210 can be acquired on the basis of a signal that is output from the detector unit 300, as a laser emitted from a laser emitting unit included in the LiDAR device is reflected from an object and received by the detector unit 300.

Accordingly, the first time interval 3220 for acquiring the first frame data 3210 may include a plurality of sub-time intervals. In this case, the plurality of sub-time intervals is for acquiring at least one piece of histogram data. For example, using the number of photons counted in each of the time bins included in one sub-time interval among a plurality of sub-time intervals, one histogram data can be acquired.

Further, one piece of point data can be acquired on the basis of at least one piece of histogram data.

For example, the first time interval 3220 for acquiring the first frame data 3210 may include a first sub-time interval 3221 and a second sub-time interval 3222, but is not limited thereto. In this case, the first sub-time interval is for acquiring first histogram data, and the first histogram data can be used to acquire the first point data 3211. Similarly, the second sub-time interval may be for acquiring second histogram data, and the second histogram data may be used to acquire the second point data 3212.

Further, in each of the plurality of sub-time intervals, the laser emitting unit 100 and the detector unit 300 included in the LiDAR device 1000 can operate.

For example, in the first sub-time interval 3221 included in the plurality of sub-time intervals, the laser emitting unit and the detector unit included in the LiDAR device can operate, and in the second sub-time interval 322), the laser emitting unit 100 and detecting unit 300 included in the LiDAR device can operate, but the present disclosure is not limited thereto.

Meanwhile, as described below, a plurality of scan cycles may be included in each of the plurality of sub-time intervals.

In more detail, the laser emitting unit can be operated to emit a laser beam N times. The detector unit 300 can be operated in synchronization with the laser emitting unit 100) to sense the N laser beams emitted from the laser emitting unit 100. Further, the detector unit 300 generates a signal from light detected in a detecting window and can store a counting value in a corresponding time bin on the basis of the generated signal.

For example, in the first sub-time interval 3221, the first laser emission unit included in the laser emitting unit 100 can be operated by the controller to emit at least one laser beam in each of a plurality of scan cycles included in the first sub-time interval. Further, a first detecting device included in the detector unit 300 can be operated by the controller to sense a laser beam emitted from the first laser emission unit, the first detecting device generates an electrical signal on the basis of a photon sensed in the detecting window, and the controller 400 can store the counting value in a corresponding time bin on the basis of the generated signal.

Further, for example, in the first sub-time interval 3221, the first laser emission unit 3111 can be operated to emit a laser beam N times. In this case, the first laser emission unit 3111 can emit at least one laser beam in each of a plurality of scan cycles included in the first sub-time interval 3221. The first detecting device operates in a detecting window corresponding to each laser beam emission, and can generate an electrical signal on the basis of a photon sensed in each detecting window. Further, the controller 400 of the LiDAR device 100 can create a data set by storing a counting value in a corresponding time bin on the basis of a generated electrical signal, and accordingly, histogram data can be acquired on the basis of N data sets corresponding to the N emitted laser beams.

Further, for example, in the second sub-time interval 3222, the second laser emission unit 3112 included in the laser emitting unit 100 can be controlled by the controller 400 to emit a laser beam. Further, a second detecting device included in the detector unit 300 can be operated by the controller 400 to sense a laser beam emitted from the second laser emission unit 3112, the second detecting device generates an electrical signal on the basis of a photon sensed in the detecting window, and the controller 400 can store the counting value in a corresponding time bin on the basis of the generated signal.

Further, for example, in the second sub-time interval 3222, the second laser emission unit 3112 can be operated to emit a laser beam N times. In this case, the second laser emission unit 3112 can emit at least one laser beam in each of a plurality of scan cycles included in the second sub-time interval 3222. The first detecting device operates in a detecting window corresponding to each laser beam emission, and can generate an electrical signal on the basis of a photon sensed in each detecting window. Further, the controller 400 of the LiDAR device 100 can create a data set by storing a counting value in a corresponding time bin on the basis of a generated electrical signal, and accordingly, histogram data can be acquired on the basis of N data sets corresponding to the N emitted laser beams.

Further, each of a plurality of point data included in the first frame data 3210 can be acquired on the basis of histogram data in which a plurality of data sets for each detecting device is accumulated for each detecting device.

For example, the first point data 3211 included in the first frame data 3210 can be acquired on the basis of first histogram data acquired in the first sub-time interval 3221, and the second point data 3212 can be acquired on the basis of second histogram data acquired in the second sub-time interval 3222, but the present disclosure is not limited thereto.

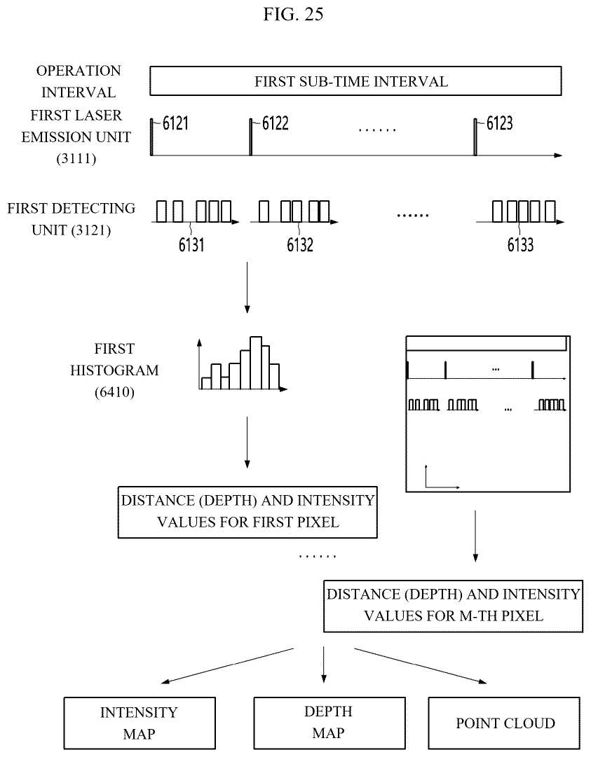

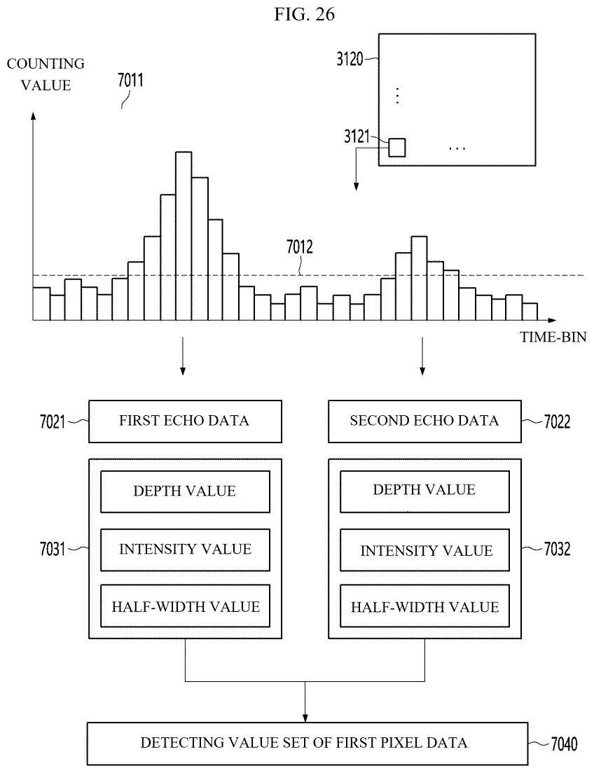

As described above, the LiDAR device 1000 can create one histogram for a sub-time interval on the basis of counting values measured in a plurality of scan cycles. Hereafter, a method of creating a histogram and a method of measuring a distance using the generated histogram are described in more detail with reference to FIG. 25 and FIG. 26.

FIG. 25 is a diagram illustrating a method of acquiring detecting values and LiDAR data according to an embodiment.

Referring to FIG. 25, an operation interval of the LiDAR device 1000 according to an embodiment may include a first sub-time interval 6110.

In this case, the operation interval of the LiDAR device 1000 according to an embodiment may refer to a time interval during which the LiDAR device 1000 performs a series of operations in order to acquire values for at least a part of point data included in LiDAR data according to an embodiment.

In the first sub-time interval 6110 of the LiDAR device according to an embodiment, the first laser emission (emitting) unit 3111 can emit a plurality of lasers.

For example, in the first sub-time interval 6110 of the LiDAR device according to an embodiment, the first laser emission unit 3111 can emit a first laser 6121, a second laser 6122, and an N-th laser 6123, but is not limited thereto.

Further, in the first sub-time interval 6110 of the LiDAR device according to an embodiment, the first detecting unit 6130 can sense photon and generate at least one signal.

For example, in the first sub-time interval 6110 of the LiDAR device according to an embodiment, when a laser beam emitted from the first laser emission (emitting) unit 3111 is reflected from an object and transmitted to the first detecting unit 6130, a laser beam emitted from the first laser emission unit 3111 and reflected from the object may be included in the photon sensed by the first detecting unit 6130, and accordingly, the first detecting unit 6130 can generate an electrical signal, but is not limited thereto.

Further, in the first sub-time interval 6110 of the LiDAR device according to an embodiment, the first detecting unit 3121 can sense photon and generate at least one electrical signal over a plurality of detecting windows.

For example, in the first sub-time interval 6110 of the LiDAR device according to an embodiment, the first detecting unit 3121 can sense at least a portion of a first laser 6121 emitted from the first laser emission unit 3111 and generate a first electrical signal during a first detecting window 6131. Further, the first detecting unit 3121 can sense at least a portion of a second laser 6122 emitted from the first laser emission unit 3111 and generate a second electrical signal during a second detecting window 6132. Similar to the above descriptions, the first detecting unit 3121 can sense at least a portion of an N-th laser 6123 emitted from the first laser emission unit 3111 and generate an N-th electrical signal during an N-th detecting window 6133.

Further, the first sub-time interval 6110 of the LiDAR device according to an embodiment can be represented as an operation interval for acquiring a distance value, an operation interval for acquiring an intensity value, an operation interval for acquiring both distance and intensity values, etc., but is not limited thereto.

Further, the LiDAR device according to an embodiment can create at least one counting value on the basis of an electrical signal generated by the first detecting unit 3121.

For example, the LiDAR device according to an embodiment can create at least one counting value assigned to at least one time bin on the basis of an electrical signal generated by the first detecting unit 3121 during the first detecting window 6131 and the time when the electrical signal is generated, but is not limited thereto.

Further, for example, the LiDAR device according to an embodiment can create at least one counting value assigned to at least one time bin on the basis of an electrical signal generated by the first detecting unit 3121 during the second detecting window 6132 and the time when the electrical signal is generated, but is not limited thereto.

Further, for example, the LiDAR device according to an embodiment can create at least one counting value assigned to at least one time bin on the basis of an electrical signal generated by the first detecting unit 3121 during the N-th detecting window 6133 and the time when the electrical signal is generated, but is not limited thereto.

Further, the LiDAR device according to an embodiment can create first histogram data 6140 on the basis of an electrical signal generated from the first detecting unit 3121 during the first sub-time interval 6110.

Further, the LiDAR device according to an embodiment can create first histogram data 6140 on the basis of an electrical signal generated from the first detecting unit 3121 in a plurality of detecting windows included in the first sub-time interval 6110.

For example, the LiDAR device according to an embodiment can acquire a first electrical signal generated from the first detecting unit 3121 in the first detecting window 6131, and can create at least one first counting value on the basis of the first electrical signal. Further, the LiDAR device according to an embodiment can acquire a second electrical signal generated from the first detecting unit 3121 in the second detecting window 6132, and can create at least one second counting value on the basis of the second electrical signal. Further, the LiDAR device according to an embodiment can acquire an N-th electrical signal generated from the first detecting unit 3121 in the N-th detecting window 6132, and can create at least one N-th counting value on the basis of the N-th electrical signal. Further, the LiDAR device can create first histogram data 6140 on the basis of at least one first counting value, at least one second counting value, and at least one N-th counting value, but is not limited thereto.

In this case, the first histogram data 6140 may be created by an algorithm that accumulates counting values assigned to time bins, which are unit times for dividing each of a plurality of detecting windows, but is not limited thereto, and may be created by various algorithms that can create a histogram on the basis of signals generally acquired from the detecting unit.

Further, the LiDAR device according to an embodiment can create at least one detecting value on the basis of the first histogram data 6140, and the operation of generating the detecting value may be implemented through at least one processor, the present disclosure is not limited thereto.

For example, the LiDAR device 1000 according to an embodiment can create a distance value for a first pixel on the basis of the first histogram data 6140, but is not limited thereto.

For example, the LiDAR device according to an embodiment can create an intensity value for a first pixel on the basis of the first histogram data 6140, but is not limited thereto. Further, the operation of creating the detecting value according to an embodiment may be implemented by various algorithms.

For example, in order to create a distance value for a first pixel on the basis of the first histogram data 6140 in accordance with an embodiment, the LiDAR device 1000 can acquire a rising edge on the basis of a threshold value. Further, the LiDAR device 1000 can acquire a distance value using an algorithm in which a distance value is created on the basis of a rising edge. However, acquiring a distance value is not limited to the example described above, and various algorithms may be used to create a distance value using histogram data.

Further, for example, in order to create an intensity value for a first pixel on the basis of the first histogram data 6140 according to an embodiment, an algorithm using pulse width, peak power, etc. may be used, but the present disclosure is not limited thereto, and various algorithms may be used to create an intensity value using histogram data.

Further, the LiDAR device 1000 according to an embodiment may include a plurality of laser emission units and a plurality of detecting units, and may create detecting values for a plurality of pixels on the basis of operations that can be understood as the operations of the first laser emission unit 3111 and first detecting unit 3121 described above.

For example, the LiDAR device according to an embodiment may include an M-th laser emission unit and an M-th detecting unit, and can create a distance value and an intensity value for an M-th pixel on the basis of the operations of the M-th laser emission unit and the M-th detecting unit, but is not limited thereto.

Further, the LiDAR device according to an embodiment can acquire at least one piece of LiDAR data using the detecting values for a plurality of pixels.

For example, the LiDAR device according to an embodiment can acquire a depth map using distance values for a plurality of pixels, but is not limited thereto.

For example, the LiDAR device according to an embodiment can acquire an intensity map using intensity values for a plurality of pixels, but is not limited thereto.

Further, for example, the LiDAR device according to an embodiment can acquire a point cloud using distance values and intensity values for a plurality of pixels, but is not limited thereto.

Meanwhile, one histogram may be created from electrical signals of photon detected by a plurality of detecting devices corresponding to one laser emission element. For example, if a plurality of detecting devices is nine detecting devices, counting up to nine can be performed simultaneously in one separate time bin in one detecting window, and a histogram may be created on the basis of the counting values counted in the detecting window by the plurality of detecting devices.

FIG. 26 is a diagram illustrating a method of acquiring a detecting value set for at least one pixel on the basis of an electrical signal acquired from a detecting array included in the LiDAR device 1000 according to an embodiment.

Referring to FIG. 26, the LiDAR device 1000 according to an embodiment may include a detecting array 3120, and the above descriptions can be applied thereto, so repetitive descriptions are omitted.

Further, referring to FIG. 26, the detecting array 3120 included in the LiDAR device according to an embodiment may include a first detecting unit 3121, and the above descriptions regarding the detecting units can be applied thereto, so repetitive descriptions are omitted.

Further, FIG. 26 is described on the basis of one detecting unit of a plurality of detecting units included in the detecting array 3120 for the convenience of explanation, and the contents described with reference FIG. 26 can be used for a method of acquiring a detecting value set for pixels corresponding to each detecting unit included in the detecting array 3120.

Referring to FIG. 26 again, first histogram data 7011 can be created on the basis of electrical signals acquired from the first detecting unit 3121 included in the detecting array 3120 according to an embodiment.

In this case, the first histogram data 7011 according to an embodiment may include at least one counting value. Further, at least one counting value included in the first histogram data 7011 may be created on the basis of an electrical signal acquired from the first detecting unit 3121.

For example, when electrical signals are generated from the first detecting unit 3121 in a plurality of detecting windows according to an embodiment, the first histogram data 7011 can be created in a manner in which counting values are accumulated in the time bins corresponding to the times when the electrical signals are generated, but the present disclosure is not limited thereto.

Further, since the above descriptions can be applied to the first histogram data 7011 created in accordance with an embodiment or the data generation method of the first histogram data 7011 according to an embodiment, so repetitive descriptions are omitted.

That is, the first histogram data 7011 according to an embodiment may be data that represents accumulated counting values from a reference time point at which a laser beam was emitted to the time point at which the laser beam can be assumed to have been detected by the detecting unit 7010.

However, the first histogram data 7011 according to an embodiment may include not only counting values corresponding to an emitted laser, but also counting values create by other factors (e.g., sunlight), and thus, a counting value group corresponding to the emitted laser can be determined.

Referring to FIG. 26 again, according to an embodiment, at least one piece of echo data can be determined on the basis of the first histogram data 7011.

For example, according to an embodiment, a counting value group for at least one counting value for a first time bin having a counting value equal to or greater than a reference value 7012 among at least one counting value included in the first histogram data 7011 and at least one counting value corresponding to second time bins continuing before and/or after the first time bin, may be determined as at least one piece of echo data, but the present disclosure is not limited thereto.

In this case, the at least one piece of echo data may refer to a portion of the histogram data that includes counting values above a predetermined reference in the histogram data. Further, it may refer to a counting value group that includes counting values above the predetermined reference in the histogram data. For example, a counting value group for a first time bin of a P-th highest counting value and Q counting values corresponding to Q consecutive second time bins before and after the first time bin in the first histogram data 7011 may be determined as one piece of echo data. As another example, a counting value group for a first time bin of a P-th highest counting value and consecutive second time bines having a counting value equal to or greater than a reference value before and after the first time bin may be determined as one piece of echo data. However, the method of determining echo data is not limited to the method described above, and concepts generally understood as echo data may be included. Further, the P and Q described above may be natural values.

Meanwhile, echo data may be expressed as a subset of histogram data in that it is a set of some counting values corresponding to some consecutive time bins among all counting values for all time bins of the histogram data, in accordance with the aforementioned method for determining echo data. That is, echo data is a subset of histogram data determined in accordance with a predetermined algorithm, such as the examples, in the histogram data, and therefore, in the embodiments to be described below, echo data may be expressed as a subset of a histogram. In other words, a subset of histogram data to be described below may be echo data. However, in the embodiments to be described below, a subset of histogram data is not limited to echo data, and as long as it is a set of at least some of counting values included in histogram data, the set can be understood as a subset of the histogram data regardless of the method by which the set is determined.

Further, for example, according to an embodiment, first echo data 7021 and second echo data 7022 can be determined on the basis of the first histogram data 7011, but the present disclosure is not limited thereto. For example, third echo data can also be determined together with the first echo data 7021 and the second echo data 7022 on the basis of the first histogram data 7011.

Further, according to an embodiment, a detecting value set can be acquired on the basis of at least one piece of echo data.

For example, according to an embodiment, a first detecting value set 7031 can be acquired on the basis of the first echo data 7021 determined on the basis of the first histogram data 7011, and a second detecting value set 7032 can be acquired on the basis of the second echo data 7022 determined on the basis of the first histogram data 701), but the present disclosure is not limited thereto.

If third echo data is determined on the basis of the first histogram data 7011, a third detecting value set 7032 can be acquired on the basis of the third echo data.

Further, according to an embodiment, a detecting value set acquired on the basis of at least one piece of echo data may include at least one detecting value.

For example, according to an embodiment, the first detecting value set 7031 acquired on the basis of the first echo data 7021 and the second detecting value set 7032 acquired on the basis of the second echo data 7022 may each include a depth value, an intensity value, and a half-width value, but they are not limited thereto and may include various detecting values. Similarly, if a third detecting value set is acquired on the basis of third echo data, the third detecting value set may also include a depth value, an intensity value, and a half-width value.

In this case, according to one embodiment, the depth value may be acquired on the basis of time bins related to at least one piece of echo data.

According to an embodiment, a first depth value acquired on the basis of the first echo data 7021 can be acquired on the basis of the time bin value of a rising edge of the first echo data 7021 with respect to a reference value 7012, but is not limited thereto and may be acquired using various algorithms for the time bins related to the first echo data 7021.

Further, for example, according to an embodiment, a second depth value acquired on the basis of the second echo data 7022 can be acquired on the basis of the time bin value of a rising edge of the second echo data 7022 with respect to the reference value 7012, but is not limited thereto and may be acquired using various algorithms for the time bins related to the second echo data 7022.

If third echo data is acquired, a third depth value acquired on the basis of the third echo data can be acquired on the basis of the time bin value of a rising edge of the third echo data with respect to the reference value 7012, but is not limited thereto and may be acquired using various algorithms for the time bins related to the third echo data.

Further, according to one embodiment, the intensity value may be acquired on the basis of a counting values related to at least one piece of echo data.

For example, according to an embodiment, a first intensity value acquired on the basis of the first echo data 7021 can be acquired on the basis of the largest counting value included in the first echo data 7021, but is not limited thereto and may be acquired using various algorithms for the counting values related to the first echo data 7021, such as the sum of the counting values included in the first echo data 7021.

For example, according to an embodiment, a second intensity value acquired on the basis of the second echo data 7022 can be acquired on the basis of the largest counting value included in the second echo data 7022, but is not limited thereto and may be acquired using various algorithms for the counting values related to the second echo data 7022, such as the sum of the counting values included in the second echo data 7022.

Further, for example, according to an embodiment, a third intensity value acquired on the basis of the third echo data can be acquired on the basis of the largest counting value included in the third echo data, but is not limited thereto and may be acquired using various algorithms for the counting values related to the third echo data, such as the sum of the counting values included in the third echo data.

Further, according to one embodiment, the half-width value may be acquired on the basis of counting values and a time bin value related to at least one piece of echo data.

According to an embodiment, a first half-width value acquired on the basis of the first echo data 7021 can be acquired on the basis of the number of consecutive time bins including counting values equal to or greater than half of the largest counting value included in the first echo data 7021, but is not limited thereto and may be acquired using various algorithms for the counting values and time bin values related to the first echo data 7021.

Further, for example, according to an embodiment, a second half-width value acquired on the basis of the second echo data 7022 can be acquired on the basis of the number of consecutive time bins including counting values equal to or greater than half of the largest counting value included in the second echo data 7022, but is not limited thereto and may be acquired using various algorithms for the counting values and time bin values related to the second echo data 7022.

Further, for example, according to an embodiment, a third half-width value acquired on the basis of the third echo data can be acquired on the basis of the number of consecutive time bins including counting values equal to or greater than half of the largest counting value included in the third echo data, but is not limited thereto and may be acquired using various algorithms for the counting values and time bin values related to the third echo data.

Referring to FIG. 26 again, a detecting value set 7040 of a first pixel can be determined on the basis of at least a portion of the first detecting value set 7031 for the first echo data 7021 and the second detecting value set 7032 for the second echo data 7022 according to an embodiment. If third echo data is acquired, the detecting value set 7040 of the first pixel may additionally be determined by further considering at least a portion of the third detecting value for the third echo data.

For example, according to an embodiment, when the first intensity value included in the first detecting value set 7031 for the first echo data 7021 is greater than the intensity value included in the detecting value set for another echo data, the first detecting value set 7031 for the first echo data 7021 can be determined as the first detecting value set 7040 of the first pixel, but is not limited thereto.

Further, according to an embodiment, the detecting value set 7040 of the first pixel may be understood as a detecting value set for an object when a laser emitted from the LiDAR device is reflected from the object and sensed by a detecting unit.

Therefore, determining the detecting value set 7040 of the first pixel in accordance with an embodiment may be understood to have the same meaning as determining which one of a plurality of pieces of echo data is echo data for an object.

### [I. Method for Measuring Short-Distance Object Using Low-Intensity Laser Beam]

As described above, a scan cycle is set on the basis of the maximum measurement distance (for example, 300 m) of the LiDAR device 1000, and in order to measure an object located at the maximum measurement distance, it was necessary to emit a relatively high-intensity laser beam. Accordingly, the LiDAR device 1000 emits the high-intensity laser beam once per scan cycle through a laser emission element, thereby acquiring point data of the pixel corresponding to the laser emission element.

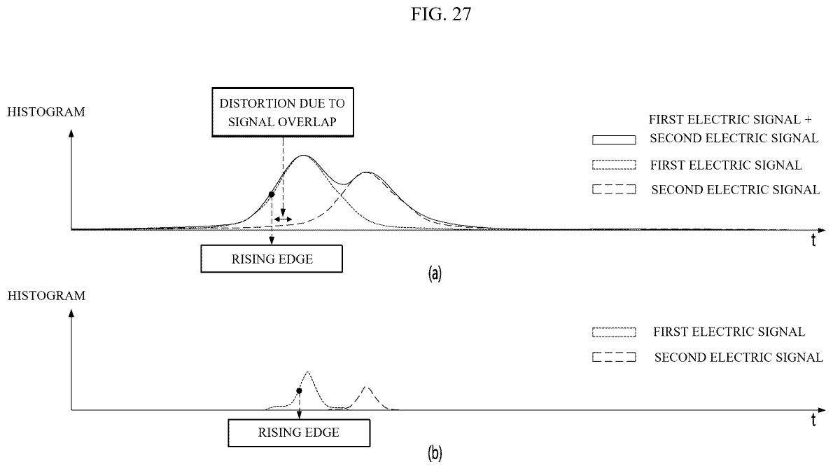

However, as can be seen in FIG. 27(a), if a high-intensity laser beam is emitted from a laser emission element and reflected from an object located at a short distance (e.g., within 7 m), and then incident on at least one detecting device included in the detecting unit corresponding to the laser emission element, the amount of light sensed by at least one detecting device may become excessive. Accordingly, due to such excessive amount of light, a phenomenon in which a count number of photon detections is counted may occur not only in the time bin corresponding to the distance between the laser emission element and the object, but also in at least one adjacent time bin.

For example, identical/similar counting values can be accumulated in consecutive time bins, and the LiDAR device may have difficulty in recognizing which time bin's counting value corresponds to an object among the time bins in which identical/similar counting values have been accumulated.

In other words, a high-intensity laser beam reflected by an object located at a short distance may be detected for a duration corresponding to multiple time bins by at least one detecting device, and as a result, at least some of histogram data created on the basis of electrical signals generated by at least one detecting device may become saturated. Further, due to the saturation phenomenon of at least some of the histogram data described above, distortion may occur in the histogram data (or at least some of the histogram data). That is, a high-intensity laser beam can be detected for a duration corresponding to a plurality of time bins, and counting values corresponding to the plurality of time bins can be counted identically/similarly. For example, when the counting values of the time bins included in the echo data (or a subset of a histogram) described with reference to FIG. 26 are all identical/similar, so it is difficult to recognize which time bin's counting value corresponds to an object, the echo data (or a subset of the histogram) may be determined to be distorted.

If distortion occurs in at least some of the histogram data, an error may be generated in determining which time bin's accumulated value the LiDAR device 1000 should use to determine the distance to the object, and an error may occur in determining the distance to the object, which may lead to a decrease in the accuracy of distance measurement.

On the other hand, as shown in FIG. 27(b), when the LiDAR device 1000 emits a low-intensity laser beam, even though the laser beam is reflected from an object located at a short distance (e.g., within 7 m) and detected by at least one detecting device, the amount of light is relatively low, so it is possible to prevent at least some of histogram data created on the basis of electrical signals generated by at least one detecting device from becoming saturated. In other words, if the amount of light is relatively low, it is possible to prevent a laser beam reflected by an object from being continuously detected over a duration corresponding to multiple time bins, so it is possible to prevent at least some of histogram data from being distorted. Accordingly, for objects located at a short distance, it may be advantageous to measure the distance using a low-intensity laser beam.

However, as described above, when a LiDAR device measures a distance, setting a high intensity is for measuring all objects up to the maximum measurement distance. Accordingly, if only a low-intensity laser beam is emitted to improve the measurement accuracy for objects located at a short distance, a problem may arise where objects located beyond a predetermined distance are not properly measured due to the phenomenon of the emitted laser beam's intensity attenuating as it travels. As a result, if only a low-intensity laser beam is emitted, there is a problem that a maximum measurement distance becomes shorter.

Therefore, there is a need for a method that can measure objects up to a maximum measurement distance by utilizing a high-intensity laser beam, as in the existing method, and can improve the measurement accuracy for objects located at a short distance by using a low-intensity laser beam. Accordingly, the measurement method is described in detail.

Meanwhile, the “high intensity” and “low intensity” used in embodiments of the present disclosure refer to relative intensities and do not imply absolute specific values. For example, as described above, “high intensity” may be set on the basis of a maximum measurement distance, and “low intensity” may be set on the basis of a distance (e.g., a short distance within 7 m) at which histogram data may be distorted with a predetermined or higher probability by a high-intensity laser beam. Further, in the following explanation, “first laser beam” may refer to a laser beam with “high intensity”, and “second laser beam” may refer to a laser beam with “low intensity”. Further, “high intensity” may be expressed as first intensity, and “low intensity” may be expressed as second intensity. Further, the first intensity and the second intensity are relative concepts, and the first intensity may have a higher value than the second intensity.

Further, for the convenience of explanation, the operations of a laser emission element and at least one detecting device are described separately, but the operations of the laser emission element and at least one detecting device are controlled by the controller, and should not be understood as separate operations. For example, on the basis of the descriptions referring to FIG. 1 to FIG. 26, a laser emission element and at least one detection device to be described below should be understood as one operation of a LiDAR device that is controlled by a controller. For example, when a first laser beam and a second laser beam are emitted in accordance with the operation of a laser emission element under the control of the controller 400, the controller can create histogram data in accordance with an electrical signal generated on the basis of at least one photon detected by at least one detecting device in accordance with the operation of the at least one detecting device. Further, the controller 400 can measure the distance between the LiDAR device and an object on the basis of a plurality of subsets of histogram data.

In other words, embodiments to be described below are merely described by distinguishing the operations of the components included in the LiDAR device for the convenience of explanation. However, it will be apparent to those skilled in the art that the actual operation of the LiDAR device 1000 can be understood as the overall operation of the LiDAR device in which the operations of the components, described separately, are performed under the control of the LiDAR device.

### [I-1-1. Operation of Laser Emission Element Controlled by Controller of LiDAR Device to Measure Short-Distance Object]

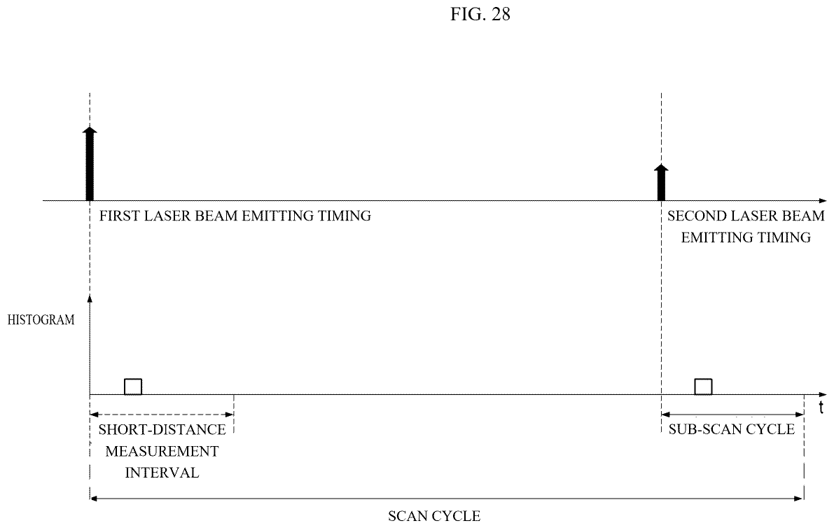

Referring to FIG. 28, the LiDAR device 1000 can emit a first laser beam with a first intensity and a second laser beam with a second intensity in one scan cycle. In this case, the second laser beam may be emitted after the first laser beam is emitted.

Meanwhile, the emitting timing of the second laser beam can be set on the basis of a distance (e.g., a short distance of 7 m) at which distortion of histogram data may occur with a predetermined or higher probability due to a high-intensity laser beam, or on the basis of an arbitrarily set distance (e.g., 7 m). Hereafter, for the convenience of explanation, the maximum distance between an object to be measured by the second laser beam and the LiDAR device is defined as a “short distance” and described accordingly.

For example, the last part of a scan cycle is set as a sub-scan cycle so that a measurable distance at the emitting timing of the second laser beam is up to a short distance. In other words, the sub-scan cycle is an interval set in a scan cycle to measure the distance between an object located within a short distance and the LiDAR device on the basis of the second laser beam. For example, the sub-scan cycle is composed of time bins for the last part of a scan cycle, and in the time bins included in the interval corresponding to the sub-scan cycle, if an object is located within a short distance, photons incident on a detecting device due to the second laser beam reflected from the object located in the short distance may be counted, and photons incident on the detecting device due to the first laser beam reflected from an object located outside the short distance may be counted. Accordingly, in the time bins included in the sub-scan cycle, photons reflected by the first laser beam may be counted or photons reflected by the second laser beam may be counted, depending on the distance to the object On the other hand, the detecting device cannot immediately determine whether the incident photons are due to the first laser beam or the second laser beam. Accordingly, there is a need for a method of distinguishing whether the counted photons in the last part of the scan cycle (i.e., the interval of a sub-scan cycle section) is due to the first laser beam or the second laser beam, and this is described in detail below.

For example, the emitting timing of the second laser beam is synchronized with the start point of the sub-scan cycle. In other words, the emitting timing of the second laser beam can be synchronized with the first time bin included in the sub-scan cycle. Meanwhile, the first time bin included in the sub-scan cycle may be a Z-th time bin included in the scan cycle. In this case, the Z-th time bin may be a time bin that can be counted from the emitting timing of the first laser beam when an object is located ahead by a measurable distance (e.g., 7 m) according to the emitting timing of the second laser beam from a maximum measurement distance and the first laser beam is reflected from the object and detected by a detecting device. For example, if the maximum measurement distance is 300 m and the measurable distance according to the emitting timing of the second laser beam is 7 m, the Z-th time bin (i.e., the first time bin included in the sub-scan cycle) may be a time bin that can be counted when the first laser beam is reflected by an object located 293 m away from the LiDAR device 1000 and detected by a detecting device.

Further, when the object is located at a short distance from the LiDAR device 1000, the sub-scan cycle and the emitting timing of the second laser beam can be set such that the counting value of the last time bin included in the scan cycle can be increased by the second laser beam reflected from the object.

In other words, the sub-scan cycle and the scan cycle can be understood as sharing the last some time bins among the time bins included in the scan cycle. Further, the start point of the sub-scan cycle is set on the basis of a set short distance, and on the basis of the system clock of the controller 400, the sub-scan cycle and the scan cycle are set such that the counting value increases when the second laser beam, reflected from an object located at the short distance from the LiDAR device 100, is detected in the last time bin of both the scan cycle and the sub-scan cycle.

In other words, the sub-scan cycle can be set at the end of the scan cycle such that an object located at a short distance from the LiDAR device 1000 can be measured by the second laser beam, and the start point of the sub-scan cycle can be synchronized with the emitting timing of the second laser beam on the basis of the system clock of the controller 400.

Meanwhile, referring to FIG. 28, the interval in which an object located at a short distance from the LiDAR device 1000 can be measured by the first laser beam is represented as a “short-distance measurement interval”. The duration of the “short-distance measurement interval” may be the same as the duration of the “sub-scan cycle”. That is, the “short-distance measurement interval” may be defined from the start point of the scan cycle to the duration of the “sub-scan cycle”. This “short-distance measurement interval” is provided to explain a method of calculating the distance between an object located in the short distance and a LiDAR device according to an embodiment to be described later, and may be an interval that is not set in the controller. That is, it should be noted that the “short-distance measurement interval” is merely an interval arbitrarily defined for the convenience of explanation of the present disclosure, and may not be an interval directly implemented or set in a LiDAR device in accordance with an embodiment of the present disclosure.

However, if necessary, the “short-distance measurement interval” may of course be actually set or implemented.

Further, a sub-scan cycle is a part of a scan cycle, it is required to distinguish whether the counting value of the time bin included in the sub-scan cycle is acquired by the reflection of the first laser beam from an object outside a short distance, or by the reflection of the second laser beam from an object within the short distance. In order to make this distinction, the counting value of the time bin included in the “short-distance measurement interval” may be required, and the method of distinguishing this is described in detail below in the description of a method of operating at least one detecting device.

In other words, the duration of the sub-scan cycle may be the same as the time duration until the second laser beam, emitted at a second emitting timing, is reflected from an object located within a short distance from the LiDAR device 1000 and detected by at least one detecting device.

Further, the duration of the short-distance measurement interval may be the same as the time duration until the first laser beam, emitted at a first emitting timing, is reflected from an object located within a short distance from the LiDAR device 1000 and detected by at least one detecting device.

Referring to FIG. 28, the LiDAR device 1000 can control a laser emission element to emit laser beams twice in one scan cycle. For example, the LiDAR device can control the laser emission element to emit a first laser beam with a first intensity synchronized with the first time bin of a scan cycle. Further, after the first laser beam is emitted, the LiDAR device can control the laser emission element to emit a second laser beam with a second intensity synchronized with the first time bin of a sub-scan cycle.

For the convenience of explanation, the time point at which the first laser beam is emitted is defined as a “first emitting timing”, and the time point at which the second laser beam is emitted is defined as a “second emitting timing”.

Meanwhile, it may also be possible to set a separate scan cycle for measuring an object located within a short distance without setting a sub-scan cycle in the scan cycle. However, when a separate scan cycle is set for measuring an object located within a short distance, the total number of scan cycles for measurement of one pixel (i.e., the total time for measuring one pixel) may increase, so the frame rate of a point cloud data may decrease. Therefore, in order to effectively maintain a frame rate, it would be preferable to emit laser beams with different intensities twice within one scan cycle and determine the distance to an object on the basis of the laser beams.

### [I-1-2. Hardware Operation of Laser Emission Element According to Embodiment of Present Disclosure]

Hereafter, the hardware operation of the laser emitting unit 100 controlled by the controller 400 of the LiDAR device 1000 to perform the operation of a laser emission element is described with reference to FIG. 28. Meanwhile, the laser emitting unit 100 may include laser emission elements, as described above.

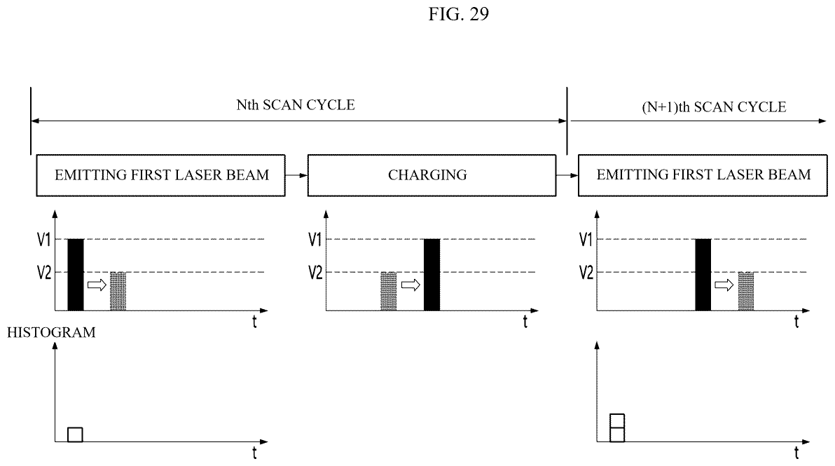

FIG. 29 shows variation in voltage corresponding to the electric charge quantity stored in the capacitor 5241 when one laser beam is emitted in one scan cycle, as in the existing methods. Variation in voltage corresponding to the electric charge quantity stored in the capacitor 5241 was described with reference to FIG. 21, and the diagram in FIG. 29 is the same as that described in FIG. 21.

Referring to FIG. 19, FIG. 21, and FIG. 29, for an N-th scan cycle in the LiDAR device 1000, when a trigger signal is received by the charging switch 5251 and the first capacitor 5241 is charged with a voltage of V1, the common driving switch 5260 can be operated to emit a first laser beam at a first emitting timing of the N-th scan cycle, and when the first laser beam is emitted by the operation of the common driving switch 5260, a voltage V2 remains in the first capacitor 5241. Further, in an (N+1)th scan cycle, for the LiDAR device 1000 to emit a first laser beam, a trigger signal is received by the charging switch 5251, the first capacitor 5241 is charged with a voltage of V1, and the first laser beam can be emitted at the first emitting timing of the (N+1)th scan cycle.

That is, when a first laser beam is emitted, the voltage charged in the first capacitor 5241 is not fully discharged and a partial voltage of V2 remains, and in an embodiment of the present disclosure, the LiDAR device 100 can emit a second laser beam with a second intensity using the remaining partial voltage of V2 without adding a separate charging process. This is because the second intensity requires relatively low voltage in comparison to the first intensity, so it is possible to emit the second laser beam using the voltage remaining after the first beam is emitted.

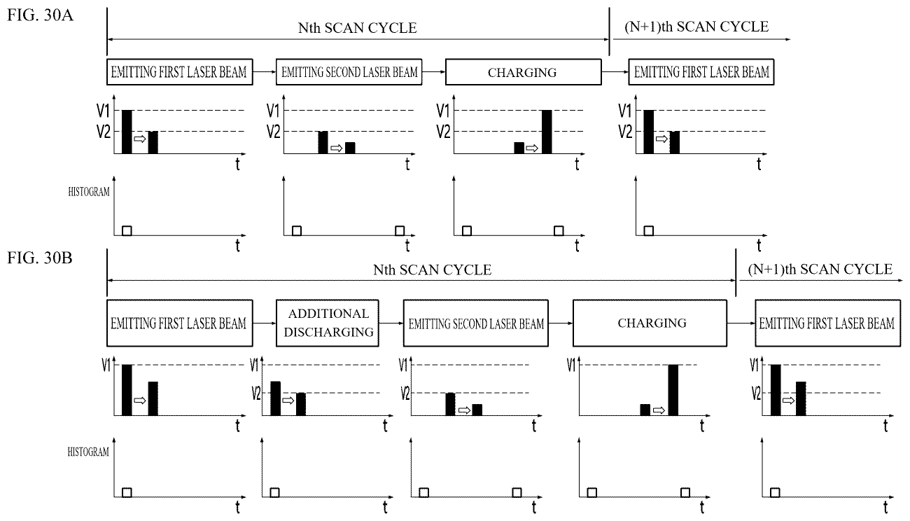

This is described with reference to FIGS. 30A and 30B. FIG. 30A illustrates a process in which a second laser beam is emitted in one scan cycle using remaining voltage. Referring to FIG. 30A, when the first capacitor 5241 is charged with a voltage of V1 through the first driving switch 5251, the LiDAR device 1000 operates the common driving switch 5260 such that a laser emission element emits a first laser beam with the first intensity in the N-th scan cycle. Further, the LiDAR device (1000) can control the laser emission element to emit a second laser beam with a second intensity by operating the common driving switch 5260 once more at the second emitting timing of the N-th scan cycle, with the voltage V2 remaining in the first capacitor 5241 without an additional charging process. The LiDAR device 1000 allows the voltage V1 to be recharged to the first capacitor 5241 through the operation of the first charging switch (5251 after the second laser beam is emitted. Thereafter, the LiDAR device 1000 allows the first laser beam to be emitted using the voltage V1 in the (N+1)th scan cycle.

In other words, in the laser beam emission operation according to an embodiment of the present disclosure, the first charging switch 5251 operates once in one scan cycle, but the common driving switch 5260 can operate twice.

Meanwhile, after the LiDAR device 1000 emits the first laser beam, the remaining voltage may be higher than V2. In this case, the second laser beam may have a large amount of light (e.g., intensity greater intensity than the second intensity) that is too much to measure the distance between an object located within a short distance, which is not suitable for measuring the distance between the object located within a short distance and the LiDAR device. In this case, there may be a need for a process of additionally discharging the voltage stored in the first capacitor 5241 such that the second laser beam has intensity (e.g., the second intensity) that is suitable for measuring the object located within the predetermined short distance.

FIG. 30B shows that such additional discharging process has been added. Referring to FIG. 30B, after the LiDAR device 1000 emits the first laser beam using the voltage V1 stored in the first capacitor 5241, a voltage having a magnitude between V1 and V2 may remain in the first capacitor 5241. In this state, if the LiDAR device 1000 emits a laser beam again, the laser beam may have intensity higher than the second intensity, so an additional discharging process is performed to emit the second laser beam with the second intensity. For example, the LiDAR device 1000 can lower the voltage remaining in the first capacitor 5241 to V2 by operating the first discharging switch 5261 after emitting the first laser beam. Thereafter, as described above, the LiDAR device 1000 can emit the second laser beam at the second emitting timing, and the subsequent process may be the same as that described with reference to FIG. 30A.

Meanwhile, whether to perform an additional discharge step, as shown in FIG. 30B, can be determined on the basis of whether the voltage remaining in the first capacitor 5241 after emitting the first laser beam exceeds a predetermined level. That is, the voltage charged in the first capacitor 5241 by the first charging switch 5251 can always be constant at V1 to emit the first laser beam. Accordingly, the voltage remaining in the first capacitor 5241 can also be constant after the first laser beam is emitted. Therefore, it can be determined in advance during a circuit design process whether the remaining voltage is appropriate for emitting the second laser beam with a second period. If the remaining voltage after the first laser beam is emitted is greater than the voltage required to emit the second laser beam, then, as shown in FIG. 30B, an additional discharging process is performed between emission of the first laser beam and emission of the second laser beam, thereby allowing appropriate voltage to remain in the first capacitor 5241 for emission of the second laser beam.

Meanwhile, though not shown in the figures, if the voltage remaining in the first capacitor 5241 after the LiDAR device 1000 emits the first laser beam is lower than V2 and thus not suitable for emitting the second laser beam with second intensity, the second laser beam may be emitted after the first charging switch 5251 is operated to charge the first capacitor 52441 to V2.

[I-1-3. Method of Determining Scan Cycle in which Laser Beam Emission Method According to Embodiment of Present Disclosure is Performed]

As described with reference to FIG. 28 to FIG. 30, according to an embodiment of the present disclosure, when the LiDAR device 1000 emits a first laser beam and then emits a second laser beam in one scan cycle, it is possible to improve the accuracy of distance measurement between the LiDAR device 1000 and an object, regardless of whether the object is located within a short distance or outside a short distance.

Further, emitting a first laser beam and a second laser beam in each of all the scan cycle included in a sub-time interval can also increase the precision of measuring an object. However, as described with reference to FIG. 30, there is a need for a charging process for the LiDAR device 100 to emit a second laser beam in an N-th scan cycle and then emit a first laser beam in an (N+1)th scan cycle. However, after the LiDAR device 100 emits the second laser beam, voltage lower than V2 remains in the first capacitor 5241 and more power is consumed to charge up to V1 from a voltage lower than V2.

For example, compared to FIG. 29, in FIG. 29, after the first laser beam is emitted, since it is only necessary to charge up to V1 from a remaining voltage of V2, only the power required to charge by (V1-V2) is consumed. However, in FIG. 30, it is required to charge up to V1 from a remaining voltage lower than V2 after emitting the second laser beam, more power is consumed than the power required to charge by (V1-V2). Accordingly, if the first laser beam and the second laser beam are emitted in every scan cycle, it may be disadvantageous in terms of power consumption.

Accordingly, when emitting laser beams in accordance with an embodiment of the present disclosure, it is possible to determine a scan cycle in which a first laser beam and a second laser beam are emitted among a plurality of scan cycles included in a sub-time interval in consideration of both the required measurement accuracy for a short-distance object and the required power consumption. For example, if priority is given to improving the measurement accuracy even at the cost of somewhat higher power consumption, the ratio of the scan cycle in which a first laser beam and a second laser beam are emitted among a plurality of scan cycles can be increased. On the contrary, if power consumption is given priority over measurement accuracy, the ratio of a scan cycle in which a first laser beam and a second laser beam are emitted among a plurality of scan cycles can be reduced.

For example, the LiDAR device 1000 can emit a first laser beam and a second laser beam in one scan cycle with a gap of two scan cycles, but the present disclosure is not limited thereto. That is, the LiDAR device 1000 may emit a first laser beam and a second laser beam in one scan cycle with a gap of three scan cycles. Further, the LiDAR device 1000 may emit a first laser beam and a second laser beam in one scan cycle with a gap of M scan cycles.

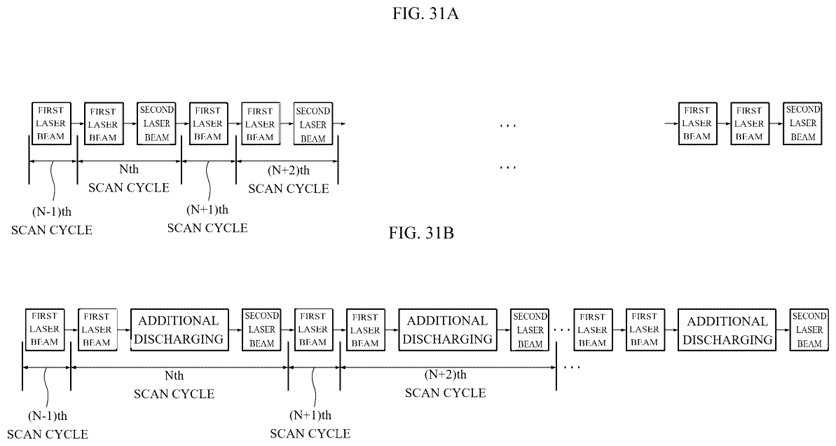

FIGS. 31A and 31B show the LiDAR device 1000 emitting a first laser beam and a second laser beam in one scan cycle with a gap of two scan cycles. For example, referring to FIG. 31A, the LiDAR device 1000 can emit a first laser beam in an (N−1)th scan cycle and then sequentially emit the first laser beam and a second laser beam in an N-th scan cycle, and can emit the first laser beam in an (N+1)th scan cycle.

FIG. 31B is intended to explain that the LiDAR device 100 undergoes an additional discharging process between emission of a first laser beam and emission of a second laser beam in an N-th scan cycle, and descriptions overlapping with the above are omitted. FIG. 31B also shows the LiDAR device 1000 emitting a first laser beam and a second laser beam in one scan cycle with a gap of two scan cycles.

For example, if one sub-time interval includes 358 scan cycles, the LiDAR device 1000 can emit a first laser beam at a first emitting timing in each of the 358 scan cycles. Further, the LiDAR device 1000 can emit a second laser beam at a second emitting timing in a total of 179 scan cycles with a gap of two scan cycles among the 358 scan cycles.

[I-2. Operation of Controller 400 that Measures Distance Between LiDAR Device 1000 and Object on Basis of Photon Detected by at Least One Detecting Device]
[I-2-1. Method of Determining Whether Object is within Short Distance or Whether Detected Photon is Due to Laser Beam Reflected from Object within Short Distance]

“As described above, the laser emission element of the LiDAR device 1000 may be optically connected to at least one detecting device. That is, a laser emission element may be optically connected to a plurality of detecting devices. That is, a laser emission element may correspond to at least one detecting device.

Hereafter, a method of measuring the distance between the LiDAR device 1000 and the object on the basis of photons detected by at least one detecting device optically connected to a laser emission element, and electrical signals generated by the at least one detecting device on the basis of the detected photons, is described.

As described above, the LiDAR device 1000 can create histogram data on the basis of electrical signals generated on the basis of photons detected by at least one detecting device. In this case, the histogram data may include accumulated counting values over a plurality of scan cycles for each time bin. he controller 400 can receive a plurality of subsets consisting of at least some of the accumulated counting values. That is, a subset can be composed of counting values for some consecutive time bins of all time bins of histogram data. For example, a corresponding subset may be the echo data described with reference to FIG. 26.

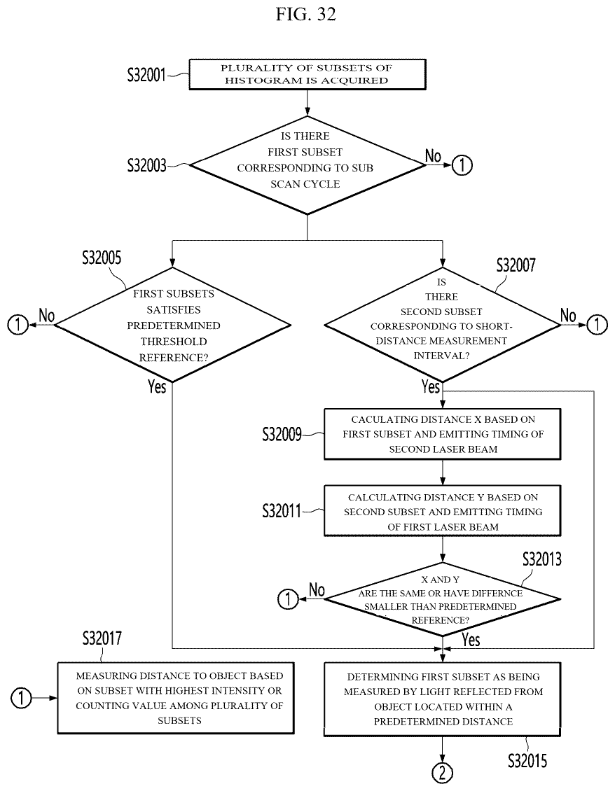

Referring to FIG. 32, the controller 400 can acquire a plurality of subsets in accordance with an embodiment (S32001). Hereafter, for the convenience of explanation, the present disclosure is described under the assumption that three subsets have been acquired. However, the controller 400 may acquire more than three subsets or may acquire two subsets, and it is apparent to those skilled in the art that embodiments to be described below can still be applied in such cases.

Meanwhile, in the following description, a first subset, which is a subset corresponding to a sub-scan cycle, may refer to a first subset including the counting values of at least some of time bins included in a sub-scan cycle. That is, the presence of the first subset may mean that an object may exist within a short distance.

Further, a second subset and a third subset, which are subsets corresponding to intervals other than a sub-scan cycles in a scan cycle, and may refer to subsets including the counting values of at least some of the time bins included in the intervals other than the sub-scan cycles in the scan cycle. In particular, the second subset may be a subset that includes the counting values of at least some of the time bins included in a short-distance measurement interval based on a first emitting timing of a first laser beam.

Referring to FIG. 32, the controller 400 determines whether there is a first subset corresponding to a sub-scan cycle included within a corresponding scan cycle among a plurality of subsets (S32003). For example, the controller 400 determines whether there is a first subset including the counting values of the time bins included in a sub-scan cycle.

If there is no first subset in the plurality of subsets, it is determined that no object exists within a predetermined short distance, it is possible to measure the distance between the LiDAR device 1000 and the object on the basis of the subset with the highest intensity or the highest counting value among the plurality of subsets (S32017). For example, if the intensity or counting value of a third subset is the highest among the plurality of subsets, it is possible to measure the distance between the LiDAR device 1000 and the object on the basis of the third subset.

If there is a first subset among the plurality of subsets, it is possible to determine whether an object exists within the predetermined short distance using at least one of the following two methods (i.e., Method 1-1 and Method 1-2).

(Method 1-1) Method of Determining Whether Object is within Short Distance on Basis of Intensity Value of First Subset

A first subset may be formed by photon detected from a first laser beam reflected from an object outside a predetermined short distance, or may be formed by photon detected from a second laser beam reflected from an object within a predetermined short distance.

However, if an object is outside the short distance, the first laser beam would decrease in intensity while traveling to a relatively long distance, and when the first laser beam is reflected from the object and detected by at least one detecting device, the intensity of the first laser beam may have significantly decreased. On the other hand, if an object is within the short distance, the second laser beam may not significantly decrease in intensity while traveling a relatively short distance. Accordingly, when the second laser beam, reflected from the object, is detected by at least one detecting device, the intensity of the second laser beam may not have significantly decreased.

Accordingly, the intensity of the first subset when the second laser beam is reflected from an object and measured may be greater than the intensity of the first subset when the first laser beam is reflected and measured. Therefore, if the intensity of the first subset is less than a first threshold, it can be assumed that the first subset has been measured on the basis of the reflected first laser beam, and if the intensity of the first subset is the first threshold or higher and is less than a second threshold value, it can be assumed that the first subset has been measured on the basis of the reflected second laser beam (S32005). In addition, if an object of a retroreflector, the first subset may have very high intensity, regardless of whether it has been measured on the basis of the reflected first laser beam or the reflected second laser beam. Accordingly, when the intensity of the first subset is the second threshold value or higher, it can be assumed that the objective is a retroreflector.

Accordingly, when the intensity value of the first subset is less than the first threshold value, the controller 400 can measure the distance between the LiDAR device 1000 and the object by performing S32017. Alternatively, when it is determined that the first subset is formed by a first laser beam reflected from an object located outside a predetermined short distance, the controller 400 can measure the distance between the LiDAR device 1000 and the object by performing S32017 in accordance with the Method 1-2 as well.

On the contrary, when the intensity value of the first subset is the first threshold value or higher and is less than the second threshold value, the controller 400 can assume that the first subset has been created on the basis of the second laser beam reflected from an object within the predetermined short distance (S32015). Alternatively, only when it is determined that the first subset has been formed on the basis of the second laser beam reflected from an object located within the predetermined short distance, the controller 400 can assume that the first subset has been finally created on the basis of the second laser beam reflected from the object located within the predetermined short distance in accordance with the Method 1-2 as well (S32015).

If the intensity value of the first subset exceeds the second threshold, the controller 400 assumes that the object is a retroreflector, and can perform S32017 or assume that the first subset has been created on the basis of the second laser beam reflected from the object located within the predetermined short distance (S32015).

(Method 1-2) Method of Determining Whether Object is Located within Short Distance by Comparing First Subset and Second Subset

When a first subset is included in a plurality of subsets and an object is within a short distance from a first emitting timing of a first laser beam, the controller 400 can determine whether there is a second subset that includes the counting values of at least some of the time bins included in a short-distance measurement interval that is an interval during which the first laser beam can be reflected and detected by at least one detecting device (S32007).

If there is no second subset, the controller 400 can determine that the first subset has been measured on the basis of the first laser beam reflected from an object outside the short distance, and can measure the distance between the LiDAR device 1000 and the object in accordance with S32017.

If there is a second subset, it can be immediately determined that the first subset has been measured on the basis of the second laser beam reflected from an object within the short distance (S32015).

Meanwhile, it there is a second subset, the controller 400 can calculate a distance X on the basis of the first subset and the second emitting timing of the second laser beam (S32009). Further, the controller 400 can calculate a distance Y on the basis of the second subset and the first emitting timing of the first laser (S32011). If X and Y are the same or have a difference of a preset reference or lower (S32013), the controller 400 can determine that the first subset has been measured on the basis of the second laser beam reflected from an object within a short distance (S32015). If X and Y are not the same or do not have a difference of a preset reference or lower (S32013), the controller 400 can measure the distance between the LiDAR device 100 and the object in accordance with S32017.

In other words, when there is a second subset, the controller 400 can determine that the first subset has been measured on the basis of the second laser beam reflected from an object within a short distance by directly progressing to S32015, or may determine that the first subset has been measured on the basis of the second laser beam reflected from an object within a short distance through S32009 to S32013.

Meanwhile, as described above, it can be determined by at least one of the (Method 1-1) and the (Method 1-2) that a first subset has been measured on the basis of a second laser beam reflected from an object within a predetermined short distance. That is, only one of the (Method 1-1) and the (Method 1-2) may be considered, or both the (Method 1-1) and the (Method 1-2) may be considered. For example, it may be determined that a first subset has been measured on the basis of a second laser beam reflected from an object located within a predetermined short distance by considering only the (Method 1-2). Further, as described above, it may be determined that a first subset has been measured on the basis of a second laser beam reflected from an object located within a predetermined short distance without S32009 to S32013 of the (Method 1-2). Alternatively, it may be determined that a first subset has been measured on the basis of a second laser beam reflected from an object located within a predetermined short distance through the processes of S32009 to S32013.

[I-2-2. Method of Measuring Distance to Object when First Subset is Included in Plurality of Subsets]

Hereafter, a method in which the LiDAR device 100 measures the distance between the LiDAR device 100 and an object using a first subset and/or a second subset when it is determined that the first subset is included in a plurality of subsets.

(Method 2-1) Method of Measuring Distance Between LiDAR Device 1000 and Object Using First Subset while Ignoring Second Subset

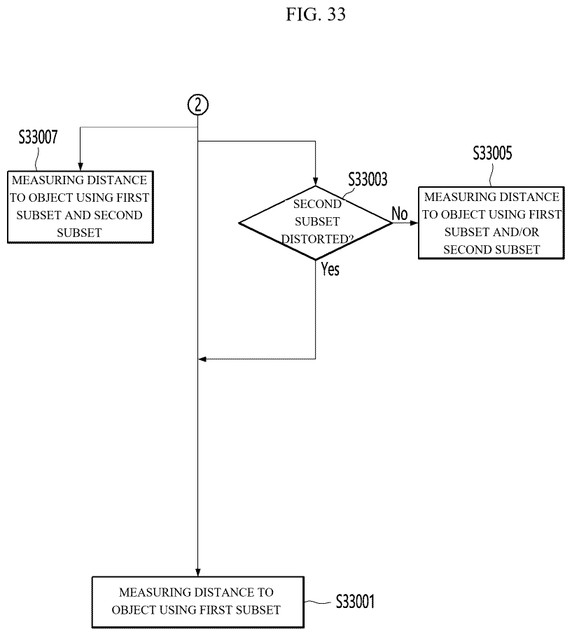

Referring to FIG. 33, when it is determined that an object is within a predetermined short distance from the LiDAR device 100, it is possible to measure the distance between the LiDAR device 100 and the object on the basis of a first subset, a second emitting timing of a second subset, and a sub-scan cycle while ignoring a second subset (S33001).

### (Method 2-2) Method of Measuring Distance Between LiDAR Device 1000 and Object Depending on Whether Second Subset is Distorted

The controller 400 can determine whether a second subset has been distorted (S33003). In this case, whether the second subset has been distorted can be determined on the basis of the counting values included in the second subset or distribution of the counting values. For example, whether the second subset has been distorted can be determined on the basis of how many counting values, which are the same as the highest counting value or have a difference within a predetermined range, are distributed among the counting values included in the second subset, and how much the deviation between these counting values and the highest counting value is.

If it is determined that the second subset has been distorted, it is possible to measure the distance between the LiDAR device 1000 and the object on the basis of the first subset, the second emitting timing of the second laser beam, and the sub-scan cycle while ignoring the second subset (S33001).

If it is determined that the second subset has not been distorted, it is possible to measure the distance between the LiDAR device 1000 and the object on the basis of the second subset, the first emitting timing of the first laser beam, and the scan cycle (S33005). In this case, the first subset, the second emitting timing of the second laser beam, and the sub-scan cycle may be additionally and supplementarily used.

### (Method 2-3) Method of Measuring Distance Between LiDAR Device 1000 and Object Using Both First Subset and Second Subset

The controller 400 can measure the distance between the LiDAR device 1000 and an object using a first subset, the second emitting timing of a second laser beam, and a sub-scan cycle, a second subset, the first emitting timing of a first laser beam, and a scan cycle.

For example, when a second subset is distorted due to causes such as saturation of histogram data, the controller 400 can correct the distance between the LiDAR device 1000 and an object, which is measured on the basis of the second subset, the first emitting timing of a first laser beam, and a scan cycle, using a first subset, the second emitting timing of a second laser beam, and a sub-scan cycle.

For example, the controller 400 can correct the degree of distortion of the second subset or the counting values included in the second subset on the basis of specific arithmetic values such as the distribution or ratio of the counting values included in the first subset. In this case, the controller 400 may additionally correct the degree of distortion of the second subset in consideration of the distance between the LiDAR device 1000 and the object measured on the basis of the first subset, the second emitting timing of the second laser beam, and the sub-scan cycle. Further, the controller 400 can measure the distance between the LiDAR device 1000 and the object using the corrected second subset, the first emitting timing of the first laser beam, and the scan cycle.

Meanwhile, the controller 400 can measure the distance between the LiDAR device 1000 and an object on the basis of at least one of the (Method 2-1), (Method 2-2), and (Method 2-3) described above. For example, the controller 400 can measure the distance between the LiDAR device 1000 and an object in accordance with any one of the (Method 2-1), (Method 2-2), and (Method 2-3).

Meanwhile, a third subset, in addition to the first subset and the second subset, may be included in a plurality of subsets. When a third subset is composed of the counting values of time bins outside a short-distance measurement interval corresponding to the time until a first laser beam is reflected from an object, which is located in a short distance, and detected by at least one detecting device from the first emitting timing of the first laser beam, and when it is determined that a first subset has been measured on the basis of a second laser beam reflected from an object located within a predetermined short distance, the controller 400 can determine a subset to compare with the third subset from the first subset and the second subset.

If it is determined to ignore the second subset, it is possible to compare the intensity value of the first subset and the intensity value of the third subset. If the second subset has not been distorted or the second subset is corrected using the first subset, the intensity value of the second subset (or corrected second subset) and the intensity value of the third subset can be compared.

Further, when the intensity value of the third subset is larger, the controller 400 can measure the distance between the LiDAR device 1000 and the object on the basis of the third subset, the first emitting timing of the first laser beam, and the scan cycle. On the other hand, when the intensity value of the first subset or the second subset (or corrected second subset) is larger, it is possible to measure the distance between the LiDAR device 1000 and the object on the basis of the first subset, the second emitting timing of the second laser beam, and the sub-scan cycle, or the second subset, the first emitting timing of the first laser beam, and the scan cycle.

If the third subset includes the counting values of at least some of the time bins in the short-distance measurement interval, the controller 400, similar to the above descriptions, can determine whether the first subset has been measured on the basis of the second laser beam reflected from an object located within a predetermined short distance in accordance with the (Method 1-1) and/or the (Method 1-2), and can measure the distance between the object and the LiDAR device 100 in accordance with any one method of the (Method 2-1), Method (2-2), and (Method 2-3). That is, at least one method of the (Method 1-1) and/or the (Method 1-2) and the (Method 2-1), the (Method 2-2) and the (Method 2-3) can be performed once more on the basis of the third subset instead of the second subset. In other words, the controller 400 can determine whether the first subset has been measured on the basis of the second laser beam reflected from an object located within a predetermined short distance and can measure the distance between the object and the LiDAR device 100 by finally performing at least one method of (Method 1-1) and/or the (Method 1-2) and the (Method 2-1), the (Method 2-2) and the (Method 2-3) on each of the second subset and the third subset, and the first subset.

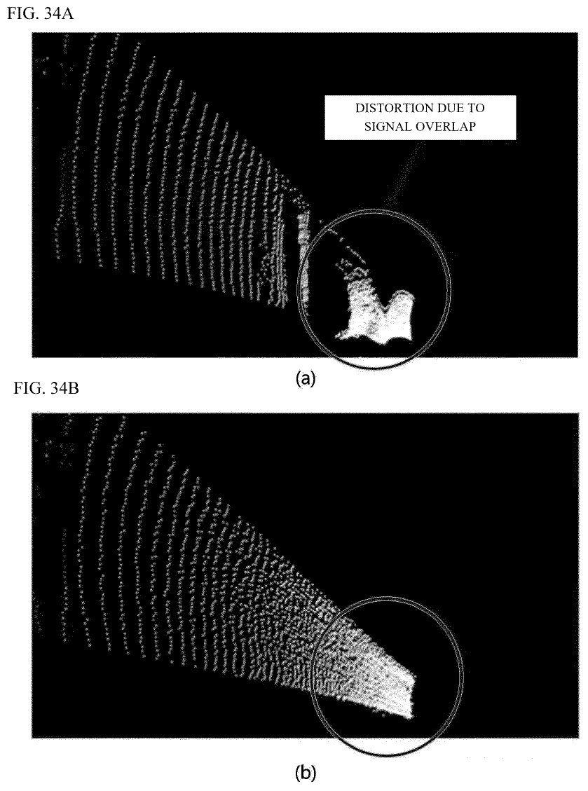

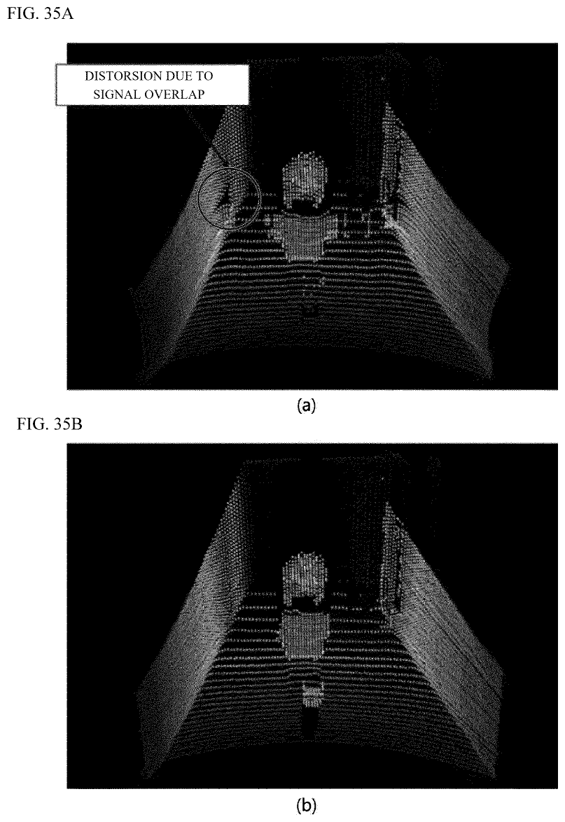

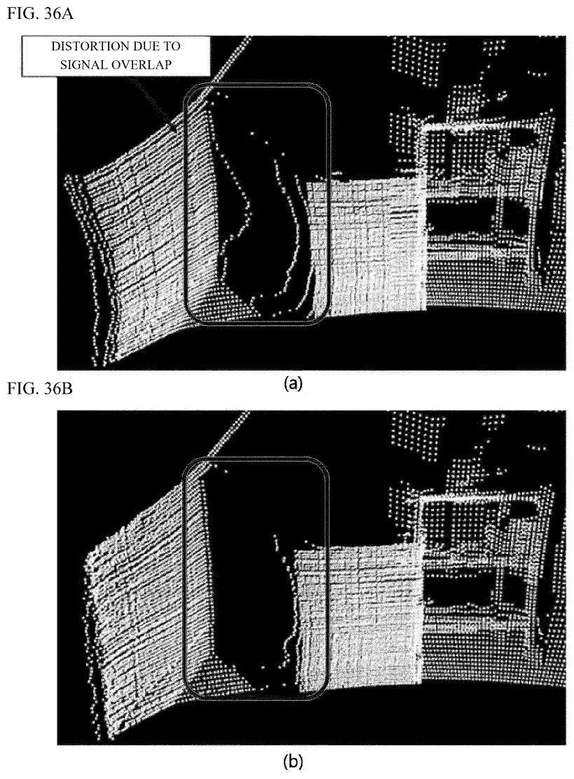

FIG. 34A to FIG. 36B compare point cloud data measured without applying embodiments of the present disclosure and point cloud data measured by applying embodiments of the present disclosure.

In each of FIG. 34 to FIG. 36, FIGS. 34A, 35A, 36A show point cloud data measured without applying embodiments of the present disclosure and FIGS. 34B, 35B, 36B show point cloud data measured without applying embodiments of the present disclosure.

Referring to FIG. 34 to FIG. 36, in the cases when embodiments of the present disclosure were applied, it can be seen that distortion of an object located at a short distance was significantly reduced. That is, it can be seen that the accuracy in distance measurement of the object has been significantly increased.

Meanwhile, in each of FIGS. 34 to 36, FIGS. 34B, 35B, 36B show a point cloud measured by the LiDAR device 1000 according to embodiments of the present disclosure by emitting a second laser beam once per two scan cycles. Accordingly, the measurement precision for a short-distance object may be lower in all scan cycles compared to when the second laser beam is emitted. That is, the point cloud data can be seen to fluctuate slightly.

However, since this is an issue caused by the second laser beam being emitted once per two scan cycles, if the second laser beam is emitted in every scan cycle, the measurement accuracy can also be increased. That is, depending on how many scan cycle intervals the LiDAR device 1000 emits the second laser beam, the measurement accuracy can vary. However, according to embodiments of the present disclosure, regardless of how many scan cycle intervals the LiDAR device 100 emits the second laser beam, it can be confirmed that the measurement accuracy significantly increases.

Methods that can increase the measurement accuracy of an object located at a short distance according to embodiments of the present disclosure were described above.

In other words, on the basis of FIG. 24 to FIG. 33, exemplary methods for implementing a method that can increase the measurement accuracy of an object located at a short distance according to an embodiment of the present disclosure were reviewed. However, the method that can increase the measurement accuracy of an object located at a short distance according to the present disclosure should not be interpreted as being limited to the examples described on the basis of FIG. 24 to FIG. 33.

That is, the operations of the LiDAR device 1000 described below are the essential configurations and implementation methods of embodiments of the present disclosure, and the specific descriptions based on FIG. 24 to FIG. 33 should be understood as merely supplementary and illustrative examples for practically implementing the operations of the LiDAR device 1000 described below.

According to embodiments of the present disclosure, in at least some scan cycles of the scan cycles included in a sub-time interval for histogram formation, the LiDAR device 1000 can emit a first laser beam with first intensity at a first emitting timing and then emit a second laser beam with second intensity lower than the first intensity at a second emitting timing.

Meanwhile, when at least some scan cycles are not all of a plurality of scan cycles, but some scan cycles, the LiDAR device 1000 can emit a first laser beam with first intensity in each of the remaining scan cycles, excluding the at least some scan cycles from the multiple scan cycles.

Further, the LiDAR device 1000 can detect photon in each of detecting windows corresponding to a plurality of scan cycles, respectively. Further, on the basis of the system clock of the LiDAR device 1000, photons detected from the first time bin synchronized with the emitting timings of a first laser beam and a second laser beam are counted, whereby it is possible to accumulate light detection count values for each time bin over a plurality of scan cycles.

Further, the LiDAR device 1000 can acquire a plurality of subsets of a histogram on the basis of the accumulated counting values. Further, the LiDAR device 1000 can check whether the first subset, which includes the counting values of at least some of the time bins included in the sub-scan cycle corresponding to the time interval from the second emitting timing to the time when the second laser beam is reflected from an object and then detected by at least one detecting device while traveling, is included in a plurality of subsets. If the first subset is included in the plurality of subsets, the LiDAR device 1000 can check whether the second subset, which includes the counting values of at least some of the time bins included in a short-distance measurement internal corresponding to the time interval from the first emitting timing to the time when the first laser beam is reflected from an object and then detected by at least one detecting device while traveling, is included in the plurality of subsets.

Further, if the second subset is included in the plurality of subsets, the LiDAR device 1000 can measure the distance between the LiDAR device 100 and the object using the first subset, the second emitting timing, and the sub-scan cycle while ignoring the second subset.

Further, if the second subset is included in the plurality of subsets, the LiDAR device 1000 can measure the distance between the LiDAR device 100 and the object using (i) the second subset, the first emitting timing, and the scan cycle and/or (ii) the first subset, the second emitting timing, and the sub-scan cycle.

Various embodiments of a laser emission array according to the present disclosure and various embodiments of the operation of the laser emission array were described above.

Therefore, other implements, other embodiments, and equivalents to the claims are included in the following claims.

However, for the convenience of explanation, since the details explained on the basis of specific embodiments can be sufficiently applied to other embodiments, and the specific descriptions were omitted, the present disclosure includes the concept that the details explained on the basis of specific embodiments are applicable to other embodiments as well.

Further, the description of the laser emission array, etc., may be replaced and described or stated using terms such as laser emission module, etc.

The method according to an embodiment may be implemented in a program that can be executed by various computers and may be recorded on computer-readable media. The computer-readable media may include program commands, data files, and data structures individually or in combinations thereof. The program commands that are recorded on the media may be those specifically designed and configured for the present invention or may be those available and known to those engaged in computer software in the art. The computer-readable recording media include magnetic media such as hard disks, floppy disks, and magnetic media such as a magnetic tape, optical media such as CD-ROMs and DVDs, magneto-optical media such as floptical disks, and hardware devices specifically configured to store and execute program commands, such as ROM, RAM, and flash memory. The program commands include not only machine language codes compiled by a compiler, but also high-level language code that can be executed by a computer using an interpreter etc. The hardware device may be configured to operate as one or more software modules to perform the operation of the present invention, and vice versa.

Embodiments were described above with reference to the limited examples and drawings, but they may be changed and modified in various ways by those skilled in the art. For example, the described technologies may be performed in order different from the described method, and/or even if components such as the described system, structure, device, and circuit are combined or associated in different ways from the description or replaced by other components or equivalents, appropriate results can be accomplished.

Therefore, other implements, other embodiments, and equivalents to the claims are included in the following claims.

What is claimed is:

1. A VCSEL (Vertical Cavity Surface Emitting Laser) array, comprising:
a plurality of sets of VCSELs, wherein each set of VCSELs comprises a plurality of VCSELs arranged along a longitudinal direction, wherein each VCSEL of the plurality of VCSELs comprises an upper electrode and a lower electrode;
a plurality of capacitors, wherein each of the plurality of capacitors is allocated to a corresponding set of VCSELs, wherein each of the plurality of capacitors is electrically connected to upper electrodes of the corresponding set of VCSELs;
a plurality of individual charging switches, wherein each of the plurality of individual charging switches is interposed between a corresponding capacitor and a power supply, wherein each of the plurality of individual charging switches is configured to selectively connect the corresponding capacitor to the power supply;
a common driving switch interposed between lower electrodes of the plurality of sets of VCSELs and a ground, wherein the common driving switch is configured to selectively connect the lower electrodes to the ground, wherein the common driving switch is configured to be capable of turning ON and OFF at a higher speed compared to the individual charging switches; and
a controller;
wherein in order to emit a first set of lasers through a first set of VCSELs, the controller is configured to:
operate a first individual charging switch during a first time duration to charge a first capacitor allocated to the first set of VCSELs, and
operate the common driving switch during a second time duration to cause the first set of VCSELs to receive energy supplied from the first capacitor and emit the first set of lasers, and
wherein the capability of the common driving switch to turn ON and OFF at a higher speed allows the energy supply duration for the first set of VCSELs to be shorted, and
wherein the energy supply duration for the first set of VCSELs is configured to be independent from the first time duration of the first individual charging switch, thereby allowing the first individual charging switch to operate at a relatively lower speed even when the energy supply duration is shorted.

2. The VCSEL array of claim 1,
wherein the second time duration is shorter than the first time duration.

3. The VCSEL array of claim 1,
wherein a number of the plurality of individual charging switches is greater than a number of the common driving switch.

4. The VCSEL array of claim 1,
wherein in order to emit a second set of lasers through a second set of VCSELs, the controller is configured:
operate a second individual charging switch during a third time duration to charge a capacitor allocated to the second set of VCSELs, and
operate the common driving switch during a fourth time duration to emit the second set of lasers through the second set of VCSELs, and
wherein the fourth time duration is shorter than the third time duration.

5. The VCSEL array of claim 4,
wherein a duration of the fourth time duration is the same as a duration of the third time duration.

6. The VCSEL array of claim 1,
wherein the controller is configured to select a set of VCSELs to emit a set of lasers, and
wherein in response to the selection of the set of VCSELs, the controller is configured to:
operate a selected individual charging switch to charge a selected capacitor allocated to the selected set of VCSELs, and
operate the common driving switch to emit the set of lasers through the selected set of VCSELs.

7. The VCSEL array of claim 1,
wherein the selection of the set of VCSELs to emit the set of lasers follows a predetermined sequence.

8. The VCSEL array of claim 1,
wherein the each set of VCSELs comprises an upper connection line, and
wherein a plurality of upper electrodes of each set of VCSELs are interconnected through the upper connection line.

9. The VCSEL array of claim 8,
wherein the upper connection line of each set of VCSELs is insulated from upper connection lines of other sets of VCSELs.

10. The VCSEL array of claim 1,
wherein the VCSEL array comprises a lower connection plane, and
wherein the lower electrodes of the plurality of sets of VCSELs are interconnected through the lower connection plane.

11. The VCSEL array of claim 1,
wherein the second time duration, to cause the first set of VCSELs to receive energy supplied from the first capacitor and emit the first set of lasers, is insufficient to completely discharge a total charge stored in the first capacitor.

12. The VCSEL array of claim 11,
wherein after the operation of the common driving switch during the second time duration, a residual charge remains in the first capacitor.

13. The VCSEL array of claim 12,
wherein the VCSEL array further comprises a discharging switch interposed between the plurality of capacitors and the ground, and
wherein the discharging switch is configured to selectively connect the plurality of capacitors to the ground.

14. The VCSEL array of claim 13,
wherein the residual charge remaining in the first capacitor is discharged by an operation of the discharging switch.

15. The VCSEL array of claim 1,
wherein the VCSEL array further comprises a plurality of discharging switches, wherein each of the plurality of discharging switches is interposed between a corresponding capacitor and the ground, and
wherein the each of the plurality of discharging switches is configured to selectively connect the corresponding capacitor to the ground.

16. A VCSEL (Vertical Cavity Surface Emitting Laser) array, comprising:
a plurality of sets of VCSELs, wherein each set of VCSELs comprises a plurality of VCSELs arranged along a longitudinal direction, wherein each VCSEL of the plurality of VCSELs comprises an upper electrode and a lower electrode;
a plurality of capacitors, wherein each of the plurality of capacitors is allocated to a corresponding set of VCSELs, wherein each of the plurality of capacitors is electrically connected to upper electrodes of the corresponding set of VCSELs;
a plurality of individual charging switches, wherein each of the plurality of individual charging switches is interposed between a corresponding capacitor and a power supply, wherein each of the plurality of individual charging switches is configured to selectively connect the corresponding capacitor to the power supply;
a common driving switch interposed between lower electrodes of the plurality of sets of VCSELs and a ground, wherein the common driving switch is configured to selectively connect the lower electrodes to the ground, wherein the common driving switch is configured to be capable of turning ON and OFF at a higher speed compared to the individual charging switches; and
a controller;
wherein the controller is configured to:
select a set of VCSELs to emit a set of lasers,
operate a selected individual charging switch during a first time duration to charge a selected capacitor allocated to the selected set of VCSELs, and
operate the common driving switch during a second time duration to cause the selected set of VCSELs to receive energy supplied from the selected capacitor and emit the set of lasers, and
wherein the capability of the common driving switch to turn ON and OFF at a higher speed allows the energy supply duration for the selected set of VCSELs to be shorted, and
wherein the energy supply duration for the selected set of VCSELs is configured to be independent from the first time duration of the first individual charging switch, thereby allowing the first individual charging switch to operate at a relatively lower speed even when the energy supply duration is shorted.

17. The VCSEL array of claim 16,
wherein the second time duration is shorter than the first time duration.

18. The VCSEL array of claim 16,
wherein a number of the plurality of individual charging switches is greater than a number of the common driving switch.

19. The VCSEL array of claim 18,
wherein the selection of the set of VCSELs to emit the set of lasers follows a predetermined sequence.

20. The VCSEL array of claim 16,
wherein after the operation of the common driving switch during the second time duration, a residual charge remains in the selected capacitor.
